(19) United States
(12) Patent Application Publication
(10) Pub. No.: US 2025/0044700 A1
(43) Pub. Date: Feb. 6, 2025

(54) PATTERN FORMING METHOD AND METHOD FOR PRODUCING ELECTRONIC DEVICE

(71) Applicant: FUJIFILM Corporation, Tokyo (JP)

(72) Inventors: Michihiro SHIRAKAWA, Haibara-gun (JP); Satomi TAKAHASHI, Haibara-gun (JP)

(73) Assignee: FUJIFILM Corporation, Tokyo (JP)

(21) Appl. No.: 18/925,335

(22) Filed: Oct. 24, 2024

Related U.S. Application Data
(63) Continuation of application No. PCT/JP2023/016115, filed on Apr. 24, 2023.

(30) Foreign Application Priority Data
Apr. 26, 2022 (JP) 2022-072437

(51) Int. Cl. G03F 7/32; G03F 7/038

(52) U.S. Cl. CPC G03F 7/325; G03F 7/038

(57) ABSTRACT

An object of the present invention is to provide a pattern forming method with which a pattern excellent in terms of critical resolution and the in-plane evenness of resolution may be formed. Another object of the present invention is to provide a method for producing an electronic device in which the pattern forming method is used.

A pattern forming method according to the present invention is a pattern forming method including a step 1 of forming a resist film on a substrate with an actinic ray- or radiation-sensitive resin composition including a resin X, a molecular weight of the resin X reducing as a result of a backbone of the resin X being broken by an action of exposure, an acid, or a base, a step 2 of exposing the resist film to light, and a step 3 of developing the resist film with a developer including an organic solvent to remove an exposed portion to form a pattern. The pattern forming method may further include a step 4 of cleaning the pattern using a rinse liquid including an organic solvent subsequent to the step 3. In the case where the pattern forming method does not include the step 4 subsequent to the step 3, the developer is a chemical solution including two or more types of organic solvents. In the case where the pattern forming method includes the step 4 subsequent to the step 3, at least one of the developer or the rinse liquid is a chemical solution including two or more types of organic solvents. The chemical solution including two or more types of organic solvents includes at least an organic solvent having a boiling point of 100° C. or more.

### CROSS-REFERENCE TO RELATED APPLICATIONS

This application is a Continuation of PCT International Application No. PCT/JP2023/016115 filed on Apr. 24, 2023, which claims priority under 35 U.S.C. § 119 (a) to Japanese Patent Application No. 2022-072437 filed on Apr. 26, 2022. The above applications are hereby expressly incorporated by reference, in their entirety, into the present application.

### BACKGROUND OF THE INVENTION

### 1. Field of the Invention

The present invention relates to a pattern forming method and a method for producing an electronic device.

### 2. Description of the Related Art

From a resist for KrF excimer laser (wavelength: 248 nm) onward, a pattern forming method that uses chemical amplification has been used for compensating the reduction in sensitivity caused by light absorption. For example, in a positive chemical amplification method, a photoacid generator included in a portion exposed to light becomes decomposed to generate an acid due to light irradiation. In a post exposure bake (PEB) process or the like, subsequently, the solubility of the exposed portion in a developer is changed as a result of, for example, an alkali insoluble group of a resin included in an actinic ray- or radiation-sensitive resin composition being changed into an alkali soluble group by the catalytic action of the acid. Subsequently, developing is performed using a basic aqueous solution or the like in order to remove the exposed portion and form an intended pattern.

In order to reduce the sizes of semiconductor elements, reductions in the wavelengths of light sources used for exposure and increases in the numerical apertures (NAs) of projection lenses have been implemented. In today's world, an exposure machine that includes an ArF excimer laser having a wavelength of 193 nm as a light source has been developed. Moreover, recently, pattern forming methods in which extreme ultraviolet radiation (EUV) and an electron beam (EB) are used as light sources have been being studied.

Under the above circumstances, various pattern forming methods in which an actinic ray- or radiation-sensitive resin composition is used have been proposed.

For example, JP2017-134373A discloses a method for forming a resist pattern, the method including:
forming a resist film using a positive resist composition that includes a polymer having a predetermined structure such that the solubility of the polymer in a developer increases as a result of the backbone of the polymer being broken when irradiated with ionizing radiation, such as an electron beam, or short-wavelength light (e.g., ionizing radiation), such as ultraviolet radiation, and a solvent;
exposing the resist film to light; and
developing the resist film exposed to light,
wherein the developing is performed using a developer including a fluorine-containing solvent and an alcohol.

### SUMMARY OF THE INVENTION

The inventors of the present invention studied the pattern forming method described in JP2017-134373A and consequently found that it is difficult to enhance both critical resolution of a pattern formed by the pattern forming method and the in-plane evenness of the resolution of the pattern in a balanced manner.

Accordingly, an object of the present invention is to provide a pattern forming method with which a pattern excellent in terms of critical resolution and the in-plane evenness of resolution may be formed.

Another object of the present invention is to provide a method for producing an electronic device in which the pattern forming method is used.

In order to achieve the above objects, the inventors of the present invention conducted extensive studies and consequently found that the above objects may be achieved by the following structures.
[1] A pattern forming method including:
a step 1 of forming a resist film on a substrate with an actinic ray- or radiation-sensitive resin composition including a resin X, a molecular weight of the resin X reducing as a result of a backbone of the resin X being broken by an action of exposure, an acid, or a base;
a step 2 of exposing the resist film to light; and
a step 3 of developing the resist film with a developer including an organic solvent to remove an exposed portion to form a pattern,
wherein the pattern forming method may further include a step 4 of cleaning the pattern using a rinse liquid including an organic solvent subsequent to the step 3,
in the case where the pattern forming method does not include the step 4 subsequent to the step 3, the developer is a chemical solution including two or more types of organic solvents,
in the case where the pattern forming method includes the step 4 subsequent to the step 3, at least one of the developer or the rinse liquid is a chemical solution including two or more types of organic solvents, and
the chemical solution including two or more types of organic solvents includes at least an organic solvent having a boiling point of 100° C. or more.
[2] The pattern forming method according to [1],
wherein the resin X has a group, a polarity of the group being reduced by an action of exposure, an acid, or a base.
[3] The pattern forming method according to [1],
wherein the composition further includes a resin Y other than the resin X, and
the resin Y has a group, a polarity of the group being reduced by an action of exposure, an acid, or a base.
[4] The pattern forming method according to [1],
wherein the resin X has an interactive group that interacts with an onium salt compound, an interaction between the interactive group and the onium salt compound being canceled by an action of exposure, an acid, or a base, and
the composition further includes an onium salt compound.
[5] The pattern forming method according to [1],
wherein the composition further includes a resin Y other than the resin X,
the resin Y has an interactive group that interacts with an onium salt compound, an interaction between the interactive group and the onium salt compound being canceled by an action of exposure, an acid, or a base, and
the composition further includes an onium salt compound.
[6] The pattern forming method according to [1],
wherein the resin X has a polar group, and
the composition further includes a compound capable of reacting with the polar group by an action of exposure, an acid, or a base.
[7] The pattern forming method according to [1],
wherein the composition further includes a resin Y other than the resin X,
the resin Y has a polar group, and
the composition further includes a compound capable of reacting with the polar group by an action of exposure, an acid, or a base.
[8] The pattern forming method according to any one of [1] to [7],
wherein the resin X has a weight-average molecular weight of 40,000 or more.
[9] The pattern forming method according to any one of [1] to [8],
wherein the resin X has a polydispersity of 1.7 or less.
[10] The pattern forming method according to any one of [1] to [9],
wherein the chemical solution including two or more types of organic solvents substantially does not include an organic solvent containing 50% by mass or more fluorine atoms.
[11] The pattern forming method according to any one of [1] to [10],
wherein the chemical solution including two or more types of organic solvents includes an organic solvent having a boiling point of 120° C. or more.
[12] The pattern forming method according to any one of [1] to [11],
wherein the chemical solution including two or more types of organic solvents includes organic solvents A and B,
the organic solvent A has a higher boiling point than the organic solvent B, and
the organic solvent A has a larger C log P than the organic solvent B.
[13] A method for producing an electronic device,
the method including the pattern forming method according to any one of [1] to [12].

According to the present invention, a pattern forming method with which a pattern excellent in terms of critical resolution and the in-plane evenness of resolution may be formed may be provided.

Moreover, a method for producing an electronic device in which the pattern forming method is used may be provided.

### DESCRIPTION OF THE PREFERRED EMBODIMENTS

Details of the present invention are described below.

Although the elements of the present invention may be described on the basis of representative embodiments of the present invention below, the present invention is not limited by the embodiments.

In the specification, when the term “group (atomic group)” is used without mentioning whether the group (atomic group) is substituted or unsubstituted, it is considered that the term “group (atomic group)” refers to both substituted and unsubstituted group unless otherwise specified. For example, the term “alkyl group” used herein refers to both an alkyl group that does not have a substituent (i.e., unsubstituted alkyl group) and an alkyl group that has a substituent (i.e., substituted alkyl group). In the specification, the term “organic group” refers to a group that includes at least one carbon atom.

The substituent is preferably a monovalent substituent unless otherwise specified.

In the specification, the term “actinic ray” or “radiation” refers to, for example, far ultraviolet radiation, extreme ultraviolet radiation (EUV), an X-ray, or an electron beam (EB), such as the emission line spectrum of a mercury lamp or an excimer laser. In the specification, the term “light” refers to an actinic ray or radiation.

In the specification, the term “exposure” refers to not only exposure with far ultraviolet radiation, extreme ultraviolet radiation, an X-ray, or the like, such as the emission line spectrum of a mercury lamp or an excimer laser, but also drawing with a corpuscular beam, such as an electron beam or an ion beam, unless otherwise specified.

In the specification, a numerical range expressed using “to” means the range specified by the lower and upper limits described before and after “to”, respectively.

The directions in which the divalent groups described in the specification are bonded to others are not limited unless otherwise specified. For example, in the case where Y included in a compound represented by “X—Y—Z” is —COO—, Y may be either —CO—O— or —O—CO— and the compound may be either “X—CO—O—Z” or “X—O—CO—Z”.

In the specification, the terms “ppm”, “ppb”, and “ppt” refer to “parts-per-million (10⁻⁶)”, “parts-per-billion (10⁻⁹)”, and “parts-per-trillion (10⁻¹²)”, respectively.

In the specification, the weight-average molecular weight Mw, number-average molecular weight Mn, and polydispersity Mw/Mn (hereinafter, also referred to as “molecular weight distribution”) of a resin are determined in terms of polystyrene-equivalent values by gel permeation chromatography (GPC) with a GPC apparatus “HLC-8120GPC” produced by Tosoh Corporation (solvent: tetrahydrofuran, flow rate (sample injection volume): 10 μL, column: TSK gel “Multipore HXL-M” produced by Tosoh Corporation, column temperature: 40° C., flow rate: 1.0 mL/min, detector: refractive index detector).

C log P is a value calculated using a program “C LOG P” available from Daylight Chemical Information System, Inc. This program provides the “calculated log P” value calculated by the fragmental approach of Hansch, Leo (see the document below). The fragmental approach is based on the chemical structure of a compound. The chemical structure is divided into partial structures (i.e., fragments), and the log P contribution values assigned to the respective fragments are summed in order to estimate the log P of the compound. Details are described in the following document. In the specification, C log P values calculated using a program “C LOG P v4.82” are used.

A. J. Leo, Comprehensive Medicinal Chemistry, Vol. 4, C. Hansch, P. G. Sammnens, J. B. Taylor and C. A. Ramsden, Eds., p. 295, Pergamon Press, 1990 C. Hansch & A. J. Leo. Substituent Constants For Correlation Analysis in Chemistry and Biology. John Wiley & Sons. A. J. Leo. Calculating log P_{oct} from structures. Chem. Rev., 93, 1281-1306, 1993.

The term “log P” refers to a common logarithm of partition coefficient P, which is a physical property value that quantifies the degree of distribution of an organic compound in a two-phase equilibrium system consisting of an oil (commonly, 1-octanol) and water. log P is expressed using the formula below.

$$log P = log ( {C}_{oil} / {C}_{water} )$$

where Cₒᵢₗ represents the molar concentration of the compound in the oil phase, and C_{water} represents the molar concentration of the compound in the water phase.

Across the zero, the larger the log P value in the positive direction, the higher the oil solubility; the larger the absolute value of the log P value in the negative direction, the higher the water solubility. That is, log P is negatively correlated with the water solubility of an organic compound. Thus, log P is widely used as a parameter for estimating the hydrophilicity or hydrophobicity of an organic compound.

In the specification, the term “acid dissociation constant (pKa)” refers to a pKa value determined in an aqueous solution, which is specifically a value calculated using Software Package 1 below on the basis of the Hammett substituent constants and the database of literature values known in the related art. Note that all the pKa values described in the specification are values calculated using the software package below.

Software Package 1: Advanced Chemistry Development (ACD/Labs) Software V8.14 for Solaris (1994-2007 ACD/Labs)

pKa may also be calculated using molecular orbital calculation. Specific examples of the method include a method in which the H⁺ dissociation free energy in an aqueous solution is calculated on the basis of thermodynamic cycle in order to determine pKa. As for the method for calculating the H⁺ dissociation free energy, for example, density functional theory (DFT) may be used. However, the method is not limited to this, and various methods have been reported in literatures and the like. There are a plurality of software that can be used for performing DFT, and examples thereof include “Gaussian 16”.

As described above, the term “pKa” used in the specification refers to a value calculated using Software Package 1 below on the basis of the Hammett substituent constants and the database of literature values known in the related art. In the case where it is not possible to calculate pKa by the above method, a value determined on the basis of density functional theory (DFT) using “Gaussian 16” is employed.

As described above, the term “pKa” used in the specification refers to a pKa value determined in an aqueous solution. In the case where it is not possible to determine pKa in an aqueous solution, “pKa determined in a dimethyl sulfoxide (DMSO) solution” is employed.

In the specification, examples of the halogen atom include fluorine, chlorine, bromine, and iodine atoms.

In the specification, the term “solid component” refers to a component that constitutes a resist film and does not refer to a solvent. Any component that constitutes a resist film is considered as a solid component even if the component is in the form of liquid.

In the specification, the term “boiling point” refers to a boiling point at 1 atmospheric pressure (i.e., 760 mmHg).

### Pattern Forming Method

A pattern forming method according to the present invention is a pattern forming method including:
a step 1 of forming a resist film on a substrate with an actinic ray- or radiation-sensitive resin composition (hereinafter, referred to also as “resist composition” or “composition”) including a resin X, a molecular weight of the resin X reducing as a result of a backbone of the resin X being broken by the action of exposure, an acid, or a base (hereinafter, such a resin is referred to simply as “resin X”);
a step 2 of exposing the resist film to light; and
a step 3 of developing the resist film with a developer including an organic solvent to remove an exposed portion to form a pattern (i.e., a positive pattern),
wherein the pattern forming method may further include a step 4 of cleaning the pattern using a rinse liquid including an organic solvent subsequent to the step 3,
in the case where the pattern forming method does not include the step 4 subsequent to the step 3, the developer is a chemical solution including two or more types of organic solvents,
in the case where the pattern forming method includes the step 4 subsequent to the step 3, at least one of the developer or the rinse liquid is a chemical solution including two or more types of organic solvents, and
the chemical solution including two or more types of organic solvents includes at least an organic solvent having a boiling point of 100° C. or more.

Hereinafter, a chemical solution including two or more types of organic solvents, the chemical solution including at least an organic solvent having a boiling point of 100° C. or more (i.e., a chemical solution including two or more types of organic solvents, wherein at least one of the organic solvents included in the chemical solution is an organic solvent having a boiling point of 100° C. or more), is referred to also as “specific chemical solution”.

The action mechanisms by which a pattern formed by the above pattern forming method is excellent in terms of critical resolution and the in-plane evenness of resolution are not completely clear. The inventors of the present invention consider as follows.

The features of the pattern forming method according to the present invention are that the resin X is used in the pattern forming method and that at least one of the developer used in Step 3 or the rinse liquid used in Step 4 includes the specific chemical solution.

When the resist film is exposed to light in Step 2, a reaction that involves breakage of the backbone of the resin X occurs in the exposed portion. This results in a difference in the degree of solubility (i.e., dissolution contrast) in an organic solvent between the exposed and unexposed portions. In the case where at least one of the developer used in Step 3 or the rinse liquid used in Step 4 includes the specific chemical solution, the specific chemical solution, which includes a plurality of organic solvents, is likely to solvate the resin X having a reduced molecular weight. This may enhance the dissolution contrast between the exposed and unexposed portions and the critical resolution of the pattern that is to be formed. Moreover, the chemical solution, which includes at least an organic solvent having a boiling point of 100° C. or more, is unlikely to vaporize during the developing treatment performed in Step 3 and the rinsing treatment performed in Step 4. This may reduce variations in composition which may occur during the treatments and consequently enhance the in-plane evenness of the resolution of the pattern.

Hereinafter, at least one of the critical resolution or the in-plane evenness of the resolution being further enhanced is referred to also as “the advantageous effects of the present invention are further enhanced”.

The pattern forming method preferably includes Steps 1, 2, and 3 and Step 4, which is an optional step conducted as needed, in this order. The pattern forming method may also include the steps described below, which are other than any of the above steps.

Each of the steps of the pattern forming method is described in detail below.

In the pattern forming method, the specific chemical solution is preferably included in at least one of the developer used in Step 3 or the rinse liquid used in Step 4 and is particularly preferably included in at least the rinse liquid used in Step 4.

### Step 1: Resist Film Formation Step

Step 1 is a step of forming a resist film using a resist composition.

For forming a resist film using a resist composition, for example, the resist composition may be applied onto a substrate. The resist composition is described below.

For applying the resist composition onto a substrate, for example, the resist composition may be applied onto a substrate (e.g., a silicon substrate) for use in the production of semiconductor devices, such as integrated circuits, with a spinner, a coater, or the like.

The coating method is preferably spin coating in which a spinner is used. The rotational speed at which spin coating is performed is preferably 1,000 to 3,000 rpm.

The substrate coated with the resist composition may be dried in order to form a resist film.

For performing drying, for example, heating may be performed. For performing heating, units included in common exposure machines and/or common developing machines known in the related art and a hot plate may be used.

The heating temperature is preferably 80° C. to 150° C., is more preferably 80° C. to 140° C., and is further preferably 80° C. to 130° C. The amount of time during which heating is performed is preferably 30 to 1,000 seconds, is more preferably 30 to 800 seconds, and is further preferably 40 to 600 seconds. The number of times the heating is performed may be only one or two or more.

The thickness of the resist film is preferably 10 to 90 nm, is more preferably 10 to 65 nm, and is further preferably 15 to 50 nm in order to form a fine pattern with further high precision.

Optionally, an undercoat film (e.g., an inorganic film, an organic film, or an antireflection film) may be interposed between the substrate and the resist film.

An undercoat film-forming composition preferably includes a common organic or inorganic material known in the related art.

The thickness of the undercoat film is preferably 10 to 90 nm, is more preferably 10 to 50 nm, and is further preferably 10 to 30 nm.

Examples of the undercoat film-forming composition include “AL412” produced by Brewer Science and “SHB” series (e.g., “SHB-A940”) produced by Shin-Etsu Chemical Co., Ltd.

Optionally, a topcoating may be formed using a topcoating composition on a surface of the resist film which does not face the substrate.

It is preferable that the topcoating composition do not mix with the resist film and be applied onto the surface of the resist film which does not face the substrate in a homogeneous manner.

The topcoating composition preferably includes a resin, an additive, and a solvent.

Examples of the method for forming a topcoating include the common topcoating forming methods known in the related art, and specific examples thereof include the topcoating forming method described in Paragraphs to of JP2014-059543A.

For forming a topcoating, it is preferable to form the topcoating including a basic compound described in JP2013-061648A on a surface of the resist film which does not face the substrate. Examples of the basic compound also include the basic compound described in WO2017/002737A.

It is also preferable that the topcoating include a compound having at least one selected from the group consisting of —O—, —S—, a hydroxyl group, a thiol group, —CO—, and —COO—.

### Step 2: Exposure Step

Step 2 is a step of exposing the resist film to light.

Step 2 is preferably a step of performing pattern exposure through a photo mask.

Examples of the photo mask include common photo masks known in the related art. The photo mask may be arranged in contact with the resist film.

Examples of the exposure light to which the resist film is exposed include infrared light, visible light, ultraviolet light, far ultraviolet light, extreme ultraviolet light (EUV), an X-ray, and an electron beam.

The wavelength of the exposure light is preferably 250 nm or less, is more preferably 220 nm or less, and is further preferably 1 to 200 nm. Specifically, a KrF excimer laser (wavelength: 248 nm), an ArF excimer laser (wavelength: 193 nm), a F₂ excimer laser (wavelength: 157 nm), an X-ray, EUV (wavelength: 13 nm), and an electron beam are preferable, a KrF excimer laser, an ArF excimer laser, EUV, and an electron beam are more preferable, and EUV and an electron beam are further preferable.

Amount of exposure is not limited and may be any amount with which the degree of solubility of the exposed resist film in an organic solvent is increased.

The method with which the exposure is performed in Step 2 may be liquid immersion exposure.

The number of times Step 2 is conducted may be only one or two or more.

### Step 3: Developing Step

Step 3 is a step of developing the exposed resist film with a developer including an organic solvent. The develop treatment removes the exposed portion of the resist film to form a pattern.

In the case where the pattern forming method does not include Step 4 described below, and in the case where the pattern forming method includes Step 4 described below and the rinse liquid used in Step 4 is a chemical solution other than the specific chemical solution (hereinafter, such a chemical solution is referred to also as “other chemical solution”), the specific chemical solution is used as a developer in Step 3.

In the case where the pattern forming method includes Step 4 described below and the rinse liquid used in Step 4 is the specific chemical solution, the developer used in Step 3 may be either the specific chemical solution or another chemical solution.

The specific chemical solution and another chemical solution are described below.

### Developing Method

Examples of the developing method include common developing methods known in the related art.

Specific examples of the developing method include a method of immersing the exposed resist film in a tank filled with a developer for a predetermined amount of time (i.e., dipping method); a method of applying a developer onto the surface of the exposed resist film such that the surface of the developer is bowed outward by surface tension and leaving the developer to stand for a predetermined amount of time (i.e., puddle method); a method of spraying a developer onto the surface of the exposed resist film (i.e., spraying method); and a method of continuously ejecting a developer onto a substrate including the exposed resist film disposed thereon, the substrate being rotated at a predetermined speed, through a nozzle capable of ejecting a developer at a predetermined rate, while scanning the substrate with the nozzle (i.e., dynamic dispense method)

Optionally, a step of stopping the developing using a solvent other than the developer may be conducted subsequent to the developing step.

The amount of time during which the developing is performed is preferably 10 to 300 seconds and is more preferably 20 to 120 seconds.

The temperature of the developer used in the developing step is preferably 0° C. to 50° C. and is more preferably 15° C. to 35° C.

### Step 4: Rinse Step

Step 4 is a step of cleaning the pattern formed in Step 3 (i.e., developing step) with a rinse liquid including an organic solvent.

In the case where the developer used in Step 3 is the specific chemical solution, the rinse liquid used in Step 4 may be either the specific chemical solution or another chemical solution.

In the case where the developer used in Step 3 is another chemical solution, the specific chemical solution is used as a rinse liquid in Step 4.

The specific chemical solution and the other chemical solution are described below.

### Rinsing Method

Examples of the rinsing method are the same as the examples of the developing method that can be used in Step 3 (i.e., a dipping method, a puddle method, a spraying method, and a dynamic dispense method).

The amount of treatment time is preferably 10 to 300 seconds and is more preferably 10 to 120 seconds.

The temperature of the rinse liquid is preferably 0° C. to 50° C. and is more preferably 15° C. to 35° C.

### Other Steps

The pattern forming method may further include a step other than any of Steps 1 to 4 described above (hereinafter, such a step is referred to as “other step”).

### Post-Exposure Bake (PEB) Step

The pattern forming method preferably includes a post-exposure bake (PEB) step conducted subsequent to Step 2 (i.e., exposure step) and prior to Step 3 (i.e., developing step).

The heating temperature at which the post-exposure baking is performed is preferably 80° C. to 150° C., is more preferably 80° C. to 140° C., and is further preferably 80° C. to 130° C. The amount of heating time is preferably 10 to 1,000 seconds, is more preferably 10 to 180 seconds, is further preferably 30 to 120 seconds.

For performing the post-exposure baking, units included in common exposure machines and/or common developing machines known in the related art and a hot plate may be used. The number of times the post-exposure baking is performed may be only one or two or more.

### Post-Baking (PB) Step

The pattern forming method preferably includes a step (i.e., post-baking step) of heating the pattern subsequent to Step 4 (i.e., rinse step). The post-baking step removes the developer or rinse liquid that retains in a gap formed in the pattern or inside the pattern and reduces roughening of the surface of the pattern.

The temperature at which heating is performed in the post-baking step is preferably 40° C. to 250° C. and is more preferably 80° C. to 200° C.

The amount of time during which heating is performed in the post-baking step is preferably 10 to 180 seconds and is more preferably 30 to 120 seconds.

### Etching Step

The pattern forming method may include a step (i.e., etching step) of etching the substrate using the pattern as a mask.

For etching the substrate, for example, common etching methods known in the related art may be used, and specific examples thereof include the etching methods described in Prospectus of International Society for Optics and Photonics (Proc. of SPIE) Vol. 6924, 692420 (2008), “Chapter 4: Etching” of “Handoutai Process Kyouhon (semiconductor process textbook)”, fourth edition, published in 2007 by SEMI Japan, and JP2009-267112A.

### Purification Step

The pattern forming method may include a step (i.e., purification step) of purifying the resist composition, the developer, the rinse liquid, and/or various types of the other components (e.g., an antireflection film-forming composition and a topcoating-forming composition) which are used in the pattern forming method.

Examples of the purification method include common purification methods known in the related art. A purification method in which filtering is performed through a filter and a purification method in which an adsorbent is used are preferable.

The pore size of the filter is preferably less than 100 nm, is more preferably 10 nm or less, and is further preferably 5 nm or less. The lower limit for the above pore size is commonly 0.01 nm or more.

The filter is preferably composed of polytetrafluoroethylene, polyethylene, or nylon. The filter may be composed of a composite material made by combining the material for the filter with an ion-exchange medium. The filter may be cleaned with an organic solvent before use.

In the method in which filtering is performed through a filter, plural types of filters arranged in series or parallel may be used. In the case where plural types of filters are used, filters that have different pore sizes and/or are composed of different materials may be used in combination. The number of times the material that is to be purified is filtered may be only one or two or more. In the case where a method in which filtering is performed two or more times is used, filtering may be performed while the material is circulated.

In the method in which an adsorbent is used, only the adsorbent may be used alone. In another case, the filter and the adsorbent may be used in combination.

Examples of the adsorbent include common adsorbents known in the related art, and specific examples thereof include inorganic adsorbents, such as silica gel and zeolite; and organic adsorbents, such as active carbon.

In the production of the resist composition, for example, it is preferable to dissolve the components that may be included in the resist composition, such as a resin, in an organic solvent and filter the resulting solution through a plurality of filters composed of different materials while circulating the solution. Specifically, it is preferable to connect a polyethylene filter having a pore size of 50 nm, a nylon filter having a pore size of 10 nm, and a polyethylene filter having a pore size of 3 nm to one another in series and filter the solution through the above filters 10 or more times while circulating the solution.

The pressure difference among the above filters is preferably small. Specifically, the pressure difference among the above filters is preferably 0.1 MPa or less, is more preferably 0.05 MPa or less, and is further preferably 0.01 MPa or less. The lower limit for the above pressure difference is commonly more than 0 MPa.

The pressure difference between the filters and the injection nozzle is also preferably small. Specifically, the above pressure difference is preferably 0.5 MPa or less, is more preferably 0.2 MPa or less, and is further preferably 0.1 MPa or less. The lower limit for the above pressure difference is commonly more than 0 MPa.

After being filtered through the filters, the resist composition is preferably charged into a clean container. In order to reduce the degradation of the resist composition with time, the resist composition charged in a container is preferably refrigerated. The amount of time it takes from when the charging of the resist composition into the container is finished to when the refrigerated storage of the resist composition is started is preferably small. Specifically, the above time interval is preferably 24 hours or less, is more preferably 16 hours or less, is further preferably 12 hours or less, and is particularly preferably 10 hours or less.

The temperature at which the refrigerated storage is performed is preferably 0° C. to 15° C., is more preferably 0° C. to 10° C., and is further preferably 0° C. to 5° C.

The resist composition, the developer, and the other components preferably do not contain an impurity.

Examples of the impurity include metal impurities, and specific examples thereof include Na, K, Ca, Fc, Cu, Mg, Al, Li, Cr, Ni, Sn, Ag, As, Au, Ba, Cd, Co, Pb, Ti, V, W, and Zn.

The impurity contents in the resist composition, the developer, and each of the other components are preferably 1 mass ppm or less, are more preferably 10 mass ppb or less, are further preferably 100 mass ppt or less, are particularly preferably 10 mass ppt or less, and are most preferably 1 mass ppt or less, relative to the total mass of the resist composition, the total mass of the developer, and the total mass of the other component (e.g., as for the impurity content in the rinse liquid, relative to the total mass of the rinse liquid), respectively. The lower limit for the impurity content is commonly set to 0 mass ppt or more.

For measuring impurities, for example, common measuring methods known in the related art, such as ICP mass spectrometry (ICP-MS), may be used.

Examples of the method for reducing the impurity content in a material include the method of filtering the material through a filter; a method of selecting a raw material having a low impurity content as a raw material constituting the material, and a method of distilling the material under conditions where the risk of contamination is minimized by, for example, lining the inside of the apparatus with Teflon (registered trademark).

The liquids including an organic solvent, such as the developer and the rinse liquid, may include a conductive compound in order to prevent the failure of chemical solution pipes and various types of parts (e.g., the filters, O-rings, and tubes) which may be caused due to electrostatic charge and discharge.

Examples of the conductive compound include methanol. In order to maintain the developing or rinsing performance, the contents of the conductive compound in the developer and the rinse liquid are preferably 10% by mass or less and are more preferably 5% by mass or less of the total masses of the developer and rinse liquid, respectively. The lower limit for the above content is commonly set to 0.01% by mass or more.

Examples of the chemical solution pipe include pipes composed of stainless steel (SUS) and various types of pipes coated with polyethylene, polypropylene, or a fluororesin (e.g., polytetrafluoroethylene and a perfluoroalkoxy resin) that has been subjected to an antistatic treatment.

Examples of the filters and O-rings include various types of filters and O-rings coated with polyethylene, polypropylene, or a fluororesin (e.g., polytetrafluoroethylene and a perfluoroalkoxy resin) that has been subjected to an antistatic treatment.

### Specific Chemical Solution

The specific chemical solution is a chemical solution including two or more types of organic solvents and includes at least an organic solvent having a boiling point of 100° C. or more. In other words, the specific chemical solution is a chemical solution including two or more types of organic solvents, wherein at least one of the organic solvents included in the chemical solution is an organic solvent having a boiling point of 100° C. or more.

In a preferable embodiment, at least one of the organic solvents included in the specific chemical solution has a boiling point of 120° C. or more.

In another preferable embodiment, all the organic solvents included in the specific chemical solution are organic solvents having a boiling point of 100° C. or more. In the above embodiment, it is preferable that at least one of the organic solvents included in the chemical solution be the organic solvent having a boiling point of 120° C. or more and it is more preferable that all the organic solvents included in the chemical solution be the organic solvents having a boiling point of 120° C. or more.

The upper limit for the boiling point of the organic solvent having a boiling point of 100° C. or more is not limited and commonly set to 260° C. or less. The upper limit is more commonly set to 220° C. or less.

The specific chemical solution may be a mixture of the organic solvents and water. The water content in the specific chemical solution is preferably less than 50% by mass, is more preferably less than 20% by mass, and is further preferably less than 10% by mass of the total mass of the chemical solution. It is particularly preferable that the specific chemical solution substantially do not contain water.

The content of the organic solvents in the specific chemical solution is preferably 50% to 100% by mass, is more preferably 80% to 100% by mass, is further preferably 90% to 100% by mass, and is particularly preferably 95% to 100% by mass of the total amount of the chemical solution.

The organic solvents included in the specific chemical solution preferably include at least one organic solvent selected from the group consisting of an ester solvent, a hydrocarbon solvent, an alcohol solvent, an ether solvent, a ketone solvent, and an amide solvent. The organic solvents included in the specific chemical solution are more preferably organic solvents selected from the group consisting of an ester solvent, a hydrocarbon solvent, an alcohol solvent, an ether solvent, a ketone solvent, and an amide solvent.

It is preferable that at least one of the organic solvents included in the specific chemical solution be an ester solvent or a hydrocarbon solvent. It is more preferable that the organic solvents included in the specific chemical solution include both ester solvent and hydrocarbon solvent.

The specific chemical solution preferably includes organic solvents A and B in order to further enhance the advantageous effects of the present invention. The organic solvent A has a higher boiling point than the organic solvent B. The organic solvent A has a larger C log P than the organic solvent B. That is, it is preferable that at least two of the organic solvents included in the specific chemical solution satisfy the relationship that one of the two organic solvents has a higher boiling point and a larger C log P than the other organic solvent.

In order to further enhance the advantageous effects of the present invention, it is more preferable that any two of the organic solvents included in the specific chemical solution satisfy the relationship that one of the two organic solvents has a higher boiling point and a larger C log P than the other organic solvent. In other words, for example, in the case where the specific chemical solution includes N types of organic solvents, it is more preferable that any two (N₁ and N₂) of the organic solvents satisfy the relationship that the organic solvent N₂ has a higher boiling point and a larger C log P than the organic solvent N₁.

### Specific Examples of Ester, Hydrocarbon, Alcohol, Ether, and Ketone Solvents

Specific examples of the ester, hydrocarbon, alcohol, ether, ketone, and amide solvents which may be suitably used as an organic solvent included in the specific chemical solution are described below.

### Ester Solvent

The ester solvent is not limited. In order to further enhance the advantageous effects of the present invention, the number of carbon atoms included in the ester solvent is preferably 3 to 12 and is more preferably 5 to 10.

The ester solvent has hetero atoms. Examples of the hetero atoms include oxygen atoms. It is preferable that the ester solvent have oxygen atoms only as hetero atoms.

The number of hetero atoms included in the ester solvent is preferably 2 to 6, is more preferably 2 or 3, and is further preferably 2. The ester solvent may have only one or two or more —COO— groups and preferably has only one —COO— group.

The boiling point of the ester solvent is preferably 100° C. to 200° C., is more preferably 120° C. to 200° C., and is further preferably 120° C. to 180° C.

The C log P of the ester solvent is preferably 1.00 to 4.00, is more preferably 1.20 to 3.50, and is further preferably 1.50 to 3.00.

Examples of the ester solvent include methyl acetate, butyl acetate, ethyl acetate, propyl acetate, isopropyl acetate, pentyl acetate, isopentyl acetate, hexyl acetate, propylene glycol monomethyl ether acetate (PGMEA), ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl butyrate, isobutyl isobutyrate, ethyl propionate, propyl propionate, and butyl propionate.

Propyl acetate, butyl acetate, hexyl acetate, PGMEA, ethyl lactate, isoamyl butyrate, ethyl propionate, and propyl propionate are preferable as ester solvents.

The above ester solvents may be used alone or in combination of two or more.

In the case where the specific chemical solution includes an ester solvent, as for the lower limit, the content of the ester solvent is preferably 30% by mass or more, is more preferably 40% by mass or more, is further preferably 50% by mass or more, and is particularly preferably 60% by mass or more of the total mass of the specific chemical solution. As for the upper limit, the content of the ester solvent is preferably 100% by mass or less, is more preferably 95% by mass or less, and is further preferably 90% by mass or less.

### Hydrocarbon Solvent

Examples of the hydrocarbon solvent include an aliphatic hydrocarbon solvent and an aromatic hydrocarbon solvent. The aliphatic hydrocarbon solvent may be a saturated or unsaturated aliphatic hydrocarbon solvent and is preferably a saturated aliphatic hydrocarbon solvent.

The number of carbon atoms included in the hydrocarbon solvent is preferably 3 to 20, is more preferably 8 to 12, and is further preferably 9 to 11.

The aliphatic hydrocarbon solvent may be any of linear, branched, or cyclic and is preferably linear. The aromatic hydrocarbon solvent may be either monocyclic or polycyclic.

Examples of the hydrocarbon solvent include saturated aliphatic hydrocarbon solvents, such as pentane, hexane, octane, nonane, decane, undecane, dodecane, hexadecane, 2,2,4-trimethylpentane, and 2,2,3-trimethylhexane; and aromatic hydrocarbon solvents, such as mesitylene, cumene, pseudocumene, 1,2,4,5-tetramethylbenzene, p-cymene, toluene, xylene, ethylbenzene, propylbenzene, 1-methylpropylbenzene, 2-methylpropylbenzene, dimethylbenzene, diethylbenzene, ethylmethylbenzene, trimethylbenzene, ethyldimethylbenzene, and dipropylbenzene.

The hydrocarbon solvent included in the specific chemical solution is preferably a saturated aliphatic hydrocarbon solvent, is more preferably at least one selected from the group consisting of octane, nonane, decane, undecane, and dodecane, and is further preferably at least one selected from the group consisting of nonane, decane, and undecane.

The boiling point of the hydrocarbon solvent is preferably 100° C. to 260° C., is more preferably 120° C. to 240° C., is further preferably 125° C. to 220° C., and is particularly preferably 140° C. to 220° C.

The C log P of the hydrocarbon solvent is preferably 3.00 to 10.0, is more preferably 4.00 to 9.00, and is further preferably 4.50 to 8.00.

The above hydrocarbon solvents may be used alone or in combination of two or more.

In the case where the specific chemical solution includes a hydrocarbon solvent, the content of the hydrocarbon solvent is preferably 5% to 30% by mass, is more preferably 10% to 25% by mass, is further preferably 10% to 20% by mass, and is particularly preferably 15% to 20% by mass of the total mass of the specific chemical solution.

### Ketone Solvent

The number of carbon atoms included in the ketone solvent is preferably 3 to 20, is more preferably 3 to 15, and is further preferably 3 to 12.

Examples of the ketone solvent include 1-octanone, 2-octanone, 1-nonanone, 2-nonanone, acetone, 2-heptanone, 4-heptanone, 1-hexanone, 2-hexanone, diisobutyl ketone, cyclohexanone, methyl cyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, and propylene carbonate.

The ketone solvent is preferably cyclohexanone, 2-heptanone, or diisobutyl ketone.

The boiling point of the ketone solvent is preferably 100° C. to 200° C., is more preferably 120° C. to 180° C., and is further preferably 150° C. to 180° C.

The C log P of the ketone solvent is preferably 1.00 to 4.00, is more preferably 1.20 to 3.50, and is further preferably 1.50 to 3.00.

The above ketone solvents may be used alone or in combination of two or more.

In the case where the specific chemical solution includes a ketone solvent, as for the lower limit, the content of the ketone solvent is, for example, preferably 20% by mass or more and is more preferably 30% by mass or more of the total mass of the specific chemical solution. As for the upper limit, the content of the ketone solvent is, for example, preferably 90% by mass or less, is more preferably 80% by mass or less, and is further preferably 70% by mass or less.

### Alcohol Solvent

Examples of the alcohol solvent include methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, n-decanol, ethylene glycol, diethylene glycol, triethylene glycol, ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

The boiling point of the alcohol solvent is preferably 80° C. to 180° C., is more preferably 80° C. to 160° C., and is further preferably 80° C. to 150° C.

The C log P of the alcohol solvent is preferably 0.00 to 3.00, is more preferably 0.20 to 2.50, and is further preferably 0.50 to 2.00.

The above alcohol solvents may be used alone or in combination of two or more.

In the case where the specific chemical solution includes an alcohol solvent, as for the lower limit, the content of the alcohol solvent is, for example, preferably 20% by mass or more and is more preferably 30% by mass or more of the total mass of the specific chemical solution. As for the upper limit, the content of the alcohol solvent is, for example, preferably 90% by mass or less, is more preferably 80% by mass or less, and is further preferably 70% by mass or less.

### Ether Solvent

Examples of the ether solvent include dioxane, tetrahydrofuran, and diisobutyl ether.

The boiling point of the ether solvent is preferably 100° C. to 180° C., is more preferably 100° C. to 160° C., and is further preferably 100° C. to 140° C.

The C log P of the ether solvent is preferably 1.00 to 4.00, is more preferably 1.20 to 3.50, and is further preferably 1.50 to 3.00.

The above ether solvents may be used alone or in combination of two or more.

In the case where the specific chemical solution includes an ether solvent, as for the lower limit, the content of the ether solvent is, for example, preferably 20% by mass or more and is more preferably 30% by mass or more of the total mass of the specific chemical solution. As for the upper limit, the content of the ether solvent is, for example, preferably 90% by mass or less, is more preferably 80% by mass or less, and is further preferably 70% by mass or less.

### Amide Solvent

Examples of the amide solvent include N-methyl-2-pyrrolidone, N,N-dimethylacetamide, N,N-dimethylformamide, hexamethylphosphoric triamide, and 1,3-dimethyl-2-imidazolidinone.

The boiling point of the amide solvent is preferably 140° C. to 250° C. and is more preferably 150° C. to 230° C.

The C log P of the amide solvent is preferably-2.00 to 1.00, is more preferably-1.80 to 0.50, and is further preferably-1.50 to 0.00.

The above amide solvents may be used alone or in combination of two or more.

In the case where the specific chemical solution includes an amide solvent, as for the lower limit, the content of the amide solvent is, for example, preferably 20% by mass or more and is more preferably 30% by mass or more of the total mass of the specific chemical solution. As for the upper limit, the content of the amide solvent is, for example, preferably 90% by mass or less, is more preferably 80% by mass or less, and is further preferably 70% by mass or less. Preferable Modes of Composition of Organic Solvents Included in Specific Chemical Solution

Preferable modes of the composition of the organic solvents included in the specific chemical solution are described below.

### Mode 1

The specific chemical solution includes at least first and second organic solvents.

At least one of the first and second organic solvents has a boiling point of 100° C. or more.

The first organic solvent is an ester solvent.

The second organic solvent is an organic solvent selected from the group consisting of a hydrocarbon solvent, an ester solvent, an alcohol solvent, an ether solvent, and a ketone solvent (note that the type of the ester solvent used as a second organic solvent is different from that of the ester solvent used as a first organic solvent).

The content of the first organic solvent is 40% by mass or more, is preferably 50% by mass or more, and is more preferably 60% by mass or more of the total content of the first and second organic solvents. Note that the upper limit for the content of the first organic solvent is not limited; the content of the first organic solvent is preferably 95% by mass or less and is more preferably 90% by mass or less.

### Mode 2

The specific chemical solution includes at least first and second organic solvents.

At least one of the first and second organic solvents has a boiling point of 100° C. or more.

The first organic solvent is a hydrocarbon solvent.

The second organic solvent is an organic solvent selected from the group consisting of an ester solvent, a hydrocarbon solvent, an alcohol solvent, an ether solvent, and a ketone solvent (note that the type of the hydrocarbon solvent used as a second organic solvent is different from that of the hydrocarbon solvent used as a first organic solvent).

The content of the first organic solvent is 30% by mass or less and is preferably 20% by mass or less of the total content of the first and second organic solvents. Note that the lower limit for the content of the first organic solvent is not limited; the content of the first organic solvent is preferably 10% by mass or more and is more preferably 15% by mass or more.

### Mode 3

The specific chemical solution includes at least first and second organic solvents.

At least one of the first and second organic solvents has a boiling point of 100° C. or more.

The first organic solvent is a ketone solvent.

The second organic solvent is an organic solvent selected from the group consisting of an alcohol solvent and a ketone solvent (note that the type of the ketone solvent used as a second organic solvent is different from that of the ketone solvent used as a first organic solvent).

The content of the first organic solvent is 30% to 70% by mass and is preferably 40% to 60% by mass of the total content of the first and second organic solvents.

### Mode 4

The specific chemical solution includes at least first and second organic solvents.

At least one of the first and second organic solvents has a boiling point of 100° C. or more.

The first organic solvent is an ester solvent.

The second organic solvent is a hydrocarbon solvent.

The mass ratio of the content of the first organic solvent to the content of the second organic solvent (i.e., Content of first organic solvent/Content of second organic solvent) is 1 to 50, is preferably 3 to 20, and is more preferably 6 to 15.

### Mode 5

The specific chemical solution includes at least first and second organic solvents.

At least one of the first and second organic solvents has a boiling point of 100° C. or more.

The first organic solvent is an organic solvent having a C log P of 3.00 or more (preferably, 3.50 or more).

The second organic solvent is an organic solvent other than the first organic solvent and is a ketone solvent or an ester solvent.

In Modes 1 to 5 above, the total content of the first and second organic solvents is preferably 80% to 100% by mass, is more preferably 90% to 100% by mass, and is further preferably 95% to 100% by mass of the total content of the organic solvents in the specific chemical solution. In the case where the specific chemical solution includes an organic solvent other than any of the first or second organic solvents, examples of the other organic solvent include the common organic solvents known in the related art which are other than any of those described above.

In Modes 1 to 4 above, as for the relationships between the boiling points and C log P values of the first and second organic solvents, it is preferable that one of the first and second organic solvents have a higher boiling point and a larger C log P than the other organic solvent. It is more preferable that one of the first and second organic solvents which is included in the specific chemical solution at a lower content have a higher boiling point and a larger C log P.

In Modes 1 to 5 above, the boiling points of the first and second organic solvents are preferably both 100° C. or more and are more preferably both 120° C. or more.

The specific chemical solution preferably substantially does not include an organic solvent including 50% by mass or more fluorine atoms in order to further enhance the advantageous effects of the present invention. Note that the expression “substantially does not include” used herein means that the content of an organic solvent including 50% by mass or more fluorine atoms is 5% by mass or less of the total mass of the chemical solution; the content of such an organic solvent is preferably 3% by mass or less and is more preferably 1% by mass or less. It is further preferable that the specific chemical solution do not include an organic solvent including 50% by mass or more fluorine atoms.

### Other Component

The specific chemical solution may optionally include a component other than an organic solvent.

Examples of the other component include common surfactants known in the related art.

The content of the surfactant is preferably 0.001% to 5% by mass, is more preferably 0.005% to 2% by mass, and is further preferably 0.01% to 0.5% by mass of the total mass of the specific chemical solution.

### Other Chemical Solution

The other chemical solution is described below. As described above, in the case where the pattern forming method includes Step 4, at least one of the developer used in Step 3 and the rinse liquid used in Step 4 is the specific chemical solution. Both developer used in Step 3 and rinse liquid used in Step 4 may be the specific chemical solutions. Alternatively, one of the developer used in Step 3 and the rinse liquid used in Step 4 may be the specific chemical solution, while the other is the other chemical solution.

The other chemical solution is a chemical solution other than the above specific chemical solution. Common developers and rinse liquids known in the related art may be used as another chemical solution.

The other chemical solution preferably includes at least one organic solvent selected from the group consisting of a ketone solvent, an ester solvent, an alcohol solvent, an amide solvent, an ether solvent, and a hydrocarbon solvent. Specifically, it is more preferable that the organic solvent included in the other chemical solution be selected from the group consisting of a ketone solvent, an ester solvent, an alcohol solvent, an amide solvent, an ether solvent, and a hydrocarbon solvent.

Specific examples of the ketone, ester, alcohol, amide, ether, and hydrocarbon solvents are the same as those described above as examples of the ketone, ester, alcohol, amide, ether, and hydrocarbon solvents that may be used as organic solvents included in the specific chemical solution.

The solvent included in the other chemical solution may be a mixture of a plurality of solvents and may be mixed with a solvent other than any of the above solvents or water. The water content in the other chemical solution is preferably less than 50% by mass, is more preferably less than 20% by mass, and is further preferably less than 10% by mass of the total mass of the other chemical solution. It is particularly preferable that the other chemical solution substantially do not contain water.

The content of the organic solvent in the other chemical solution is preferably 50% to 100% by mass, is more preferably 80% to 100% by mass, is further preferably 90% to 100% by mass, and is particularly preferably 95% to 100% by mass of the total amount of the other chemical solution.

The other chemical solution may include a component other than any of the above-described components.

Examples of the other component include the common organic solvents and surfactants known in the related art which are other than any of those described above.

The content of the surfactant is preferably 0.001% to 5% by mass, is more preferably 0.005% to 2% by mass, and is further preferably 0.01% to 0.5% by mass of the total mass of the other chemical solution.

### Resist Composition

The resist composition used in Step 1 is described below.

The resist composition includes a resin X. The resin X is a resin the molecular weight of which reduces as a result of the backbone of the resin being broken by the action of exposure, an acid, or a base.

The resist composition preferably satisfies at least one of Requirements X and Y below.
Requirement X: The resist composition satisfies at least one of Requirements A1 to A3 below.
Requirement A1: The resin X has a group the polarity of which reduces by the action of exposure, an acid, a base, or heat (hereinafter, such a group is referred to also as “polarity reduction group”).
Requirement A2: The resin X has a group that interacts with an onium salt compound, the interaction between the group and the onium salt compound being canceled by the action of exposure, an acid, a base, or heat (hereinafter this group is referred to as “interactive group”), and the resist composition further includes an onium salt compound.
Requirement A3: The resin X has a polar group, and the resist composition further includes a compound capable of reacting with the polar group by the action of exposure, an acid, a base, or heat (hereinafter, this compound is referred to also as “capping agent” or “hydrophobization agent”).
Requirement Y: The resist composition further includes a resin other than the resin X (hereinafter, this resin is referred to as “resin Y”) and satisfies at least one of Requirements B1 to B3 below.
Requirement B1: The resin Y has a group the polarity of which reduces by the action of exposure, an acid, a base, or heat (i.e., polarity reduction group).
Requirement B2: The resin Y has a group that interacts with an onium salt compound, the interaction between the group and the onium salt compound being canceled by the action of exposure, an acid, a base, or heat (i.e., interactive group), and the resist composition further includes an onium salt compound.
Requirement B3: The resin Y has a polar group, and the resist composition further includes a compound capable of reacting with the polar group by the action of exposure, an acid, a base, or heat (i.e., capping agent).

In the formation of a pattern, the difference between the degrees of solubility of the exposed and unexposed portions in the organic solvents (i.e., dissolution contrast) is caused primarily by the action of the resin X, the molecular weight of which reduces as a result of the backbone of the resin X being broken by the action of exposure, an acid, a base, or heat. It is considered that the advantageous effects of the present invention may be further enhanced in the case where the resist composition satisfies at least one of Requirements X and Y above for the following reasons.

The polarity of the resin X, which is included in the resist compositions in Requirements A1 to A3, and the polarity of the resin Y, which is included in the resist compositions in Requirements B1 to B3, may reduce by the action of exposure, an acid, a base, or heat. Moreover, the interaction between the resin X and an onium salt compound and the interaction between the resin Y and an onium salt compound may be canceled by the action of exposure, an acid, a base, or heat. Note that, while the formation of a pattern commonly involves an exposure treatment and a post-exposure heating treatment, the conditions (i.e., exposure, acid, and base) that may act on the resins X and Y that satisfy the above-described predetermined requirements are factors that may occur to the resist film during the exposure treatment and the post-exposure heating treatment. When the resist film is subjected to an exposure treatment, the degrees of polarity of the resins X and Y, which satisfy the predetermined requirements described above, are reduced or the interaction between the resins X and Y, which satisfy the predetermined requirements described above, and an onium salt compound is canceled. This makes it easier to increase the dissolution contrast between the exposed and unexposed portions (i.e., it becomes easier to increase the affinity of the exposed portion for the developer or rinse liquid that includes organic solvents). Consequently, the advantageous effects of the present invention may be further enhanced.

Details of the resins X and Y are described below.

### Resin X

The resist composition includes a resin X.

The resin X is a resin the molecular weight of which reduces as a result of the backbone of the resin being broken by the action of exposure, an acid, a base, or heat. The resin X typically corresponds to the specific modes X-1 to X-5 below and preferably corresponds to modes X-1 to X-4.
Mode X-1: The molecular weight of the resin X reduces as a result of the backbone of the resin X being broken by the action of exposure, an acid, a base, or heat. Moreover, the resin X has a polarity reduction group.
Mode X-2: The molecular weight of the resin X reduces as a result of the backbone of the resin X being broken by the action of exposure, an acid, a base, or heat. Moreover, the resin X has an interactive group.
Mode X-3: The molecular weight of the resin X reduces as a result of the backbone of the resin X being broken by the action of exposure, an acid, a base, or heat. Moreover, the resin X has a polar group.
Mode X-4: The molecular weight of the resin X reduces as a result of the backbone of the resin X being broken by the action of exposure, an acid, a base, or heat. Moreover, the resin X has two or more groups selected from the group consisting of a polarity reduction group, an interactive group, and a polar group.
Mode X-5: The molecular weight of the resin X reduces as a result of the backbone of the resin X being broken by the action of exposure, an acid, a base, or heat. Moreover, the resin X does not have any of a polarity reduction group, an interactive group, or a polar group.

Note that, in Modes X-1 to X-4, as described above, the polarity reduction group is a group the polarity of which reduces by the action of exposure, an acid, a base, or heat, and the interactive group is a group that interacts with an onium salt compound, the interaction between the group and the onium salt compound being canceled by the action of exposure, an acid, a base, or heat.

In the case where the resin X has a polarity reduction group, the resin X may have both of the polarity reduction group and a group the polarity of which has been reduced, which is generated from the polarity reduction group by the action of exposure, an acid, a base, or heat, prior to the action of exposure, an acid, a base, or heat.

In the case where the resin X has an interactive group (Modes X-2 and X-4), the resist composition typically further includes an onium salt compound capable of forming a bond as a result of the interaction between the onium salt compound and the interactive group of the resin X.

In the case where the resin X has a polar group Modes (X-3 and X-4), the resist composition typically further includes a capping agent capable of reacting with the polar group of the resin X to reduce the polarity of the resin X.

### Polarity Reduction Group, Interactive Group, and Polar Group

The polarity reduction group, the interactive group, and the polar group are described below.

### Polarity Reduction Group

The polarity reduction group is described below.

The polarity reduction group is a group the polarity of which reduces by the action of exposure, an acid, a base, or heat, as described above.

Whether or not a group is the polarity reduction group can be determined by calculating log P (octanol/water partition coefficient) on the basis of the chemical structures that has been and has not yet been subjected to the action of exposure, an acid, a base, or heat and determining whether or not the log P is increased by the action of exposure, an acid, a base, or heat.

The mechanisms by which the polarity of the polarity reduction group is reduced by the action of exposure, an acid, a base, or heat are not limited. Examples of the polarity reduction mechanisms include the following:
A mechanism in which polarity is reduced by the elimination reaction represented by Formula (K1) caused by the action of an acid.
A mechanism in which polarity is reduced by the elimination reaction represented by Formula (K2) caused as a result of cyclization reaction caused by the action of an acid.
A mechanism in which the polarity reduction group is an onium salt group that becomes decomposed by the action of exposure and polarity is reduced as a result of the group decomposing by exposure.
A mechanism in which the polarity reduction group is an acid-decomposable group including a polar group and a protecting group that protects the polar group, the protecting group being eliminated by the action of an acid, and the polar group generated subsequent to the acid decomposition is more hydrophobic than the acid-decomposable group prior to the acid decomposition.

Each of the above mechanisms is described below.

Mechanism in Which Polarity Is Reduced by Elimination Reaction Represented by Formula (K1) Caused by Action of Acid and Mechanism in Which Polarity Is Reduced by Elimination Reaction Represented by Formula (K2) Caused as Result of Cyclization Reaction Caused by Action of Acid

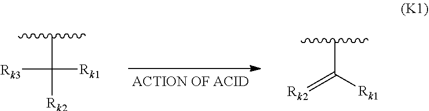

In the mechanism illustrated in Formula (K1), Rₖ₁ and Rₖ₂ represent an organic group including a hydrogen atom. Specifically, Rₖ₁ and Rₖ₂ are preferably organic groups including a hydrogen atom that is added to Rₖ₃ to cause elimination of Rₖ₃H by the action of an acid. It is preferable that Rₖ₁ and Rₖ₂ each independently represent an alkyl group (any of linear, branched, or cyclic) or an aryl group. It is more preferable that at least one of Rₖ₁ and Rₖ₂ be an alkyl group.

The number of carbon atoms included in the alkyl group is preferably 1 to 20, is more preferably 1 to 12, and is further preferably 1 to 6. The aryl group is preferably a phenyl group.

Rₖ₁ and Rₖ₂ may be bonded to each other to form an alicyclic ring. The number of members constituting the alicyclic ring is not limited and may be, for example, 5 to 7.

Rₖ₃ is preferably a group capable of being eliminated in the form of Rₖ₃H upon the addition of a hydrogen atom by the action of an acid. Specifically, Rₖ₃ is more preferably a group capable of being eliminated in the form of Rₖ₃H upon the addition of a hydrogen atom eliminated from Rₖ₁ and Rₖ₂ by the action of an acid. Rₖ₃ is preferably, for example, a hydroxyl group (—OH), an alkoxy group (—OR^{S}), an ester group (—OCOR^{S}), or, a carbonate group (—OCOOR^{S}), where R^{S} represents an organic group, which is preferably an alkyl group. The number of carbon atoms included in the alkyl group is preferably 1 to 20, is more preferably 1 to 12, and is further preferably 1 to 6.

One of Rₖ₁ and Rₖ₂ may be bonded to another atom included in the resin having a polarity reduction group to form a ring structure.

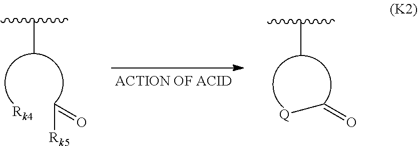

In the mechanism illustrated in Formula (K2), Rₖ₄ represents —OR^{T}, —NR^{T}R^{U}, or —SR^{T}, where R^{T} represents a hydrogen atom or an organic group capable of being eliminated by the action of an acid and R^{U} represents a hydrogen atom or an organic group.

In Formula (K2), Q represents —O—, —NR^{U}—, or —S— that is a portion of the Rₖ₄ group which remains subsequent to the cyclization reaction.

Rₖ₅ may be any group capable of being eliminated in the form of Rₖ₅H upon the addition of a hydrogen atom. Examples of such a group include a hydroxyl group (—OH), an alkoxy group (—OR^{V}), and a substituted or unsubstituted amino group (—NH₂, —NHR^{W}, or —NR^{W}R^{X}, where R^{W} and R^{X} represent an organic group and, in the case where the substituted or unsubstituted amino group is —NR^{W}R^{X}, any one of R^{W} or R^{X} is an organic group capable of being eliminated upon the cyclization reaction).

Note that, for example, in the case where Rₖ₄ is —OH and a phenolic hydroxyl group, it corresponds also to an interactive group or a polar group. In the case where Rₖ₄ is —OH and a alcoholic hydroxyl group, it corresponds also to a polar group. In the case where Rₖ₅ is, for example, —OH, —NH₂, —NHR^{W}, or —NR^{W}R^{X}, the group represented by —CO—Rₖ₅ illustrated in Formula (K2) corresponds also to an interactive group (when the group is a carboxyl group and an amide group) or a polar group (when the group is a carboxyl group).

The organic group represented by RT, which is eliminated by the action of an acid, is preferably an alkyl group (linear, branched, or cyclic) or an aryl group. The number of carbon atoms included in the alkyl group is preferably 1 to 20, is more preferably 1 to 12, and is further preferably 1 to 6. The aryl group is preferably a phenyl group. The above alkyl and aryl groups may further have a substituent.

The organic group represented by RU is not limited and is preferably an alkyl group (linear, branched, or cyclic) or an aryl group. The number of carbon atoms included in the alkyl group is preferably 1 to 20, is more preferably 1 to 12, and is further preferably 1 to 6. The aryl group is preferably a phenyl group. The above alkyl and aryl groups may further have a substituent.

R^{V} represents an organic group capable of being eliminated upon the cyclization reaction and is more preferably an alkyl group (linear, branched, or cyclic) or an aryl group. The number of carbon atoms included in the alkyl group is preferably 1 to 20, is more preferably 1 to 12, and is further preferably 1 to 6. The aryl group is preferably a phenyl group. The above alkyl and aryl groups may further have a substituent.

The organic groups represented by R^{W} and R^{X} are not limited and are preferably an alkyl group (linear, branched, or cyclic) or an aryl group. The number of carbon atoms included in the alkyl group is preferably 1 to 20, is more preferably 1 to 12, and is further preferably 1 to 6. The aryl group is preferably a phenyl group. The above alkyl and aryl groups may further have a substituent. The above alkyl and aryl groups correspond also to an organic group capable of being eliminated upon the cyclization reaction.

Specific examples of the polarity reduction group the polarity of which reduces by the mechanism illustrated in Formula (K1) above include the functional group represented by Formula (KD1) below.

Specific examples of the polarity reduction group the polarity of which reduces by the mechanism illustrated in Formula (K2) above include a monovalent functional group formed as a result of one hydrogen atom being removed from the hydrogen atoms of one or more selected from R^{d4} to R^{d10} of the compound represented by Formula (KD2) below and a monovalent functional group formed as a result of one hydrogen atom being removed from the hydrogen atoms bonded to the atoms constituting a ring formed by R^{d6} and R^{d7} of the compound represented by Formula (KD2) below being bonded to each other or a ring formed by R^{d8} and R^{d9} of the compound represented by Formula (KD2) below being bonded to each other.

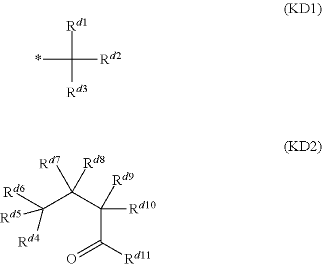

In Formula (KD1) above, R^{d1}, R^{d2}, and R^{d3} represent the same things as Rₖ₁, Rₖ₂, and Rₖ₃ in Formula (K1) above, respectively, and preferable examples thereof are also the same.

In Formula (KD2) above, R^{d4} and R^{d11} represent the same things as Rₖ₄ and Rₖ₅ in Formula (K2) above, respectively, and preferable examples thereof are also the same.

R^{d5} to R^{d10} each independently represent a hydrogen atom or a substituent. Examples of the substituent include, but are not limited to, a halogen atom, an alkyl group (linear, branched, or cyclic), and an alkoxy group (linear, branched, or cyclic). The number of carbon atoms included in the alkyl group or the alkyl group section of the alkoxy group is preferably, for example, 1 to 10, and is more preferably 1 to 6. The alkyl group and the alkoxy group may further have a substituent.

R^{d6} and R^{d7} or R^{d8} and R^{d9} may be bonded to each other to form a ring. The ring formed as a result of R^{d6} and R^{d7} being bonded to each other and the ring formed as a result of R^{d8} and R^{d9} being bonded to each other are not limited and may be either alicyclic or aromatic rings. These rings are preferably aromatic rings. The aromatic rings are preferably, for example, benzene rings. In the case where R^{d6} and R^{d7} are bonded to each other to form an aromatic ring (e.g., benzene ring), R^{d5} and R^{d8} serve as direct bonds. In the case where R^{d8} and R^{d9} are bonded to each other to form an aromatic ring (e.g., benzene ring), R^{d7} and R^{d10} serve as direct bonds.

In the compound represented by Formula (KD2) above, at least one of R^{d5} to R^{d10} represents a hydrogen atom, or a pair of R^{d6} and R^{d7} or a pair of R^{d8} and R^{d9} are bonded to each other to form a ring and the atoms constituting the ring has one or more hydrogen atoms.

Another preferable example of the polarity reduction group the polarity of which reduces by the mechanism illustrated in Formula (K2) above is the group represented by Formula (KD2-1) below.

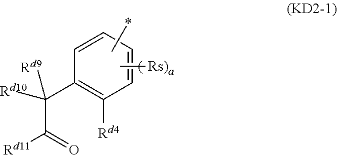

In Formula (KD2-1), R^{d4} and R^{d9} to R^{d11} represent the same things as R^{d4} and R^{d9} to R^{d11} in Formula (KD2) above, respectively, and preferable examples thereof are also the same.

Rs represents a substituent. Examples of the substituent include, but are not limited to, a halogen atom, an alkyl group, and an alkoxy group. The number of carbon atoms included in the alkyl group and the alkyl group section of the alkoxy group is, for example, preferably 1 to 10 and is more preferably 1 to 6.
a represents an integer of 0 to 3.
* represents a bond position.

### Mechanism in Which Polarity Reduction Group Is Onium Salt Group That Becomes Decomposed by Action of Exposure and Polarity Is Reduced as Result of Group Decomposing by Exposure.

The onium salt group decomposable by the action of exposure is described below.

The onium salt group is a group having an onium salt structure (i.e., a group having a structural site having an ion pair of a cation and an anion) and is preferably a group having a structural site represented by “Xⁿ⁻ nM⁺”, where n represents, for example, an integer of 1 to 3 and is preferably 1 or 2, M⁺ represents a structural site including a positively charged atom or atomic group, and Xⁿ⁻ represents a structural site including a negatively charged atom or atomic group. The anion included in the onium salt group is preferably a non-nucleophilic anion (i.e., anion having significantly poor ability to cause a nucleophilic reaction).

In particular, the onium salt group is more preferably a group selected from the group consisting of the groups represented by Formulae (O1) and (O2) below.

*—X_{A}ⁿ⁻nM_{A}⁺ (O1)

*-M_{B}⁺X_{B}⁻ (O2)

In Formula (O1), X_{A}ⁿ⁻ represents a monovalent anionic group having n-valent charge, M_{A}⁺ represents an organic cation, and n represents 1 or 2.

In Formula (O2), M_{B}⁺ represents a monovalent organic cationic group.

The organic anions represented by X_{A}ⁿ⁻ and X_{B}⁻ are preferably non-nucleophilic anions (i.e., anions having significantly poor ability to cause a nucleophilic reaction).

Details of the groups represented by Formulae (O1) and (O2) below are described below.

In Formula (O1), X_{A}ⁿ⁻ represents a monovalent anionic group having n-valent charge, where n is one or two.

The monovalent anionic group having n-valent charge, which is represented by X_{A}ⁿ⁻ (where n is one or two), is not limited and is preferably, for example, a group selected from the group consisting of the groups represented by Formulae (B-1) to (B-15) below. Note that the groups represented by Formulae (B-1) to (B-14) below correspond to a monovalent anionic group having monovalent charge, while the group represented by Formula (B-15) below corresponds to a monovalent anionic group having divalent charge.

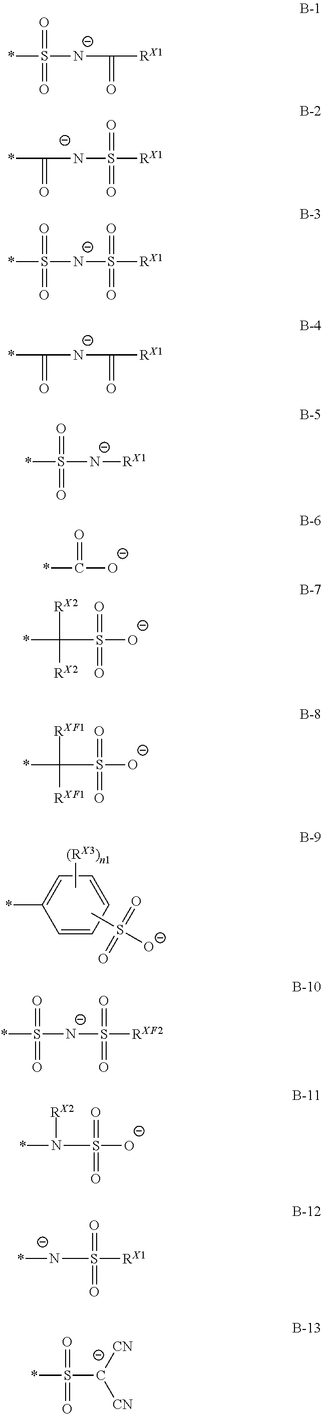

*—O⁻ (B-14)

In Formulae (B-1) to (B-14), * represents a bond position.

In Formulae (B-1) to (B-5) and (B-12), R^{X1} each independently represents a monovalent organic group.

In Formulae (B-7) and (B-11), R^{X2}'s each independently represent a hydrogen atom or a substituent other than a fluorine atom or a perfluoroalkyl group. The two R^{X2}'s in Formula (B-7) may be identical to or different from each other.

In Formula (B-8), R^{XF1} represents a hydrogen atom, a fluorine atom, or a perfluoroalkyl group. At least one of the two R^{XF1}'s is a fluorine atom or a perfluoroalkyl group. The two R^{XF1}'s in Formula (B-8) may be identical to or different from each other.

In Formula (B-9), R^{X3} represents a hydrogen atom, a halogen atom, or a monovalent organic group, and n1 represents an integer of 0 to 4. In the case where n1 is an integer of 2 to 4, a plurality of R^{X3}'s may be identical to or different from one another.

In Formula (B-10), R^{XF2} represents a fluorine atom or a perfluoroalkyl group.

In Formula (B-14), the group that is to be bonded to the bond position represented by * is preferably an unsubstituted or substituted phenylene group. Examples of the substituent that the phenylene group may have include a halogen atom.

In Formulae (B-1) to (B-5) and (B-12), R^{X1} each independently represents a monovalent organic group.

R^{X1} is preferably an alkyl group (either linear or branched, the number of carbon atoms is preferably 1 to 15), a cycloalkyl group (either monocyclic or polycyclic, the number of carbon atoms is preferably 3 to 20), or an aryl group (either monocyclic or polycyclic, the number of carbon atoms is preferably 6 to 20). The group represented by R^{X1} may have a substituent.

Note that, in Formula (B-5), an atom included in R^{X1} which is directly bonded to N-is preferably neither the carbon atom of —CO— nor the sulfur atom of —SO₂—.

The cycloalkyl group represented by R^{X1} may be either monocyclic or polycyclic.

Examples of the cycloalkyl group represented by R^{X1} include a norbornyl group and an adamantyl group.

The substituent that the cycloalkyl group represented by R^{X1} may have is not limited and is preferably an alkyl group (either linear or branched, the number of carbon atoms is preferably 1 to 5). One or more carbon atoms constituting the ring of the cycloalkyl group represented by R^{X1} may be replaced with a carbonyl carbon atom. The number of carbon atoms included in the alkyl group represented by R^{X1} is preferably 1 to 10 and is more preferably 1 to 5.

The substituent that the alkyl group represented by R^{X1} may have is not limited and is preferably, for example, a cycloalkyl group, a fluorine atom, or a cyano group.

Examples of the cycloalkyl group used as a substituent include the cycloalkyl group described above as for the case where R^{X1} is a cycloalkyl group.

In the case where the alkyl group represented by R^{X1} has a fluorine atom as a substituent, the alkyl group may be a perfluoroalkyl group.

One or more —CH₂— groups of the alkyl group represented by R^{X1} may be replaced with a carbonyl group.

The aryl group represented by R^{X1} is preferably a benzene ring group.

The substituent that the aryl group represented by R^{X1} may have is not limited and is preferably an alkyl group, a fluorine atom, or a cyano group.

Examples of the alkyl group used as a substituent include the alkyl group described above as for the case where R^{X1} is an alkyl group.

In Formulae (B-7) and (B-11), R^{X2}'s each independently represent a hydrogen atom or a substituent other than a fluorine atom or a perfluoroalkyl group. The two R^{X2}'s in Formula (B-7) may be identical to or different from each other.

The substituent other than a fluorine atom or a perfluoroalkyl group, which is represented by R^{X2}, is preferably an alkyl other than a perfluoroalkyl group or cycloalkyl group.

Examples of the above alkyl group include the alkyl groups described above as for the case where R^{X1} is an alkyl group except for perfluoroalkyl groups. The above alkyl group preferably does not have a fluorine atom.

Examples of the above cycloalkyl group include the cycloalkyl groups described above as for the case where R^{X1} is a cycloalkyl group. The above cycloalkyl group preferably does not have a fluorine atom.

In Formula (B-8), R^{XF1} represents a hydrogen atom, a fluorine atom, or a perfluoroalkyl group. At least one of the R^{XF1}'s is a fluorine atom or a perfluoroalkyl group. The two R^{XF1}'s in Formula (B-8) may be identical to or different from each other. The number of carbon atoms included in the perfluoroalkyl group represented by R^{XF1} is preferably 1 to 15, is more preferably 1 to 10, and is further preferably 1 to 6.

In Formula (B-9), R^{X3} represents a hydrogen atom, a halogen atom, or a monovalent organic group. Examples of the halogen atom represented by R^{X3} include a fluorine atom, a chlorine atom, a bromine atom, and an iodine atom. Among these, a fluorine atom is preferable.

The monovalent organic group represented by R^{X3} is the same as the monovalent organic group represented by R^{X1} above.
n1 represents an integer of 0 to 4.
n1 is preferably an integer of 0 to 2 and is more preferably 0 or 1. In the case where n1 is an integer of 2 to 4, a plurality of R^{X3}'s may be identical to or different from one another.

In Formula (B-10), R^{XF2} represents a fluorine atom or a perfluoroalkyl group.

The number of carbon atoms included in the perfluoroalkyl group represented by R^{XF2} is preferably 1 to 15, is more preferably 1 to 10, and is further preferably 1 to 6.

*−B_{M1}−L_{M}−B_{M2} (B-15)

In Formula (B-15), BMI represents a divalent anionic group represented by any one of Formulae (BB-1) to (BB-4) below, LM represents a single bond or a divalent linking group, and B_{M2} represents any one selected from the group consisting of the group represented by Formulae (B-1) to (B-14) above.

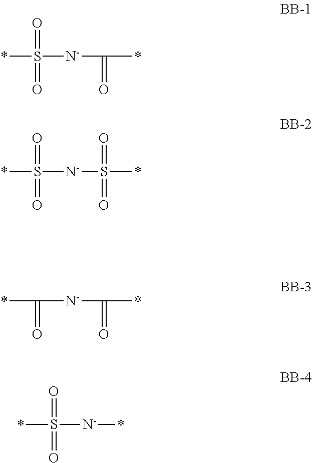 [SMILES: *C(=O)[N-]S(*)(=O)=O ; *S(=O)(=O)[N-]S(*)(=O)=O ; *C(=O)[N-]C(*)=O ; *[N-]S(*)(=O)=O]

Examples of the divalent linking group represented by L_{M} include, but are not limited to, —CO—, —NR—, —O—, —S—, —SO—, —SO₂—, an alkylene group (preferably has 1 to 6 carbon atoms, either linear or branched), a cycloalkylene group (preferably has 3 to 15 carbon atoms), an alkenylene group (preferably has 2 to 6 carbon atoms), a divalent aliphatic heterocyclic group (preferably a five-to ten-membered ring, more preferably a five-to seven-membered ring, and further preferably a five- or six-membered ring that have at least one N, O, S, or Se atom in the ring structure), a divalent aromatic heterocyclic group (preferably a five-to ten-membered ring, more preferably a five-to seven-membered ring, and further preferably a five- or six-membered ring that have at least one N, O, S, or Se atom in the ring structure), a divalent aromatic hydrocarbon ring group (preferably a six-to ten-membered ring and is further preferably a six-membered ring), and a divalent linking group formed as a result of a plurality of the above groups being combined with one another. Examples of the group represented by R above include a hydrogen atom and a monovalent organic group. The above monovalent organic group is not limited and is preferably, for example, an alkyl group (preferably having 1 to 6 carbon atoms).

The alkylene group, the cycloalkylene group, the alkenylene group, the divalent aliphatic heterocyclic group, the divalent aromatic heterocyclic group, and the divalent aromatic hydrocarbon ring group may have a substituent. Examples of the substituent include a halogen atom (preferably, a fluorine atom).

In particular, the divalent linking group represented by LM is preferably an alkylene group. The alkylene group is preferably substituted with a fluorine atom. That is, the alkylene group may be a perfluoro group.

The organic cation represented by M_{A}⁺ in Formula (O1) is preferably an organic cation represented by Formula (ZaI) below (hereinafter, referred to as “cation (ZaI)”) or an organic cation represented by Formula (ZaII) below (hereinafter, referred to as “cation (ZaII)”).

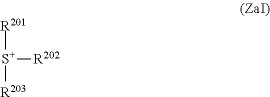

R²⁰⁴—I⁺—R²⁰⁵ (ZaII)

In Formula (ZaI) above,

R²⁰¹, R²⁰², and R²⁰³ each independently represent an organic group.

The number of carbon atoms included in each of the organic groups represented by R²⁰¹, R²⁰², and R²⁰³ is commonly 1 to 30 and is preferably 1 to 20. Two of R²⁰¹ to R²⁰³ may be bonded to each other to form a ring structure, and the ring may include an oxygen atom, a sulfur atom, an ester group, an amide group, or a carbonyl group. Examples of the group formed as a result of two of R²⁰¹ to R²⁰³ being bonded to each other include an alkylene group (e.g., butylene group or pentylene group) and —CH₂—CH₂—O—CH₂—CH₂—.

Preferable examples of the organic cation represented by Formula (ZaI) include a cation (ZaI-1), a cation (ZaI-2), an organic cation represented by Formula (ZaI-3b) (hereinafter, referred to as “cation (ZaI-3b)”), and an organic cation represented by Formula (ZaI-4b) (hereinafter, referred to as “cation (ZaI-4b)”), which are described below.

The cation (ZaI-1) is described below.

The cation (ZaI-1) is an arylsulfonium cation represented by Formula (ZaI) above in which at least one of R²⁰¹ to R²⁰³ is an aryl group.

All of R²⁰¹ to R²⁰³ of the arylsulfonium cation may be an aryl group. In another case, only some of R²⁰¹ to R²⁰³ may be an aryl group, while the other is an alkyl group or a cycloalkyl group.

Alternatively, only one of R²⁰¹ to R²⁰³ may be an aryl group while the other two are bonded to each other to form a ring structure, and the ring may include an oxygen atom, a sulfur atom, an ester group, an amide group, or a carbonyl group. Examples of the group formed as a result of two of R²⁰¹ to R²⁰³ being bonded to each other include an alkylene group (e.g., a butylene group, a pentylene group, or —CH₂—CH₂—O—CH₂—CH₂—) in which one or more methylene groups may be replaced with an oxygen atom, a sulfur atom, an ester group, an amide group, and/or a carbonyl group.

Examples of the arylsulfonium cation include a triarylsulfonium cation, a diarylalkylsulfonium cation, an aryldialkylsulfonium cation, a diarylcycloalkylsulfonium cation, and an aryldicycloalkylsulfonium cation.

The aryl group included in the arylsulfonium cation is preferably a phenyl group or a naphthyl group and is more preferably a phenyl group. The aryl group may be an aryl group having a heterocyclic structure that has an oxygen, nitrogen, or sulfur atom. Examples of the heterocyclic structure include a pyrrole residue, a furan residue, a thiophene residue, an indole residue, a benzofuran residue, and a benzothiophene residue. In the case where the arylsulfonium cation has two or more aryl groups, the aryl groups may be identical to or different from one another.

The alkyl or cycloalkyl group that the arylsulfonium cation may have as needed is preferably a linear alkyl group having 1 to 15 carbon atoms, a branched alkyl group having 3 to 15 carbon atoms, or a cycloalkyl group having 3 to 15 carbon atoms and is more preferably, for example, a methyl group, an ethyl group, a propyl group, an n-butyl group, a sec-butyl group, a t-butyl group, a cyclopropyl group, a cyclobutyl group, and a cyclohexyl group.

The substituents that the aryl, alkyl, and cycloalkyl groups represented by R²⁰¹ to R²⁰³ may have are preferably each independently an alkyl group (e.g., having 1 to 15 carbon atoms), an cycloalkyl group (e.g., having 3 to 15 carbon atoms), an aryl group (e.g., having 6 to 14 carbon atoms), an alkoxy group (e.g., having 1 to 15 carbon atoms), a cycloalkylalkoxy group (e.g., having 1 to 15 carbon atoms), a halogen atom (e.g., fluorine or iodine atom), a hydroxyl group, a carboxyl group, an ester group, a sulfinyl group, a sulfonyl group, an alkylthio group, and a phenylthio group.

The above substituents may further have a substituent when possible. For example, it is also preferable that the above alkyl group have a halogen atom that serves as a substituent to form a halogenated alkyl group, such as a trifluoromethyl group.

It is also preferable that the above substituents be used in combination with one another to form an acid-decomposable group. Examples of the acid-decomposable group are the same as the acid-decomposable group described above as an example of the polarity reduction group.

The cation (ZaI-2) is described below.

The cation (ZaI-2) is a cation represented by Formula (ZaI) above in which R²⁰¹ to R²⁰³ each independently represent an organic group that does not have an aromatic ring. Note that the term “aromatic ring” above also refers to an aromatic ring having a hetero atom.

The number of carbon atoms included in the organic group that does not have an aromatic ring, which is represented by R²⁰¹ to R²⁰³, is commonly 1 to 30 and is preferably 1 to 20.

R²⁰¹ to R²⁰³ are preferably each independently an alkyl group, a cycloalkyl group, an allyl group, or a vinyl group, are more preferably each independently a linear or branched 2-oxoalkyl group, a 2-oxocycloalkyl group, or an alkoxycarbonylmethyl group, and are further preferably each independently a linear or branched 2-oxoalkyl group.

Examples of the alkyl and cycloalkyl groups represented by R²⁰¹ to R²⁰³ include linear alkyl groups having 1 to 10 carbon atoms and branched alkyl groups having 3 to 10 carbon atoms (e.g., a methyl group, an ethyl group, a propyl group, a butyl group, and a pentyl group); and cycloalkyl groups having 3 to 10 carbon atoms (e.g., a cyclopentyl group, a cyclohexyl group, and a norbornyl group).

The groups represented by R²⁰¹ to R²⁰³ may be further substituted with a halogen atom, an alkoxy group (e.g., having 1 to 5 carbon atoms), a hydroxyl group, a cyano group, or a nitro group.

It is also preferable that the substituents of R²⁰¹ to R²⁰³ be each independently combined with one another to form an acid-decomposable group.

The cation (ZaI-3b) is described below.

The cation (ZaI-3b) is a cation represented by Formula (ZaI-3b) below.

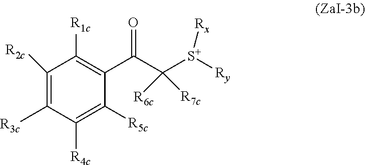

In Formula (ZaI-3b),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group;

R_{6c} and R_{7c} each independently represent a hydrogen atom, an alkyl group (e.g., t-butyl group), a cycloalkyl group, a halogen atom, a cyano group, or an aryl group;

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

It is also preferable that the substituents of R_{1c} to R_{7c} and Rₓ and R_{y} be each independently combined with one another to form an acid-decomposable group.

Two or more of R_{1c} to R_{5c}, R_{5c} and R_{6c}, R_{6c} and R_{7c}, R_{5c} and Rₓ, and Rₓ and R_{y} may be bonded to each other to form a ring. These rings may each independently include an oxygen atom, a sulfur atom, a ketone group, an ester bond, or an amide bond.

Examples of the above rings include aromatic and non-aromatic hydrocarbon rings, aromatic and non-aromatic hetero rings, and polycyclic fused rings formed by the combination of two or more of the above rings. The number of the member atoms forming the rings is, for example, 3 to 10, is preferably 4 to 8, and is more preferably 5 or 6.

Examples of the group formed as a result of two or more of R_{1c} to R_{5c} being bonded to one another, the group formed as a result of R_{6c} and R_{7c} being bonded to each other, and the group formed as a result of Rₓ and R_{y} being bonded to each other include alkylene groups, such as a butylene group and a pentylene group. A methylene group included in the above alkylene group may be replaced with a hetero atom, such as an oxygen atom.

The group formed as a result of R_{5c} and R_{6c} being bonded to each other and the group formed as a result of R_{5c} and Rₓ being bonded to each other are each preferably a single bond or an alkylene group. Examples of the alkylene group include a methylene group and an ethylene group.

R_{1c} to R_{5c}, R_{6c}, R_{7c}, Rₓ, R_{y}, the ring formed as a result of two or more of R_{1c} to R_{5c} being bonded to one another, the ring formed as a result of R_{5c} and R_{6c} being bonded to each other, the ring formed as a result of Roc and Rye being bonded to each other, the ring formed as a result of R_{5c} and Rₓ being bonded to each other, and the ring formed as a result of Rₓ and R_{y} being bonded to each other may have a substituent.

The cation (ZaI-4b) is described below.

The cation (ZaI-4b) is a cation represented by Formula (ZaI-4b) below.

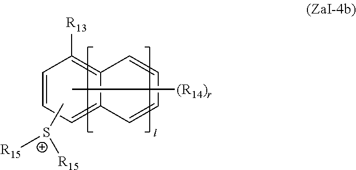

In Formula (ZaI-4b),

l represents an integer of 0 to 2;

r represents an integer of 0 to 8;

R₁₃ represents a hydrogen atom, a halogen atom (e.g., a fluorine or iodine atom), a hydroxyl group, an alkyl group, a halogenated alkyl group, an alkoxy group, a carboxyl group, an alkoxycarbonyl group, or a group having a cycloalkyl group (either a cycloalkyl group or a group including a cycloalkyl group section), and the above groups may have a substituent;

R₁₄ represents a hydroxyl group, a halogen atom (e.g., a fluorine or iodine atom), an alkyl group, a halogenated alkyl group, an alkoxy group, an alkoxycarbonyl group, an alkylcarbonyl group, an alkylsulfonyl group, a cycloalkylsulfonyl group, or a group having a cycloalkyl group (either a cycloalkyl group or a group including a cycloalkyl group section), the above groups may have a substituent, and, in the case where a plurality of R₁₄'s are present, R₁₄'s each independently represent any of the above groups, such as a hydroxyl group; and

R₁₅'s each independently represent an alkyl group, a cycloalkyl group, or a naphthyl group, two R₁₅'s may be bonded to each other to form a ring and, in the case where two R₁₅'s are bonded to each other to form a ring, the skeleton of the ring may include a hetero atom, such as an oxygen or nitrogen atom. In one embodiment, it is preferable that two R₁₅'s be alkylene groups that are bonded to each other to form a ring structure. Note that the alkyl group, the cycloalkyl group, the naphthyl group, and the ring formed as a result of two R₁₅'s being bonded to each other may have a substituent.

In Formula (ZaI-4b), the alkyl groups represented by R₁₃, R₁₄, and R₁₅ are preferably each linear or branched. The number of carbon atoms included in each of the above alkyl groups is preferably 1 to 10. The alkyl groups are more preferably each a methyl group, an ethyl group, an n-butyl group, or a t-butyl group.

It is also preferable that the substituents of R₁₃ to R₁₅, Rₓ, and R_{y} be each independently combined with one another to form an acid-decomposable group.

Formula (ZaII) above is described below.

In Formula (ZaII), R²⁰⁴ and R²⁰⁵ each independently represent an aryl group, an alkyl group, or a cycloalkyl group.

The aryl groups represented by R²⁰⁴ and R²⁰⁵ are each preferably a phenyl group or a naphthyl group and are each more preferably a phenyl group. The aryl groups represented by R²⁰⁴ and R²⁰⁵ may be aryl groups having a hetero ring having an oxygen atom, a nitrogen atom, a sulfur atom, or the like. Examples of the skeleton of the aryl group which has a hetero ring include a pyrrole, a furan, a thiophene, an indole, a benzofuran, and a benzothiophene.

Preferable examples of the alkyl and cycloalkyl groups represented by R²⁰⁴ and R²⁰⁵ include linear alkyl groups having 1 to 10 carbon atoms and branched alkyl groups having 3 to 10 carbon atoms (e.g., a methyl group, an ethyl group, a propyl group, a butyl group, and a pentyl group); and cycloalkyl groups having 3 to 10 carbon atoms (e.g., a cyclopentyl group, a cyclohexyl group, and a norbornyl group).

The aryl, alkyl, and cycloalkyl groups represented by R²⁰⁴ and R²⁰⁵ may each independently have a substituent. Examples of the substituent that the aryl, alkyl, and cycloalkyl groups represented by R²⁰⁴ and R²⁰⁵ may have include an alkyl group (e.g., having 1 to 15 carbon atoms), a cycloalkyl group (e.g., having 3 to 15 carbon atoms), an aryl group (e.g., having 6 to 15 carbon atoms), an alkoxy group (e.g., having 1 to 15 carbon atoms), a halogen atom, a hydroxyl group, and a phenylthio group. It is also preferable that the substituents of R²⁰⁴ and R²⁰⁵ be each independently combined with one another to form an acid-decomposable group.

The monovalent organic cationic group represented by M_{B}⁺ in Formula (O2) is preferably an organic cationic group represented by Formula (ZBI) or (ZBII) below.

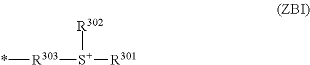

*—R³⁰⁵—I⁺—R³⁰⁴ (ZBII)

In Formula (ZBI) above, R³⁰¹ and R³⁰² each independently represent an organic group. The number of carbon atoms included in each of the organic groups represented by R³⁰¹ and R³⁰² is commonly 1 to 30 and is preferably 1 to 20. R³⁰³ represents a divalent linking group. Two of R³⁰¹ to R³⁰³ may be bonded to each other to form a ring structure, and the ring may include an oxygen atom, a sulfur atom, an ester group, an amide group, or a carbonyl group. Examples of the group formed as a result of two of R³⁰¹ to R³⁰³ being bonded to each other include an alkylene group (e.g., butylene group or pentylene group) and —CH₂—CH₂—O—CH₂—CH₂—.

The organic groups represented by R³⁰¹ and R³⁰² are preferably, but not limited to, each an alkyl group, a cycloalkyl group, or an aryl group.

The aryl group is preferably a phenyl group or a naphthyl group and is more preferably a phenyl group. The aryl group may be an aryl group having a heterocyclic structure that has an oxygen, nitrogen, or sulfur atom. Examples of the heterocyclic structure include a pyrrole residue, a furan residue, a thiophene residue, an indole residue, a benzofuran residue, and a benzothiophene residue.

The alkyl or cycloalkyl group is preferably a linear alkyl group having 1 to 15 carbon atoms, a branched alkyl group having 3 to 15 carbon atoms, or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, and a cyclohexyl group.

The substituents that the aryl, alkyl, and cycloalkyl groups represented by R³⁰¹ and R³⁰² may have are preferably each independently an alkyl group (e.g., having 1 to 15 carbon atoms), an cycloalkyl group (e.g., having 3 to 15 carbon atoms), an aryl group (e.g., having 6 to 14 carbon atoms), an alkoxy group (e.g., having 1 to 15 carbon atoms), a cycloalkylalkoxy group (e.g., having 1 to 15 carbon atoms), a halogen atom, a hydroxyl group, and a phenylthio group.

The divalent linking group represented by R³⁰³ is not limited and is preferably an alkylene group, a cycloalkylene group, an aromatic group, or a group formed by the combination of two or more of the above groups.

The above alkylene group may be either linear or branched. The alkylene group preferably has 1 to 20 carbon atoms and more preferably has 1 to 10 carbon atoms.

The above cycloalkylene group may be either monocyclic or polycyclic. The cycloalkylene group preferably has 3 to 20 carbon atoms and more preferably has 3 to 10 carbon atoms.

The above aromatic group is a divalent aromatic group. The aromatic group preferably has 6 to 20 carbon atoms and more preferably has 6 to 15 carbon atoms.

Examples of the aromatic ring constituting the aromatic group include, but are not limited to, an aromatic ring having 6 to 20 carbon atoms, and specific examples thereof include a benzene ring, a naphthalene ring, an anthracene ring, and a thiophene ring. The above aromatic ring is preferably a benzene or naphthalene ring and is more preferably a benzene ring.

The above alkylene, cycloalkylene, and aromatic groups may further have a substituent.

In Formula (ZBII) above, R³⁰⁴ represents an aryl group, an alkyl group, or a cycloalkyl group, and R³⁰⁵ represents a divalent linking group.

The aryl group represented by R³⁰⁴ is preferably a phenyl group or a naphthyl group and is more preferably a phenyl group. The aryl group represented by R³⁰⁴ may be an aryl group having a hetero ring having an oxygen atom, a nitrogen atom, a sulfur atom, or the like. Examples of the skeleton of the aryl group which has a hetero ring include a pyrrole, a furan, a thiophene, an indole, a benzofuran, and a benzothiophene.

Preferable examples of the alkyl and cycloalkyl groups represented by R³⁰⁴ include linear alkyl groups having 1 to 10 carbon atoms and branched alkyl groups having 3 to 10 carbon atoms (e.g., a methyl group, an ethyl group, a propyl group, a butyl group, and a pentyl group); and cycloalkyl groups having 3 to 10 carbon atoms (e.g., a cyclopentyl group, a cyclohexyl group, and a norbornyl group).

The aryl, alkyl, and cycloalkyl groups represented by R³⁰⁴ may each independently have a substituent. Examples of the substituent that the aryl, alkyl, and cycloalkyl groups represented by R³⁰⁴ may have include an alkyl group (e.g., having 1 to 15 carbon atoms), a cycloalkyl group (e.g., having 3 to 15 carbon atoms), an aryl group (e.g., having 6 to 15 carbon atoms), an alkoxy group (e.g., having 1 to 15 carbon atoms), a halogen atom, a hydroxyl group, and a phenylthio group.

The divalent linking group represented by R³⁰⁵ is preferably, but not limited to, an alkylene group, a cycloalkylene group, an aromatic group, or a group formed by the combination of two or more of the above groups.

The above alkylene group may be either linear or branched. The alkylene group preferably has 1 to 20 carbon atoms and more preferably has 1 to 10 carbon atoms.

The above cycloalkylene group may be either monocyclic or polycyclic. The cycloalkylene group preferably has 3 to 20 carbon atoms and more preferably has 3 to 10 carbon atoms.

The above aromatic group is a divalent aromatic group. The aromatic group preferably has 6 to 20 carbon atoms and more preferably has 6 to 15 carbon atoms.

Examples of the aromatic ring constituting the aromatic group include, but are not limited to, an aromatic ring having 6 to 20 carbon atoms, and specific examples thereof include a benzene ring, a naphthalene ring, an anthracene ring, and a thiophene ring. The aromatic ring constituting the aromatic group is preferably a benzene or naphthalene ring and is more preferably a benzene ring.

The above alkylene, cycloalkylene, and aromatic groups may further have a substituent.

The organic anion represented by X_{B}⁻ in Formula (O2) is preferably a non-nucleophilic anion (i.e., an anion having significantly poor ability to cause a nucleophilic reaction).

Examples of the non-nucleophilic anion include sulfonate anions (e.g., an aliphatic sulfonate anion, an aromatic sulfonate anion, and a camphor sulfonate anion), carboxylate anions (e.g., an aliphatic carboxylate anion, an aromatic carboxylate anion, and an aralkyl carboxylate anion), sulfonylimide anions, bis(alkylsulfonyl)imide anions, and tris(alkylsulfonyl)methide anions.

The aliphatic sections of the aliphatic sulfonate anion and the aliphatic carboxylate anion may be each either an alkyl or cycloalkyl group and are preferably each a linear or branched alkyl group having 1 to 30 carbon atoms or a cycloalkyl group having 3 to 30 carbon atoms.

The above alkyl group may be, for example, a fluoroalkyl group. The fluoroalkyl group may, but does not necessarily, have a substituent other than a fluorine atom and may be a perfluoroalkyl group.

The aryl groups included in the aromatic sulfonate anion and the aromatic carboxylate anion are preferably each an aryl group having 6 to 14 carbon atom, and examples thereof include a phenyl group, a tolyl group, and a naphthyl group.

The above alkyl, cycloalkyl, and aryl groups may have a substituent. Specific examples of the substituent include, but are not limited to, a nitro group, a halogen atom, such as a fluorine or chlorine atom, a carboxyl group, a hydroxyl group, an amino group, a cyano group, an alkoxy group (preferably having 1 to 15 carbon atoms), an alkyl group (preferably having 1 to 10 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), and an aryloxysulfonyl group (preferably having 6 to 20 carbon atoms).

The aralkyl group included in the aralkyl carboxylate anion is preferably an aralkyl group having 7 to 14 carbon atoms, and examples thereof include a benzyl group, a phenethyl group, a naphthylmethyl group, a naphthylethyl group, and a naphthylbutyl group.

Examples of the sulfonylimide anions include a saccharin anion.

The alkyl groups included in the bis(alkylsulfonyl)imide anions and the tris(alkylsulfonyl)methide anions are preferably each an alkyl group having 1 to 5 carbon atoms. Examples of the substituent that the above alkyl groups may have include a halogen atom, an alkyl group substituted with a halogen atom, an alkoxy group, an alkylthio group, an alkyloxysulfonyl group, an aryloxysulfonyl group, and a cycloalkyl aryloxysulfonyl group. Among these, a fluorine atom and an alkyl group substituted with a fluorine atom are preferable.

The alkyl groups included in the bis(alkylsulfonyl)imide anion may be bonded to each other to form a ring structure. This increases acid strength.

The non-nucleophilic anion is preferably an aliphatic sulfonate anion in which the sulfonic acid is substituted with a fluorine atom at least at the α-position, an aromatic sulfonate anion substituted with a fluorine atom or a group having a fluorine atom, a bis(alkylsulfonyl) imide anion in which the alkyl group is substituted with a fluorine atom, or a tris (alkylsulfonyl) methide anion in which the alkyl group is substituted with a fluorine atom.

The organic anion represented by X_{B}⁻ in Formula (O2) is also preferably, for example, organic anion represented by Formula (DA) below.

A₃₁^{e}−Lₐ₁−Rₐ₁ (DA)

In Formula (DA), A₃₁⁻ represents an anionic group, Rₐ₁ represents a hydrogen atom or a monovalent organic group, and Lₐ₁ represents a single bond or a divalent linking group.

A₃₁⁻ represents an anionic group. The anionic group represented by A₃₁⁻ is not limited and is preferably, for example, a group selected from the group consisting of the groups represented by Formulae (B-1) to (B-14) above.

The monovalent organic group represented by Rₐ₁ is not limited, commonly has 1 to 30 carbon atoms, and preferably has 1 to 20 carbon atoms.

Rₐ₁ is preferably an alkyl group, a cycloalkyl group, or an aryl group.

The above alkyl group may be either linear or branched. The alkyl group is preferably an alkyl group having 1 to 20 carbon atoms, is more preferably an alkyl group having 1 to 15 carbon atoms, and is further preferably an alkyl group having 1 to 10 carbon atoms.

The above cycloalkyl group may be either monocyclic or polycyclic. The cycloalkyl group is preferably a cycloalkyl group having 3 to 20 carbon atoms, is more preferably a cycloalkyl group having 3 to 15 carbon atoms, and is further preferably a cycloalkyl group having 3 to 10 carbon atoms.

The above aryl group may be either monocyclic or polycyclic. The aryl group is preferably an aryl group having 6 to 20 carbon atoms, is more preferably an aryl group having 6 to 15 carbon atoms, and is further preferably an aryl group having 6 to 10 carbon atoms.

The cycloalkyl group may include a hetero atom that serves as a ring-member atom.

Examples of the hetero atom include, but are not limited to, a nitrogen atom and an oxygen atom.

The cycloalkyl group may include a carbonyl bond (>C═O) that serves as a ring-member atom.

The above alkyl, cycloalkyl, and aryl groups may further have a substituent.

The divalent linking group represented by Lₐ₁ is not limited and is an alkylene group, a cycloalkylene group, an aromatic group, —O—, —CO—, —COO—, or a group formed by the combination of two or more of the above groups.

The above alkylene group may be either linear or branched. The alkylene group preferably has 1 to 20 carbon atoms and more preferably has 1 to 10 carbon atoms.

The above cycloalkylene group may be either monocyclic or polycyclic. The cycloalkylene group preferably has 3 to 20 carbon atoms and more preferably has 3 to 10 carbon atoms.

The above aromatic group is a divalent aromatic group. The aromatic group preferably has 6 to 20 carbon atoms and more preferably has 6 to 15 carbon atoms.

Examples of the aromatic ring constituting the aromatic group include, but are not limited to, an aromatic ring having 6 to 20 carbon atoms, and specific examples thereof include a benzene ring, a naphthalene ring, an anthracene ring, and a thiophene ring. The aromatic ring constituting the aromatic group is preferably a benzene or naphthalene ring and is more preferably a benzene ring.

The above alkylene, cycloalkylene, and aromatic groups may further have a substituent. The substituent is preferably a halogen atom.

A₃₁⁻ and Rₐ₁ may be bonded to each other to form a ring.

Mechanism in which Polarity Reduction Group is Acid-Decomposable Group Including Polar Group and Protecting Group that Protects Polar Group, the Protecting Group being Eliminated by Action of Acid, and Polar Group Generated Subsequent to Acid Decomposition is More Hydrophobic than Acid-Decomposable Group Prior to Acid Decomposition

Examples of the polarity reduction group include an acid-decomposable group including a polar group and a protecting group that protects the polar group, the protecting group being eliminated by the action of an acid, and the polar group generated subsequent to the acid decomposition is more hydrophobic than the acid-decomposable group prior to the acid decomposition.

Examples of the acid-decomposable group include an acid-decomposable group having the following structure.

### Acid-Decomposable Group

The acid-decomposable group is a group that becomes decomposed to generate a polar group by the action of an acid and is typically constituted by a leaving group capable of being eliminated by the action of an acid and a polar group protected by the leaving group.

The polar group is preferably an alkali-soluble group, and examples thereof include the following acidic groups and alcoholic hydroxyl groups: a carboxyl group, a phenolic hydroxyl group, a fluorinated alcohol group, a sulfonate group, a phosphate group, a sulfonamide group, sulfonylimide group, an (alkylsulfonyl)(alkyl carbonyl)methylene group, a an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Among these, a carboxyl group, a phenolic hydroxyl group, a fluorinated alcohol group (preferably, a hexafluoroisopropanol group), and a sulfonate group are preferable as a polar group.

Examples of the leaving group capable of being eliminated by the action of an acid include the groups represented by Formulae (Y1) to (Y4) below.

—C(Rₓ₁)(Rₓ₂)(Rₓ₃) (Y1):

—C(═O)OC(Rₓ₁)(Rₓ₂)(Rₓ₃) (Y2):

—C(R₃₆)(R₃₇)(OR₃₈) (Y3):

—C(Rn)(H)(Ar) (Y4):

In Formulae (Y1) and (Y2), Rₓ₁ to Rₓ₃ each independently represent an alkyl group (linear or branched), a cycloalkyl group (monocyclic or polycyclic), an alkenyl group (linear or branched), or an aryl group (monocyclic or polycyclic). In the case where all of Rₓ₁ to Rₓ₃ are alkyl groups (linear or branched), it is preferable that at least two of Rₓ₁ to Rₓ₃ be methyl groups.

In particular, Rₓ₁ to Rₓ₃ are preferably each independently a linear or branched alkyl group and are more preferably each independently a linear alkyl group.

Two of Rₓ₁ to Rₓ₃ may be bonded to each other to form a monocyclic or polycyclic ring.

The alkyl groups represented by Rₓ₁ to Rₓ₃ are preferably each an alkyl group having 1 to 5 carbon atoms, such as a methyl group, an ethyl group, an n-propyl group, an isopropyl group, an n-butyl group, an isobutyl group, or a t-butyl group.

The cycloalkyl groups represented by Rₓ₁ to Rₓ₃ are preferably each a monocyclic cycloalkyl group, such as a cyclopentyl group or a cyclohexyl group, or a polycyclic cycloalkyl group, such as a norbornyl group, a tetracyclodecanyl group, a tetracyclododecanyl group, or an adamantyl group.

The aryl groups represented by Rₓ₁ to Rₓ₃ are preferably each an aryl group having 6 to 10 carbon atoms, such as a phenyl group, a naphthyl group, or an anthryl group.

The alkenyl groups represented by Rₓ₁ to Rₓ₃ are preferably each a vinyl group.

The ring formed as a result of two of Rₓ₁ to Rₓ₃ being bonded to each other is preferably a cycloalkyl group. The cycloalkyl group formed as a result of two of Rₓ₁ to Rₓ₃ being bonded to each other is preferably a monocyclic cycloalkyl group, such as a cyclopentyl group or a cyclohexyl group; or a polycyclic cycloalkyl group, such as a norbornyl group, a tetracyclodecanyl group, a tetracyclododecanyl group, or an adamantyl group. A monocyclic cycloalkyl group having 5 or 6 carbon atoms is more preferable.

In the cycloalkyl group formed as a result of two of Rₓ₁ to Rₓ₃ being bonded to each other, for example, one of the methylene groups forming the ring may be replaced with a hetero atom, such as an oxygen atom, a group having a hetero atom, such as a carbonyl group, or a vinylidene group. In the above cycloalkyl groups, one or more of the ethylene groups constituting the cycloalkane ring may be replaced with a vinylene group.

In the groups represented by Formulae (Y1) and (Y2), for example, it is preferable that Rₓ₁ be a methyl or ethyl group and Rₓ₂ and Rₓ₃ be bonded to each other to form the above cycloalkyl group.

In the case where the resist composition is, for example, a resist composition for use in exposure to EUV, it is also preferable that the alkyl, cycloalkyl, alkenyl, and aryl groups represented by Rₓ₁ to Rₓ₃ and the ring formed as a result of two of Rₓ₁ to Rₓ₃ being bonded to each other further have a fluorine or iodine atom as a substituent.

In Formula (Y3) above, R₃₆ to R₃₈ each independently represent a hydrogen atom or a monovalent organic group, and R₃₇ and R₃₈ may be bonded to each other to form a ring. Examples of the monovalent organic group include an alkyl group, a cycloalkyl group, an aryl group, an aralkyl group, and an alkenyl group. It is also preferable that R₃₆ be a hydrogen atom.

The above alkyl, cycloalkyl, aryl, and aralkyl groups may include a hetero atom, such as an oxygen atom, and/or a group having a hetero atom, such as a carbonyl group. For example, one or more methylene groups included in the alkyl, cycloalkyl, aryl, or aralkyl group may be replaced with a hetero atom, such as an oxygen atom, and/or a group having a hetero atom, such as a carbonyl group. Examples of such a group include an alkylcarbonyl group.

In the case where the resist composition is, for example, a resist composition that is to be exposed to EUV, it is also preferable that the monovalent organic groups represented by R³⁶ to R³⁸ and the ring formed as a result of R³⁷ and R³⁸ being bonded to each other further have a fluorine or iodine atom as a substituent.

The group represented by Formula (Y3) is preferably a group represented by Formula (Y3-1) below.

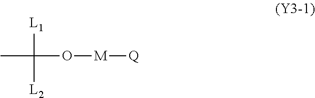

In Formula (Y3), L₁ and L₂ each independently represent a hydrogen atom, an alkyl group, a cycloalkyl group, an aryl group, or a group formed by the combination of the above groups (e.g., a group formed by the combination of an alkyl group and an aryl group).
M represents a single bond or a divalent linking group.
Q represents an alkyl group that may include a hetero atom, a cycloalkyl group that may include a hetero atom, an aryl group that may include a hetero atom, an amino group, an ammonium group, a mercapto group, a cyano group, an aldehyde group, or a group formed by the combination of the above groups (e.g., a group formed by the combination of an alkyl group and a cycloalkyl group).

For example, one of the methylene groups included in the alkyl or cycloalkyl group may be replaced with a hetero atom, such as an oxygen atom, or a group having a hetero atom, such as a carbonyl group.

It is preferable that one of L₁ and L₂ be a hydrogen atom and the other be an alkyl group, a cycloalkyl group, an aryl group, or a group formed by the combination of an alkylene group and an aryl group.

At least two of Q, M, and L₁ may be bonded to each other to form a ring (preferably, a five-membered or six-membered ring).

In order to form a fine pattern, L₂ is preferably a secondary or tertiary alkyl group and is more preferably a tertiary alkyl group. Examples of the secondary alkyl group include an isopropyl group, a cyclohexyl group, and a norbornyl group. Examples of the tertiary alkyl group include a tert-butyl group and an adamantane group. According to the above embodiment, the glass transition temperature (Tg) and activation energy of a resin including the above-described acid-decomposable group are increased. This may increase the hardness of the film and reduce the occurrence of fogging.

In the case where the resist composition is, for example, a resist composition that is to be exposed to EUV, it is also preferable that the alkyl, cycloalkyl, or aryl group represented by L₁ and L₂ or a group formed by the combination of the above groups further have a fluorine or iodine atom as a substituent. It is also preferable that the above alkyl, cycloalkyl, aryl, and aralkyl groups include a hetero atom other than a fluorine or iodine atom, such as an oxygen atom (e.g., one of the methylene groups included in the alkyl, cycloalkyl, aryl, or aralkyl group is replaced with a hetero atom, such as an oxygen atom, or a group having a hetero atom, such as a carbonyl group).

In the case where the resist composition is, for example, a resist composition that is to be exposed to EUV, it is also preferable that the hetero atom included in the alkyl group that may include a hetero atom, the cycloalkyl group that may include a hetero atom, the aryl group that may include a hetero atom, the amino group, the ammonium group, the mercapto group, the cyano group, the aldehyde group, or the group formed by the combination of the above groups, which is represented by Q, be a hetero atom selected from the group consisting of a fluorine atom, an iodine atom, and an oxygen atom.

In Formula (Y4) above, Ar represents an aromatic ring group, and Rn represents an alkyl group, a cycloalkyl group, or an aryl group. Rn and Ar may be bonded to each other to form a non-aromatic ring. Ar is more preferably an aryl group.

In the case where the resist composition is, for example, a resist composition that is to be exposed to EUV, it is also preferable that the aromatic ring group represented by Ar and the alkyl, cycloalkyl, or aryl group represented by Rn have a fluorine or iodine atom as a substituent.

In order to further enhance the capability of acid decomposition, in the case where a non-aromatic ring is directly bonded to the polar group (or the residue thereof) in the leaving group protecting the polar group, it is preferable that the atoms constituting the non-aromatic ring which are adjacent to the ring-member atom directly bonded to the polar group (or the residue thereof) do not have a halogen atom, such as a fluorine atom, as a substituent.

Examples of the leaving group capable of being eliminated by the action of an acid further include a 2-cyclopentenyl group having a substituent (e.g., an alkyl group), such as a 3-methyl-2-cyclopentenyl group; and a cyclohexyl group having a substituent (e.g., an alkyl group), such as a 1,1,4,4-tetramethylcyclohexyl group.

The acid-decomposable group that serves as a polarity reduction group is an acid-decomposable group such that the polar group generated subsequent to the acid decomposition is more hydrophobic than the acid-decomposable group prior to the acid decomposition.

Whether the polar group generated subsequent to the acid decomposition is more hydrophobic than the acid-decomposable group prior to the acid decomposition is determined on the basis of the log P (octanol/water partition coefficient) calculated on the basis of the chemical structures of the acid-decomposable group and the polar group. That is, the acid-decomposable group that serves as a polarity reduction group is an acid-decomposable group constituted by a protecting group capable of being eliminated by the action of an acid and a polar group protected by the protecting group, the acid-decomposable group having a smaller log P than the polar group from which the protecting group has been eliminated. The difference in log P between the acid-decomposable group and the polar group is not limited. The above difference is preferably, for example, 0.3 or more and is more preferably 0.6 or more.

### Interactive Group

The interactive group is described below.

The interactive group is a group that interacts with an onium salt compound, wherein the above interaction can be canceled by the action of exposure, an acid, a base, or heat.

The interactive group is preferably a group capable of forming an association structure by the interaction between the interactive group and an onium salt compound and is more preferably a group capable of serving as a proton donor or a proton acceptor. The group capable of serving as a proton donor is a group having a free hydrogen atom. Examples of the group capable of serving as proton acceptor include a group having a lone electron pair, such as a nitrogen atom and an oxygen atom. In particular, the interactive group is preferably a phenolic hydroxyl group, a carboxyl group, a sulfonate group, an amide group, or a sulfonamide group in order to further enhance the interaction between the interactive group and an onium salt compound.

Note that the term “phenolic hydroxyl group” used herein refers to a hydroxyl group substituted to one of the atoms constituting an aromatic ring.

The aromatic ring is not limited to a benzene ring and may be any of an aromatic hydrocarbon ring or an aromatic hetero ring. The aromatic ring may be either monocyclic or polycyclic.

Examples of the amide group include, but are not limited to, —C(═O)—NHR^{B}, where R^{B} represents a hydrogen atom or an alkyl group having 1 to 5 carbon atoms.

In the case where the resist composition includes an onium salt compound and a capping agent, for example, the carboxyl group included in the resin corresponds to both interactive group and polar group.

### Polar Group

The polar group is not limited and is preferably, for example, an alcoholic hydroxyl group, a phenolic hydroxyl group, or a carboxyl group in order to further enhance reactivity with the capping agent, which is described below.

Note that the term “phenolic hydroxyl group” used herein refers to a hydroxyl group substituted to one of the atoms constituting an aromatic ring.

The aromatic ring is not limited to a benzene ring and may be any of an aromatic hydrocarbon ring or an aromatic hetero ring. The aromatic ring may be either monocyclic or polycyclic.

An alcoholic hydroxyl group is distinguished from a phenolic hydroxyl group; in the specification, the term “alcoholic hydroxyl group” refers to a hydroxyl group substituted to an aliphatic hydrocarbon group.

### Preferable Examples of Resin X

Preferable examples of the resin X are described below.

The resin X is a resin the molecular weight of which reduces as a result of the backbone of the resin X being broken by the action of exposure, an acid, a base, or heat, that is, “backbone breakage-type resin”.

Examples of types of the resin X, which is a backbone breakage-type resin, include resins having the following structures. Note that, among the resins having the following structures, resins X-I-A and X-I-B correspond to a resin the molecular weight of which reduces as a result of the backbone of the resin being broken by the action of exposure, while resins X-II and X-III correspond to a resin the molecular weight of which reduces as a result of the backbone of the resin being broken by the action of an acid.

Among these, the resin X-I-A is preferable in order to further enhance the advantageous effects of the present invention.

### Resin X-I-A

The resin X-I-A is a resin that includes the repeating units represented by Formulae (XP) and (XQ) below.

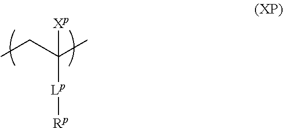

In Formula (XP), X^{p} represents a halogen atom, L^{p} represents a single bond or a divalent linking group, and RP represents a substituent.

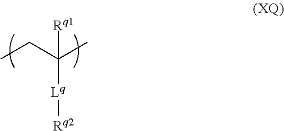

In Formula (XQ), R^{q1} represents an unsubstituted or substituted alkyl group, L^{q} represents a single bond or a divalent linking group, and R^{q2} represents a substituent.

The resin X-I-A has one or more groups selected from the group consisting of the polarity reduction group, the interactive group, and the polar group described above.

As for the resin X-I-A, it is preferable that at least one of the substituent represented by R^{p} in Formula (XP) and the substituent represented by R^{q2} in Formula (XQ) have one or more groups selected from the group consisting of the polarity reduction group, the interactive group, and the polar group described above or that the resin X-I-A include a repeating unit other than any of the repeating units represented by Formulae (XP) and (XQ) and the other repeating unit have one or more groups selected from the group consisting of the polarity reduction group, the interactive group, and the polar group described above.

In order to further enhance the advantageous effects of the present invention, it is more preferable that, in the resin X-I-A, at least one of the substituent represented by R^{p} in Formula (XP) and the substituent represented by R^{q2} in Formula (XQ) have one or more groups selected from the group consisting of the polarity reduction group, the interactive group, and the polar group described above.

### Preferable Mode of Resin X-I-A

Details of a preferable mode of the resin X-I-A are described below.

The resin X-I-A includes the repeating units represented by Formulae (XP) and (XQ) above.

The total content of the repeating units represented by Formulae (XP) and (XQ) above in the resin X-I-A is preferably 90 mol % or more and is more preferably 95 mol % or more of the total amount of all the repeating units. The upper limit for the total content is preferably 100 mol % or less.

In the resin X-I-A, the repeating units represented by Formulae (XP) and (XQ) above may be arranged in any manner, such as the manner of a random copolymer, a block copolymer, or an alternating copolymer (ABAB . . . ). Among these, an alternating copolymer is preferable.

In another preferable mode of the resin X-I-A, for example, the abundance of the alternating copolymer in the resin X is 90% by mass or more and is preferably 100% by mass or more of the total mass of the resin X.

The content of the repeating unit represented by Formula (XP) above in the resin X-I-A is preferably 10 to 90 mol % and is more preferably 30 to 70 mol % of the total amount of all the repeating units. The content of the repeating unit represented by Formula (XQ) above in the resin X-I-A is preferably 10 to 90 mol % and is more preferably 30 to 70 mol % of the total amount of all the repeating units.

The halogen atom represented by XP in Formula (XP) above is preferably a fluorine atom or a chlorine atom and is more preferably a chlorine atom in order to further enhance the advantageous effects of the present invention.

Examples of the divalent linking group represented by L^{p} in Formula (XP) above include, but are not limited to, —CO—, —O—, —SO—, —SO₂—, —NR^{A}—, an alkylene group (preferably having 1 to 6 carbon atoms, either linear or branched), a cycloalkylene group (preferably having 3 to 15 carbon atoms), a divalent aromatic hydrocarbon ring group (preferably six- to ten-membered, and further preferably six-membered), and a divalent linking group formed by the combination of two or more of the above groups. The above alkylene, cycloalkylene, and divalent aromatic hydrocarbon ring groups may have a substituent. Examples of the substituent include an alkyl group, a halogen atom, and a hydroxyl group. Examples of the group represented by R^{A} include a hydrogen atom and an alkyl group having 1 to 6 carbon atoms.

In a preferable mode of the divalent linking group represented by L^{p} is, for example, the position at which the divalent linking group represented by L^{p} is bonded to the backbone is —COO—.

Examples of the substituent represented by RP in Formula (XP) above include, but are not limited to, an alkyl group, a cycloalkyl group, an aryl group, an aralkyl group, an alkenyl group, an alkoxy group, an acyloxy group, a cyano group, a nitro group, a halogen atom, an ester group (—OCOR″ or —COOR″, where R″ represents an alkyl group or a fluorinated alkyl group), a lactone group, the polarity reduction group, the interactive group, and the polar group.

The alkyl, cycloalkyl, aryl, aralkyl, alkenyl, alkoxy, acyloxy, ester, and lactone groups may further have a substituent, and examples thereof include a halogen atom, the polarity reduction group, the interactive group, and the polar group. In the case where the alkyl group has a fluorine atom, the alkyl group may be a perfluoroalkyl group.

The alkyl group may be either linear or branched. The number of carbon atoms thereof is, for example, but not limited to, preferably 1 to 20, is more preferably 1 to 10, and is further preferably 1 to 6.

The cycloalkyl group may be either monocyclic or polycyclic. The number of carbon atoms thereof is, for example, but not limited to, preferably 5 to 15 and is more preferably 5 to 10. Examples of the cycloalkyl group include monocyclic cycloalkyl groups, such as a cyclopentyl group and a cyclohexyl group; and polycyclic cycloalkyl groups, such as a norbornyl group, a tetracyclodecanyl group, a tetracyclododecanyl group, and an adamantyl group.

The aryl group may be either monocyclic or polycyclic. The number of carbon atoms thereof is, for example, but not limited to, preferably 6 to 15 and is more preferably 6 to 10. The aryl group is preferably a phenyl group, a naphthyl group, or, an anthranil group and is more preferably a phenyl group.

The aralkyl group is preferably an aralkyl group formed as a result of one of the hydrogen atoms included in the above alkyl group being replaced with the above aryl group. The number of carbon atoms of the aralkyl group is preferably 7 to 20 and is more preferably 7 to 15.

The alkenyl group may be any of linear, branched, or cyclic. The number of carbon atoms thereof is, for example, but not limited to, preferably 2 to 20, is more preferably 2 to 10, and is further preferably 2 to 6.

The alkoxy group may be any of linear, branched, or cyclic. The number of carbon atoms thereof is preferably 1 to 20, is more preferably 1 to 10, and is further preferably 1 to 6.

The acyloxy group may be any of linear, branched, or cyclic. The number of carbon atoms thereof is preferably 2 to 20, is more preferably 2 to 10, and is further preferably 2 to 6.

The number of carbon atoms of the alkyl or fluorinated alkyl group represented by R″ above is preferably 1 to 20, is more preferably 1 to 10, and is further preferably 1 to 6.

The lactone group is preferably a lactone group having a five-to seven-membered ring and is more preferably a lactone group including a five-to seven-membered lactone ring and another ring structure fused to the lactone ring so as to form a bicyclo or spiro structure.

The polarity reduction group, the interactive group, and the polar group are as described above.

The repeating unit represented by Formula (XP) above is preferably one or more selected from the group consisting of the repeating units represented by Formulae (XP1) and (XP2) below.

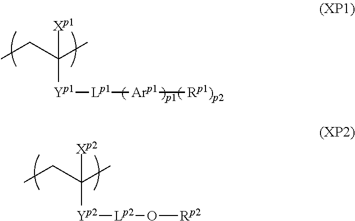

In Formula (XP1), X^{p1} represents the same as X^{p} in Formula (XP) above, and preferable examples thereof are also the same as that of X^{p}.

Y^{p1} represents a single bond or —COO—.

L^{p1} represents a single bond or a divalent linking group.

Examples of the divalent linking group represented by L^{p1} include, but are not limited to, —CO—, —O—, —SO—, —SO₂—, —NR^{A}—, an alkylene group (preferably having 1 to 6 carbon atoms, either linear or branched), and a divalent linking group formed by the combination of two or more of the above groups. The above alkylene group may have a substituent. Examples of the substituent include a halogen atom and a hydroxyl group. Examples of the group represented by R^{A} include a hydrogen atom and an alkyl group having 1 to 6 carbon atoms.

Ar^{p1} represents a (p2+1)-valent aromatic or alicyclic ring group.

In the case where p2 is 1, the divalent aromatic ring group is preferably, for example, an arylene group having 6 to 18 carbon atoms, such as a phenylene group, a tolylene group, a naphthylene group, or an anthracenylene group; or a divalent aromatic ring group including a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. Among these, an arylene group is preferable, a phenylene group, a naphthalene group, and an anthracenylene group are more preferable, and a phenylene group and a naphthalene group are further preferable.

Specific examples of the (p2+1)-valent aromatic ring group where p2 is an integer of 2 or more include groups formed as a result of (p2-1) hydrogen atoms being removed from the above specific examples of the divalent aromatic ring group.

The (p2+1)-valent alicyclic ring group represented by Ar^{p1} may include a hetero atom, such as an oxygen atom, or a carbonyl carbon atom. Examples of the (p2+1)-valent alicyclic ring group represented by Ar^{p1} include groups formed as a result of (p2+1) hydrogen atoms being removed from polycyclic cycloalkanes, such as norbornene, tetracyclodecane, tetracyclododecane, and adamantane. Examples of the (p2+1)-valent alicyclic ring group represented by Ar^{p1} further include groups formed as a result of (p2+1) hydrogen atoms being removed from lactone and sultone rings. The lactone and sultone rings are preferably five-to seven-membered lactone and sultone rings and are more preferably rings formed as a result of another ring structure being fused to five-to seven-membered lactone and sultone rings so as to form a bicyclo or spiro structure.

The (p2+1)-valent aromatic and alicyclic ring groups may have a substituent other than R^{p1}.
p1 represents 0 or 1.

In the case where p1 is 0, p2 represents 1. In the case where p1 is 1, p2 represents an integer of 0 to 4.

R^{p1} represents a substituent. Examples of the group represented by R^{p1} include the same things as those of the group represented by RP in Formula (XP) above. Among those, an unsubstituted or substituted alkyl group, the polarity reduction group, the interactive group, and the polar group are preferable. The substituent is preferably a halogen atom.

A preferable example of the substituent represented by R^{p1} is a substituent represented by *-L_{N}-R^{pA}. L_{N} represents a single bond or a divalent linking group. Examples of the divalent linking group represented by L_{N} include the same things as those of the divalent linking group represented by L^{p} in Formula (XP) above. Among those, an alkylene group having 1 to 6 carbon atoms is preferable. R^{pA} represents the polarity reduction group, the interactive group, or the polar group, which are described above.

In Formula (XP2), X^{p1} represents the same as X^{p} in Formula (XP) above.
Y^{p2} represents a single bond or —COO—.
L^{p2} represents a divalent linking group.

Examples of the divalent linking group represented by L^{p2} include —CO—, —O—, —S—, —SO—, —SO₂—, a hydrocarbon group (e.g., an alkylene group, a cycloalkylene group, an alkenylene group, or an arylene group), and a linking group formed by the combination of two or more of the above groups. The above hydrocarbon group may have a substituent. Examples of the substituent include, but are not limited to, fluorine and iodine atoms.

In particular, the divalent linking group represented by L^{p2} is preferably an arylene group, an arylene group —CO—, an alkylene group —CO—, or an alkylene group-arylene group and is more preferably an arylene group.

The above arylene group is preferably a phenylene group.

The above alkylene group may be either linear or branched. The number of carbon atoms included in the alkylene group is preferably, but not limited to, 1 to 10 and is more preferably 1 to 3.
R^{p2} represents a leaving group capable of being eliminated by the action of an acid.

Examples of the leaving group capable of being eliminated by the action of an acid, which is represented by R^{p2}, include the above-described leaving groups represented by Formulae (Y1) to (Y4).

Note that, in the case where the repeating unit represented by Formula (XP2) includes an acid-decomposable group including a polar group protected by a leaving group, the polar group generated subsequent to the acid decomposition is more hydrophobic than the acid-decomposable group prior to the acid decomposition. Specifically, the acid-decomposable group has a smaller log P than the polar group from which the protecting group has been eliminated.

In Formula (XQ), the alkyl group represented by R^{q1} may be any of linear, branched, or cyclic. The number of carbon atoms included in the alkyl group is preferably 1 to 12, is more preferably 1 to 6, and is further preferably 1 to 3.

The alkyl group represented by R^{q1} may have a substituent. Examples of the substituent include, but are not limited to, a halogen atom and a hydroxyl group.

Examples of the divalent linking group represented by L_{q} in Formula (XQ) include the same things as those of the divalent linking group represented by LP in Formula (XP) above.

Examples of the substituent represented by R^{q2} in Formula (XQ) include the same things as those of the substituent represented by R^{p} in Formula (XP) above.

The repeating unit represented by Formula (XQ) above is preferably one or more selected from the group consisting of the repeating units represented by Formulae (XQ1) and (XQ2) below.

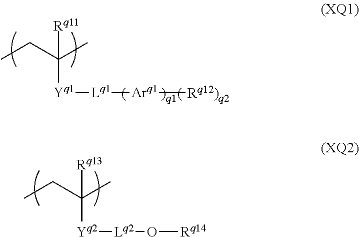

In Formula (XQ1), R^{q11} represents the same as R^{q1} in Formula (XQ) above, and preferable examples thereof are also the same as that of R^{q1}.

A preferable example of the substituent represented by R^{q12} is a substituent represented by *-L_{N}-R^{pA}. L_{N} represents a single bond or a divalent linking group. Examples of the divalent linking group represented by L_{N} include the same things as those of the divalent linking group represented by L^{p} in Formula (XP) above. Among those, an alkylene group having 1 to 6 carbon atoms is preferable. R^{pA} represents the polarity reduction group, the interactive group, or the polar group, which are described above.
Y^{q1} represents a single bond or —COO—.
L^{q1} represents a single bond or a divalent linking group.

Examples of the divalent linking group represented by L^{q1} include, but are not limited to, —CO—, —O—, —SO—, —SO₂—, —NR^{A}—, an alkylene group (preferably having 1 to 6 carbon atoms, either linear or branched), and a divalent linking group formed by the combination of two or more of the above groups. The above alkylene group may have a substituent. Examples of the substituent include a halogen atom and a hydroxyl group. Examples of the group represented by R^{A} include a hydrogen atom and an alkyl group having 1 to 6 carbon atoms.
Ar^{q1} represents a (q2+1)-valent aromatic or alicyclic ring group.

In the case where q2 is 1, the divalent aromatic ring group is preferably, for example, an arylene group having 6 to 18 carbon atoms, such as a phenylene group, a tolylene group, a naphthylene group, or an anthracenylene group; or a divalent aromatic ring group including a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. Among these, an arylene group is preferable, and a phenylene group and a naphthalene group are more preferable.

Specific examples of the (q2+1)-valent aromatic ring group where q2 is an integer of 2 or more include groups formed as a result of (q2-1) hydrogen atoms being removed from the above specific examples of the divalent aromatic ring group.

The (q2+1)-valent alicyclic ring group represented by Ar^{q1} may include a hetero atom, such as an oxygen atom, or a carbonyl carbon atom. Examples of the (q2+1)-valent alicyclic ring group represented by Ar^{q1} include groups formed as a result of (q2+1) hydrogen atoms being removed from polycyclic cycloalkanes, such as norbornene, tetracyclodecane, tetracyclododecane, and adamantane. Examples of the (q2+1)-valent alicyclic ring group represented by Aral further include groups formed as a result of (q2+1) hydrogen atoms being removed from lactone and sultone rings. The lactone and sultone rings are preferably five-to seven-membered lactone and sultone rings and are more preferably rings formed as a result of another ring structure being fused to five-to seven-membered lactone and sultone rings so as to form a bicyclo or spiro structure.

The (q2+1)-valent aromatic and alicyclic ring groups may have a substituent other than R^{q12}.
q1 represents 0 or 1.

In the case where q1 is 0, 92 represents 1. In the case where q1 is 1, q2 represents an integer of 0 to 4.
R^{p12} represents a substituent. Examples of the group represented by R^{p12} include the same things as those of the group represented by R^{p} in Formula (XP) above. Among those, an unsubstituted or substituted alkyl group, the polarity reduction group, the interactive group, and the polar group are preferable. The substituent is preferably a halogen atom.

A preferable example of the substituent represented by R^{p12} is a substituent represented by *-L_{N}-R^{pA}. L_{N} represents a single bond or a divalent linking group. Examples of the divalent linking group represented by L_{N} include the same things as those of the divalent linking group represented by L^{p} in Formula (XP) above. Among those, an alkylene group having 1 to 6 carbon atoms is preferable. R^{pA} represents the polarity reduction group, the interactive group, or the polar group, which are described above.

In Formula (XQ2), R^{q13} represents the same as R^{q1} in Formula (XQ) above.
Y^{q2} represents a single bond or —COO—.
L^{q2} represents a divalent linking group.

Examples of the divalent linking group represented by L^{q2} include —CO—, —O—, —S—, —SO—, —SO₂—, a hydrocarbon group (e.g., an alkylene group, a cycloalkylene group, an alkenylene group, or an arylene group), and a linking group formed by the combination of two or more of the above groups. The above hydrocarbon group may have a substituent. Examples of the substituent include, but are not limited to, fluorine and iodine atoms.

In particular, the divalent linking group represented by L^{q2} is preferably an arylene group, an arylene group —CO—, an alkylene group —CO—, or an alkylene group-arylene group and is more preferably an arylene group.

The above arylene group is preferably a phenylene group.

The above alkylene group may be either linear or branched. The number of carbon atoms included in the alkylene group is preferably, but not limited to, 1 to 10 and is more preferably 1 to 3.
R^{q14} represents a leaving group capable of being eliminated by the action of an acid.

Examples of the leaving group capable of being eliminated by the action of an acid, which is represented by R^{q14}, include the above-described leaving groups represented by Formulae (Y1) to (Y4).

Note that, in the case where the repeating unit represented by Formula (XQ2) includes an acid-decomposable group including a polar group protected by a leaving group, the polar group generated subsequent to the acid decomposition is more hydrophobic than the acid-decomposable group prior to the acid decomposition. Specifically, the acid-decomposable group has a smaller log P than the polar group from which the protecting group has been eliminated.

The above-described resin X-I-A may include a repeating unit other than any of the above-described repeating units without inhibiting the advantageous effects of the present invention.

### Resin X-I-B

The resin X-I-B is a resin that includes the repeating unit represented by Formula (XP) above.

The repeating unit represented by Formula (XP) which is included in the resin X-I-B is the same as the repeating unit represented by Formula (XP) included in the resin X-I-A described above, and preferable examples thereof are also the same.

### Resin X-II

The resin X-II is a resin having a backbone structure including a partial structure represented by Formula (XR0) below.

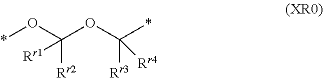

In Formula (XR0), R^{r1} to R^{r4} each independently represent a hydrogen atom or a substituent. R^{r2} and R^{r3} may be bonded to each other to form a ring. The symbol * represents a bond position.

The resin X-II has one or more groups selected from the group consisting of the polarity reduction group, the interactive group, and the polar group described above.

It is preferable for the resin X-II that one or more of R^{r1} to R^{r4} in Formula (XR0) be substituents and at least one of the substituents have one or more groups selected from the group consisting of the polarity reduction group, the interactive group, and the polar group described above; that R^{r2} and R^{r3} in Formula (XR0) be bonded to each other to form a ring and at least one of the substituent substituted to the ring have one or more groups selected from the group consisting of the polarity reduction group, the interactive group, and the polar group described above; or the resin X-II have a repeating unit other than the repeating unit represented by Formula (XR0) and the other repeating unit have one or more groups selected from the group consisting of the polarity reduction group, the interactive group, and the polar group described above.

It is more preferable for the resin X-II that one or more of R^{r1} to R^{r4} in Formula (XR0) be substituents and at least one of the substituents have one or more groups selected from the group consisting of the polarity reduction group, the interactive group, and the polar group described above; or that R^{r2} and R^{r3} in Formula (XR0) be bonded to each other to form a ring and at least one of the substituent substituted to the ring have one or more groups selected from the group consisting of the polarity reduction group, the interactive group, and the polar group described above.

In order to further enhance the advantageous effects of the present invention, it is more preferable for the resin X-II that R^{r2} and R^{r3} in Formula (XR0) be bonded to each other to form a ring and at least one of the substituent substituted to the ring have one or more groups selected from the group consisting of the polarity reduction group, the interactive group, and the polar group described above.

The resin X-II may include the partial structure represented by Formula (XR0) as a part of the resin X-II or a repeating unit. In order to further enhance the advantageous effects of the present invention, it is preferable that the resin X-II be a resin including the structure represented by Formula (XR0) as a repeating unit, that is, a resin including the repeating unit represented by Formula (XR) below.

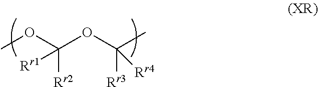

R^{r1} to R^{r4} in Formula (XR) represent the same things as R^{r1} to R^{r4} in Formula (XR0) above, respectively, and preferable examples thereof are also the same.

### Preferable Mode of Resin X-II

Details of a preferable mode of the resin X-II are described below.

The content of the repeating unit represented by Formula (XR) above in the resin X-II is preferably 90 mol % or more and is more preferably 95 mol % or more of the total amount of all the repeating units. The upper limit for the above content is preferably 100 mol % or less.

Examples of the substituents represented by R^{r1} to R^{r4} in Formulae (XR) and (XR0) above include the same things as those of the substituent represented by R^{p} in Formula (XP) above, and preferable examples thereof are also the same.

A preferable example of the substituents represented by R^{r1} to R^{r4} is a substituent represented by *-L_{N}-R^{pA}. L_{N} represents a single bond or a divalent linking group. Examples of the divalent linking group represented by L_{N} include the same things as those of the divalent linking group represented by L^{p} in Formula (XP) above. Among those, an alkylene group having 1 to 6 carbon atoms is preferable. R^{pA} represents the polarity reduction group, the interactive group, or the polar group, which are described above.

The ring formed as a result of R^{r2} and R^{r3} in Formula (XR) or (XR0) being bonded to each other is not limited and may be either an alicyclic or aromatic ring. The above ring may further has a substituent, and examples of the substituent include the polarity reduction group, the interactive group, and the polar group. It is also preferable that the substituent be the group represented by *-L_{N}-R^{pA}, which is described as an example of the substituents represented by R^{r1} to R^{r4} above.

In the case where R^{r2} and R^{r3} in Formula (XR) are bonded to each other, it is also preferable that the repeating unit represented by Formula (XR) be the repeating unit represented by Formula (XRA) below.

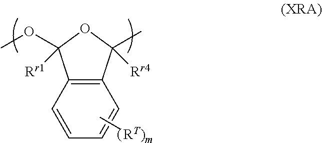

In Formula (XRA), R^{r1} and R^{r4} represent the same things as R^{r1} and R^{r4} in Formula (XR) above, respectively, and preferable examples thereof are also the same. R^{T} represents a substituent. Examples of the substituent represented by R^{T} include the same things as those of the substituent represented by R^{p} in Formula (XP) above, and preferable examples thereof are also the same.

Note that at least one of the substituents represented by R^{T}'s is the polarity reduction group, the interactive group, or the polar group. m is an integer of 0 to 4.

The above-described resin X-II may include a repeating unit other than any of the above-described repeating units without inhibiting the advantageous effects of the present invention.

### Resin X-III

The resin X-III is a resin that includes the repeating unit represented by Formula (XS) below.

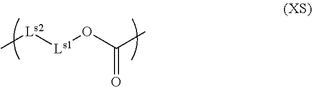

In Formula (XS), L^{s1} represents a linking group represented by *—C(R^{s1})(R^{s2})—*; R^{s1} and R^{s2} each independently represent a hydrogen atom or a monovalent organic group, where at least one of R^{s1} and R^{s2} is a monovalent organic group; and L^{s2} represents a single bond or a divalent linking group.

The resin X-III has one or more groups selected from the group consisting of the polarity reduction group, the interactive group, and the polar group described above.

It is preferable for the resin X-III that the monovalent organic groups represented by R^{s1} and R^{s2} in Formula (XS) and the divalent linking group represented by L^{s2} in Formula (XS) have one or more groups selected from the group consisting of the polarity reduction group, the interactive group, and the polar group described above.

In order to further enhance the advantageous effects of the present invention, it is more preferable for the resin X-III that the monovalent organic groups represented by R^{s1} and R^{s2} in Formula (XS) have one or more groups selected from the group consisting of the polarity reduction group, the interactive group, and the polar group described above.

### Preferable Mode of Resin X-III

Details of a preferable mode of the resin X-III are described below.

The content of the repeating unit represented by Formula (XS) above in the resin X-III is preferably 90 mol % or more and is more preferably 95 mol % or more of the total amount of all the repeating units. The upper limit for the above content is preferably 100 mol % or less.

In Formula (XS), L^{s1} represents a linking group represented by *—C(R^{s1})(R^{s2})—*.
R^{s1} and R^{s2} each independently represent a hydrogen atom or a monovalent organic group.

At least one of R^{s1} and R^{s2} in Formula (XS) is a monovalent organic group.

The monovalent organic groups represented by R^{s1} and R^{s2} are preferably each an alkyl group (linear or branched), a cycloalkyl group (monocyclic or polycyclic), or an aryl (monocyclic or polycyclic) group and are more preferably each an alkyl group.

The alkyl groups represented by R^{s1} and R^{s2} are preferably each an alkyl group having 1 to 4 carbon atoms.

The cycloalkyl groups represented by R^{s1} and R^{s2} are preferably each a monocyclic cycloalkyl group, such as a cyclopentyl group or a cyclohexyl group, or a polycyclic cycloalkyl group, such as a norbornyl group, a tetracyclodecanyl group, a tetracyclododecanyl group, or an adamantyl group.

The aryl groups represented by R^{s1} and R^{s2} are preferably each a phenyl group.

The groups represented by R^{s1} and R^{s2} are preferably both alkyl groups, are more preferably both alkyl groups having 1 to 4 carbon atoms, and are further preferably both methyl groups.

Examples of the divalent linking group represented by L^{s2} in Formula (XS) include the same things as those of the divalent linking group represented by L^{p} in Formula (XP).

In particular, the group represented by L^{s2} is preferably the group represented by *¹-L_{O1}-ph-L^{O2}-O—*², where ph represents an unsubstituted or substituted phenylene group, *1 represents the position of a bond to L^{s1}, *² represents the other bond position, and L_{O1} and L_{O2} represent a single bond or a divalent linking group.

The substituent that ph may have is not limited and is preferably, for example, the group represented by *-L_{N}-R^{pA}. L_{N} represents a single bond or a divalent linking group. Examples of the divalent linking group represented by L_{N} include the same things as those of the divalent linking group represented by L^{p} in Formula (XP) above. Among those, an alkylene group having 1 to 6 carbon atoms is preferable. R^{pA} represents the polarity reduction group, the interactive group, or the polar group, which are described above.

Examples of the divalent linking groups represented by L_{O1} and L_{O2} include —CO—, —O—, —SO—, —SO₂—, —NR^{A}—, an alkylene group (preferably having 1 to 6 carbon atoms, either linear or branched), and a divalent linking group formed by the combination of two or more of the above groups. The above alkylene group may have a substituent. Examples of the substituent include a halogen atom and a hydroxyl group. Examples of the group represented by R^{A} include a hydrogen atom and an alkyl group having 1 to 6 carbon atoms.

Examples of the divalent linking groups represented by L_{O1} and L_{O2} include a divalent linking group represented by -Alkylene group —O—.

The above-described resin X-III may include a repeating unit other than any of the above-described repeating units without inhibiting the advantageous effects of the present invention.

The resin X may be synthesized in accordance with a conventional method (e.g., radical polymerization).

The weight-average molecular weight Mw of the resin X is preferably 15,000 or more, is more preferably 20,000 or more, is further preferably 30,000 or more, and is particularly preferably 40,000 or more. As for the upper limit, the above Mw is preferably, for example, 200,000 or less and is more preferably 150,000 or less.

The polydispersity Mw/Mn of the resin X is not limited. The Mw/Mn is preferably 2.5 or less, is more preferably 2.0 or less, and is further preferably 1.7 or less. The lower limit for the Mw/Mn is not limited and is, for example, 1.0 or more.

The content of the resin X in the resist composition is preferably 30.0% to 99.9% by mass, is more preferably 45.0% to 99.0% by mass, and is further preferably 70.0% to 99.0% by mass of the total solid content in the composition.

The resin X may be used alone. In another case, a plurality of resins X may be used in combination of one another. In the case where two or more types of the resins X are used, it is preferable that the total content of the resins X fall within the suitable content range above.

### Resin Y

The resist composition may include a resin Y that is different from the resin X described above.

Specific modes of the resin Y include the following.
Mode Y-1: the resin Y has the polarity reduction group.
Mode Y-2: the resin Y has the interactive group.
Mode Y-3: the resin Y has the polar group.
Mode Y-4: the resin Y has two or more selected from the group consisting of the polarity reduction group, the interactive group, and the polar group.

In Modes Y-1 to Y-4, as described above, the polarity reduction group is a group the polarity of which reduces by the action of exposure, an acid, a base, or heat, and the interactive group is a group that interacts with an onium salt compound, wherein the above interaction can be canceled by the action of exposure, an acid, a base, or heat.

In the case where the resin Y has the interactive group (Modes Y-2 and Y-4), the resist composition typically further includes an onium salt compound capable of generating a bond due to the interaction between the onium salt compound and the interactive group included in the resin Y.

In the case where the resin Y has the polar group (Modes Y-3 and Y-4), the resist composition typically further includes a capping agent that reacts with the polar group included in the resin Y to reduce the polarity of the resin Y.

The polarity reduction group, interactive group, and polar group that may be included in the resin Y are the same as the polarity reduction group, interactive group, and polar group that may be included in the resin X described above, respectively, and preferable examples thereof are also the same.

### Suitable Mode of Resin Y

A suitable mode of the resin Y is described below.

The resin Y is not limited and may be any resin that includes a repeating unit including one or more selected from the group consisting of the polarity reduction group, the interactive group, and the polar group. Examples of the above repeating unit include a repeating unit represented by any one of Formulae (I) to (III) and (T1) below.

### Repeating Unit Represented by Formula (I)

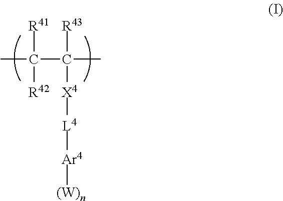

In Formula (I),
R⁴¹, R⁴², and R⁴³ each independently represent a hydrogen atom, an alkyl group, a cycloalkyl group, a halogen atom, a cyano group, or an alkoxycarbonyl group, R⁴² and Ar⁴ may be bonded to each other to form a ring, and, in such a case, R⁴² is a single bond or an alkylene group;
X⁴ represents a single bond, —COO—, or —CONR⁶⁴—, where R⁶⁴ represents a hydrogen atom or an alkyl group;
L⁴ represents a single bond or an alkylene group;
Ar⁴ represents a (n+1)-valent aromatic ring group, and, in the case where Ar⁴ is bonded to R⁴² to form a ring, Ar⁴ is a (n+2)-valent aromatic ring group;
W represents the polarity reduction group, the interactive group, or the polar group; and
n represents an integer of 1 to 5.

The alkyl groups represented by R⁴¹, R⁴², and R⁴³ in Formula (I) are preferably alkyl groups having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, are more preferably alkyl groups having 8 or less carbon atoms, and are further preferably alkyl groups having 3 or less carbon atoms.

The cycloalkyl groups represented by R⁴¹, R⁴², and R⁴³ in Formula (I) may be either monocyclic or polycyclic and, in particular, are preferably monocyclic cycloalkyl groups having 3 to 8 carbon atoms, such as a cyclopropyl group, a cyclopentyl group, and a cyclohexyl group.

Examples of the halogen atoms represented by R⁴¹, R⁴², and R⁴³ in Formula (I) include a fluorine atom, a chlorine atom, a bromine atom, and an iodine atom, and a fluorine atom is preferable.

The alkyl groups included in the alkoxycarbonyl groups represented by R⁴¹, R⁴², and R⁴³ in Formula (I) are preferably the same as the alkyl groups represented by R⁴¹, R⁴², and R⁴³ described above.

The above groups represented by R⁴¹, R⁴², and R⁴³ in Formula (I) may have a substituent.

Ar⁴ represents a (n+1)-valent aromatic ring group. In the case where n is 1, the divalent aromatic ring group is preferably, for example, an arylene group having 6 to 18 carbon atoms, such as a phenylene group, a tolylene group, a naphthylene group, or an anthracenylene group; or a divalent aromatic ring group including a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. Among these, an arylene group is preferable and a phenylene group and a naphthalene group are more preferable. The above aromatic ring group may have a substituent.

Specific examples of the (n+1)-valent aromatic ring group where n is an integer of 2 or more include groups formed as a result of (n-1) hydrogen atoms being removed from the above specific examples of the divalent aromatic ring group.

The (n+1)-valent aromatic ring group may further have a substituent.

Examples of the substituent that may be included in the alkyl, cycloalkyl, alkoxycarbonyl, and alkylene groups and the (n+1)-valent aromatic ring group described above include the above-described examples of the alkyl groups represented by R⁴¹, R⁴², and R⁴³ in Formula (I); alkoxy groups, such as a methoxy group, an ethoxy group, a hydroxyethoxy group, a propoxy group, a hydroxypropoxy group, and a butoxy group; aryl groups, such as a phenyl group; and halogen atoms.

Examples of the alkyl group represented by R⁶⁴ in —CONR⁶⁴— (where R⁶⁴ represents a hydrogen atom or an alkyl group) represented by X⁴ include alkyl groups having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group. An alkyl group having 8 or less carbon atoms is preferable.
X⁴ is preferably a single bond, —COO—, or —CONH— and is more preferably a single bond or —COO—.

The alkylene group represented by L⁴ is preferably an alkylene group having 1 to 8 carbon atoms, such as a methylene group, an ethylene group, a propylene group, a butylene group, a hexylene group, or an octylene group.

Specific examples of the polarity reduction group, interactive group, and polar group represented by W are as described above. In particular, W is preferably the group represented by Formula (KD1), the interactive group, or the polar group.

The repeating unit represented by Formula (I) is preferably the repeating unit represented by Formula (1) below.

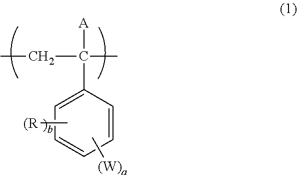

In Formula (1),
A represents a hydrogen atom, an alkyl group, a cycloalkyl group, a halogen atom, or a cyano group;
R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group, in the case where a plurality of R's are present, they may be identical to or different from one another, in the case where a plurality of R's are present, they may form a ring together, and R is preferably a hydrogen atom;
a represents an integer of 1 to 3;
b represents an integer of 0 to (5-a); and
W represents the polarity reduction group, the interactive group, or the polar group.

Examples of the repeating unit represented by Formula (I) are illustrated below. In the formulae below, a represents 1 or 2, and W represents the polarity reduction group, the interactive group, or the polar group. Specific examples of the polarity reduction group, interactive group, and polar group represented by W are as described above.

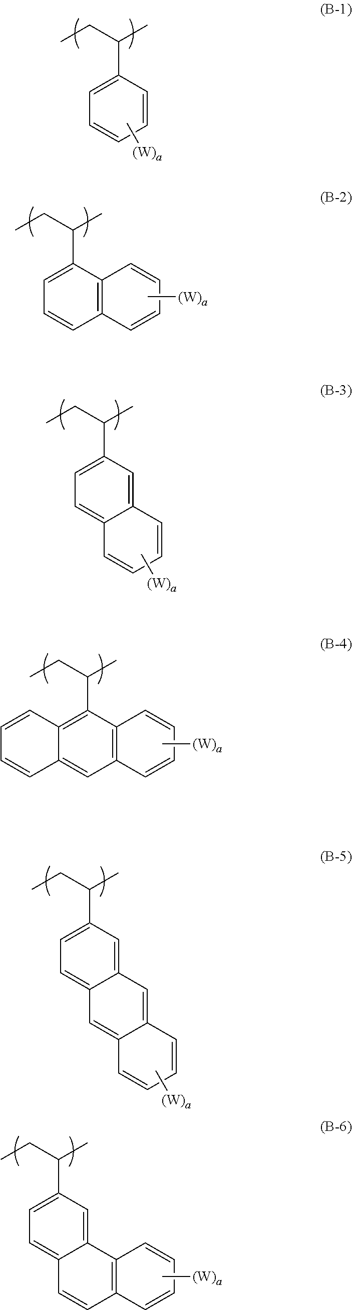

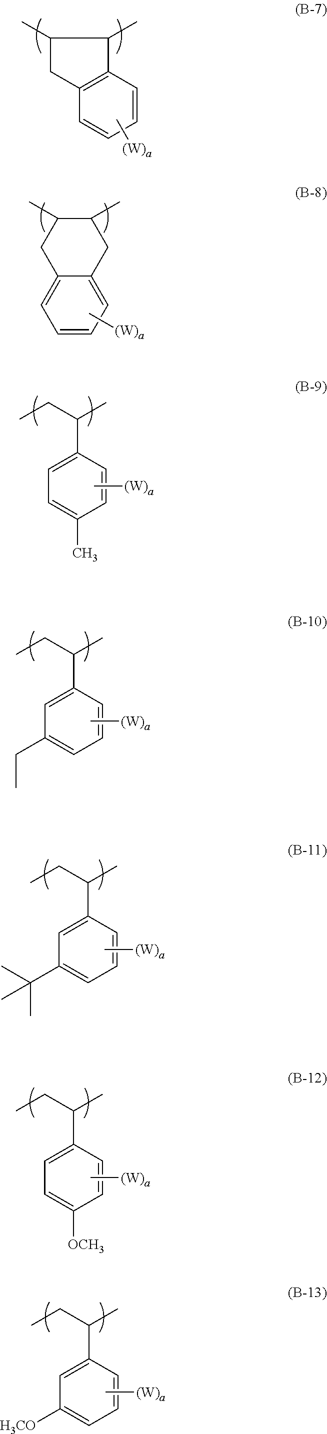

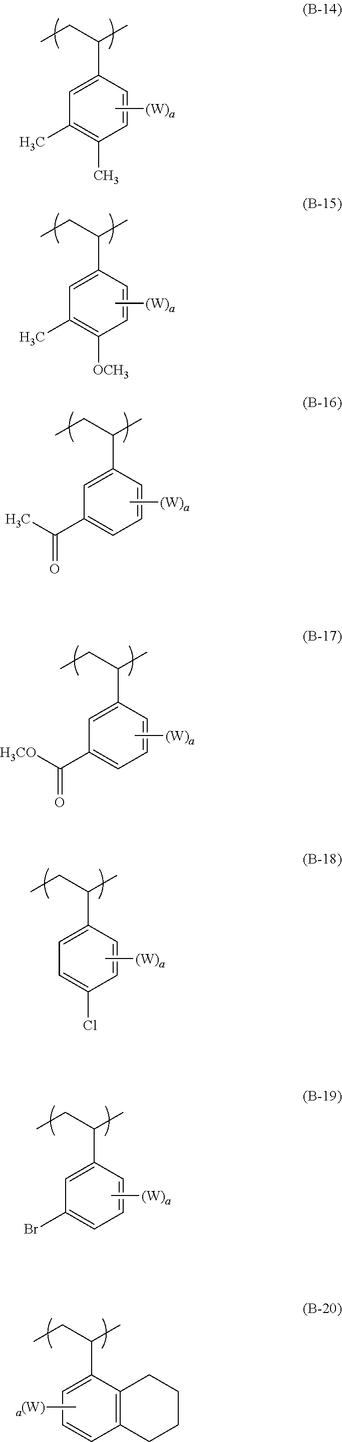

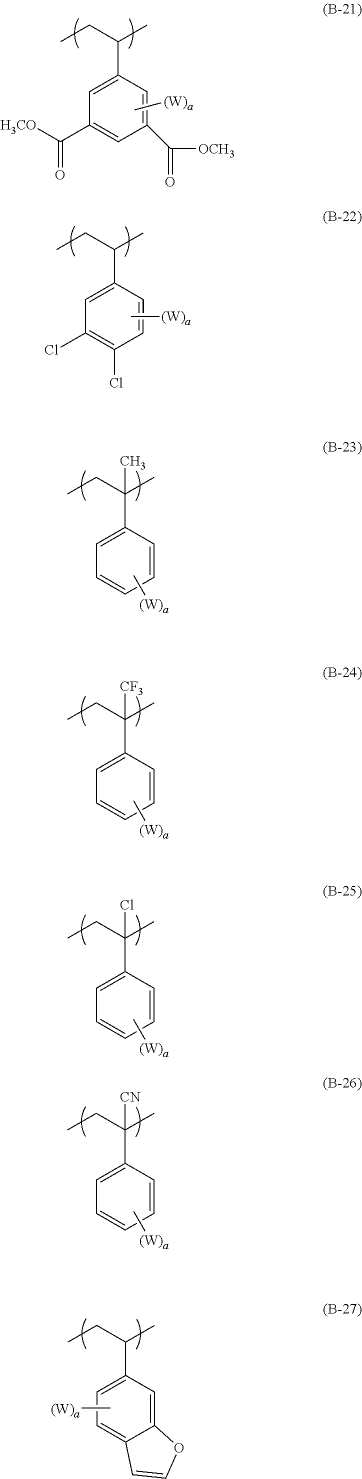

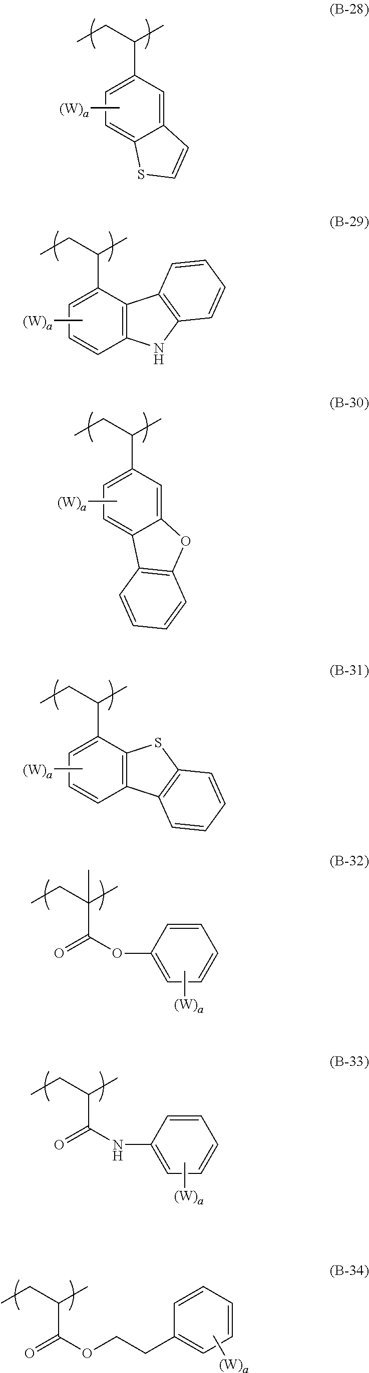

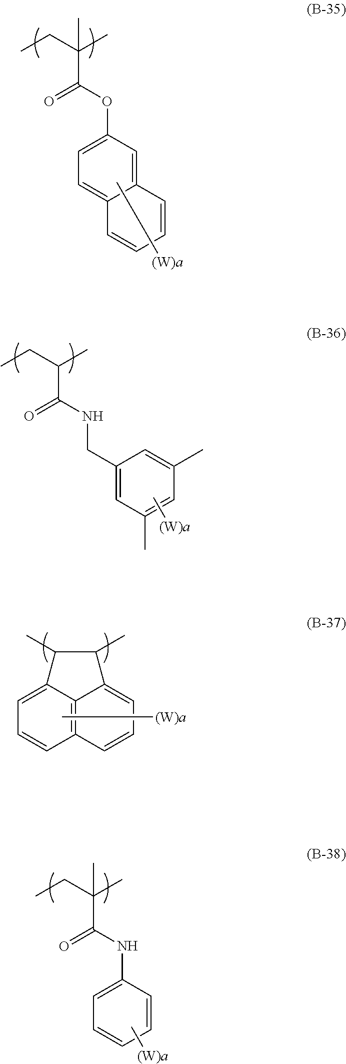

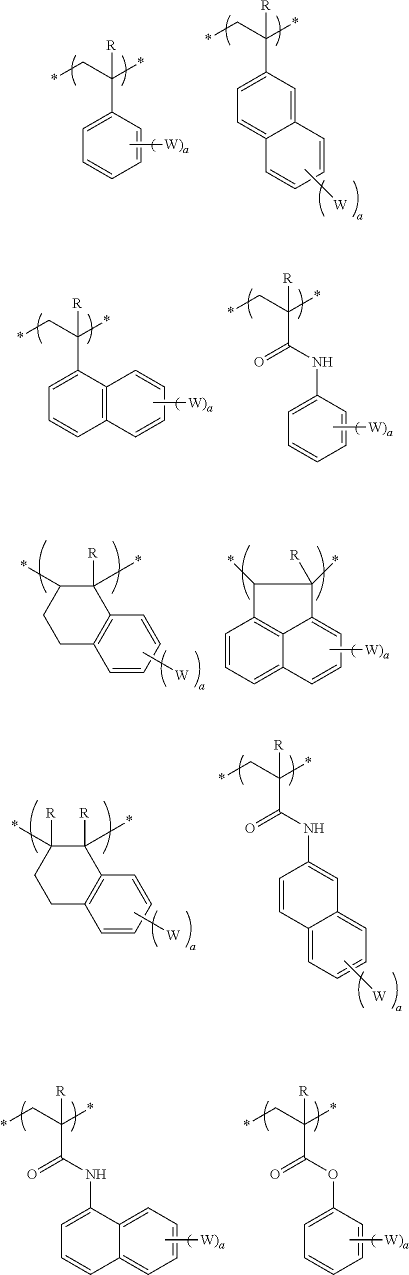

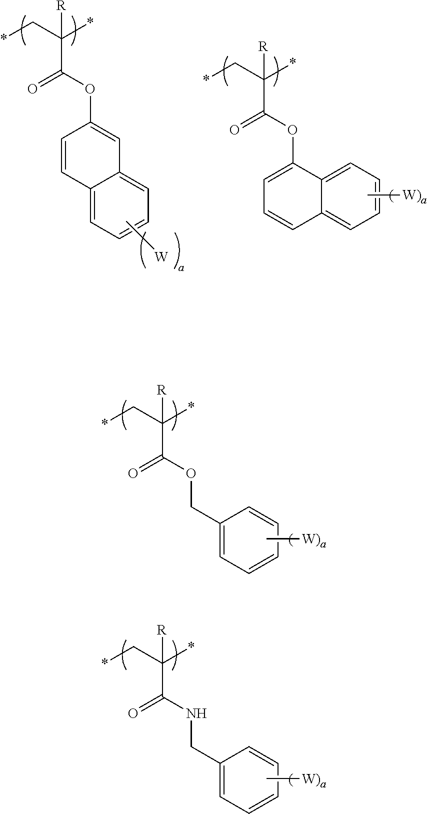

The content of the repeating unit represented by Formula (1) is preferably 10 mol % or more and is more preferably 20 mol % or more of the total amount of all the repeating units included in the resin Y. The upper limit for the above content is preferably 100 mol % or less, is more preferably 90 mol % or less, and is further preferably 80 mol % or less.

### Repeating Unit Represented by Formula (II)

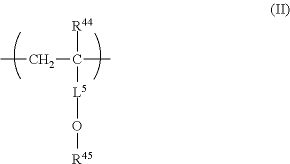

L⁵ represents a divalent linking group.

Examples of the divalent linking group represented by L⁵ include —CO—, —O—, —S—, —SO—, —SO₂—, a hydrocarbon group (e.g., an alkylene group, a cycloalkylene group, an alkenylene group, or an arylene group), and a linking group formed by the combination of two or more of the above groups. The above hydrocarbon group may have a substituent. Examples of the substituent include, but are not limited to, fluorine and iodine atoms.

In particular, the divalent linking group represented by L⁵ is preferably —CO—, an arylene group, or -Arylene group-Alkylene group- and is more preferably —CO— or an arylene group.

The above arylene group is preferably a phenylene group. The above alkylene group may be either linear or branched.

The number of carbon atoms included in the alkylene group is preferably, but not limited to, 1 to 10 and is more preferably 1 to 3.

R⁴⁴ represents a hydrogen atom, a fluorine atom, an iodine atom, an alkyl group, or an aryl group.

The alkyl group may be either linear or branched. The number of carbon atoms included in the alkyl group is preferably, but not limited to, 1 to 10 and is more preferably 1 to 3.

The alkyl and aryl groups represented by R⁴⁴ may have a substituent. Examples of the substituent include, but are not limited to, a fluorine atom and an iodine atom.

R⁴⁵ represents a leaving group capable of being eliminated by the action of an acid.

Examples of the leaving group capable of being eliminated by the action of an acid, which is represented by R⁴⁵, include the above-described leaving groups represented by Formulae (Y1) to (Y4).

According to a preferable embodiment, at least one of L⁵, R⁴⁴, and R⁴⁵ has a fluorine or iodine atom.

Note that the repeating unit represented by Formula (II) includes an acid-decomposable group including a polar group protected by a leaving group, and the polar group generated subsequent to the acid decomposition is more hydrophobic than the acid-decomposable group prior to the acid decomposition. Specifically, the acid-decomposable group has a smaller log P than the polar group from which the leaving group has been eliminated.

The content of the repeating unit represented by Formula (II) is preferably 10 mol % or more and is more preferably 20 mol % or more of the total amount of all the repeating units included in the resin Y. The upper limit for the above content is preferably 100 mol % or less, is more preferably 90 mol % or less, and is further preferably 80 mol % or less.

### Repeating Unit Represented by Formula (III)

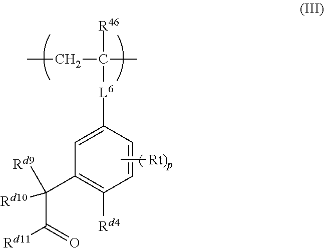

R⁴⁶ represents a hydrogen atom, a fluorine atom, an iodine atom, an alkyl group, or an aryl group.

The alkyl group may be either linear or branched. The number of carbon atoms included in the alkyl group is preferably, but not limited to, 1 to 10 and is more preferably 1 to 3.

The alkyl and aryl groups represented by R⁴⁶ may have a substituent. Examples of the substituent include, but are not limited to, a fluorine atom and an iodine atom.
L⁶ represents a single bond or a divalent linking group.

Examples of the divalent linking group represented by L⁶ include —CO—, —O—, —S—, —SO—, —SO₂—, a hydrocarbon group (e.g., an alkylene group, a cycloalkylene group, an alkenylene group, or an arylene group), and a linking group formed by the combination of two or more of the above groups. The above hydrocarbon group may have a substituent. Examples of the substituent include, but are not limited to, fluorine and iodine atoms.

The divalent linking group represented by L⁶ is preferably —COO—.

R^{d4} and R^{d9} to R^{d11} represents the same things as R^{d4} and R^{d9} to R^{d11} in Formula (KD2) above, respectively, and preferable examples thereof are also the same.
Rt represents a substituent. Examples of the substituent include, but are not limited to, an alkyl group having 1 to 6 carbon atoms, an alkoxy group having 1 to 6 carbon atoms, a fluorine atom, and an iodine atom.
p represents an integer of 0 to 3.

The content of the repeating unit represented by Formula (III) is preferably 10 mol % or more and is more preferably 20 mol % or more of the total amount of all the repeating units included in the resin Y. The upper limit for the above content is preferably 100 mol % or less, is more preferably 90 mol % or less, and is further preferably 80 mol % or less.

### Repeating Unit Represented by Formula (T1)

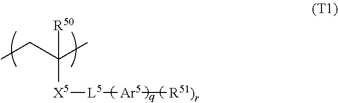

In Formula (T1) above, R⁵⁰ represents a hydrogen atom, a halogen atom, or an unsubstituted or substituted alkyl group;
X⁵ represents a single bond, —COO—, or —CONR⁵²—, where R⁵² represents a hydrogen atom or an alkyl group;
L⁵ represents a single bond or an alkylene group;
Ar⁵ represents a (r+1)-valent aromatic or alicyclic ring group;
R⁵¹ represents the polarity reduction group, the interactive group, or the polar group;
q represents 0 or 1; and
r represents 1 when q is 0 and represents an integer of 1 to 4 when q is 1.

The alkyl group represented by R⁵⁰ may be any of linear, branched, or cyclic. The number of carbon atoms included in the alkyl group is preferably 1 to 12, is more preferably 1 to 6, and is further preferably 1 to 3. The alkyl group represented by R⁵⁰ may have a substituent. Examples of the substituent include, but are not limited to, a halogen atom and a hydroxyl group.

Examples of the alkyl group represented by R⁶⁴ in —CONR⁶⁴— (where R⁶⁴ represents a hydrogen atom or an alkyl group) represented by X⁵ include alkyl groups having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group. An alkyl group having 8 or less carbon atoms is preferable.
X⁵ is preferably a single bond, —COO—, or —CONH— and is more preferably a single bond or —COO—.

Examples of the divalent linking group represented by L⁵ include —CO—, —O—, —SO—, —SO₂—, —NR^{A}—, an alkylene group (preferably having 1 to 6 carbon atoms, either linear or branched), and a divalent linking group formed by the combination of two or more of the above groups. The above alkylene group may have a substituent. Examples of the substituent include a halogen atom and a hydroxyl group. Examples of the group represented by RA include a hydrogen atom and an alkyl group having 1 to 6 carbon atoms.
Ar⁵ represents a (r+1)-valent aromatic or alicyclic ring group.

In the case where r is 1, the divalent aromatic ring group is preferably, for example, an arylene group having 6 to 18 carbon atoms, such as a phenylene group, a tolylene group, a naphthylene group, or an anthracenylene group; or a divalent aromatic ring group including a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, or a thiazole ring. Among these, an arylene group is preferable, and a phenylene group and a naphthalene group are more preferable. The aromatic ring group may have a substituent other than R⁵¹.

Specific examples of the (r+1)-valent aromatic ring group where r is an integer of 2 or more include groups formed as a result of (r−1) hydrogen atoms being removed from the above specific examples of the divalent aromatic ring group.

The (r+1)-valent alicyclic ring group represented by Ar⁵ may include a hetero atom, such as an oxygen atom, or a carbonyl carbon atom. Examples of the (r+1)-valent alicyclic ring group represented by Ar⁵ include groups formed as a result of (r+1) hydrogen atoms being removed from polycyclic cycloalkanes, such as norbornene, tetracyclodecane, tetracyclododecane, and adamantane. Examples of the (r+1)-valent alicyclic ring group represented by Ar⁵ further include a group formed as a result of (r+1) hydrogen atoms being removed from a lactone ring. The lactone ring is preferably a five-to seven-membered lactone ring and are more preferably a ring formed as a result of another ring structure being fused to a five-to seven-membered lactone ring so as to form a bicyclo or spiro structure.

The (r+1)-valent aromatic and alicyclic ring groups may further have a substituent. Examples of the substituent include alkyl groups that are the same as the alkyl group represented by R⁵⁰; alkoxy groups, such as a methoxy group, an ethoxy group, a hydroxyethoxy group, a propoxy group, a hydroxypropoxy group, and a butoxy group; aryl groups, such as a phenyl group; and halogen atoms.

In Formula (T1), R^{s1} represents the polarity reduction group, the interactive group, or the polar group. The polarity reduction group, the interactive group, and the polar group are as described above.

The content of the repeating unit represented by Formula (T1) is preferably 10 mol % or more and is more preferably 20 mol % or more of the total amount of all the repeating units included in the resin Y. The upper limit for the above content is preferably 100 mol % or less, is more preferably 90 mol % or less, and is further preferably 80 mol % or less.

The resin Y may include a repeating unit other than any of the above repeating units.

Examples of the other repeating unit include the repeating unit having a fluorine or iodine atom which is described in Paragraphs [0074] to [0077] of WO2018/193954A; the repeating unit having a lactone group which is described in Paragraphs [0080] to [0088]; and the repeating unit represented by General Formula (V-1) or (V-2) which is described in Paragraphs [0097] to

Examples of the other repeating unit further include the repeating units described in Paragraphs to of WO2018/193954A.

The resin Y may be synthesized in accordance with a conventional method (e.g., radical polymerization).

The weight-average molecular weight of the resin Y determined by GPC in terms of polystyrene equivalent is preferably 1,000 to 200,000, is more preferably 2,500 to 150,000, and is further preferably 3,000 to 50,000. When the above weight-average molecular weight falls within the above numerical range, the degradation of heat resistance and dry etching resistance may be further reduced. In addition, the possibility of film formability becoming degraded due to the degradation of the developing property and an increase in viscosity may be further reduced.

The polydispersity (molecular weight distribution) of the resin Y is commonly 1.0 to 5.0, is preferably 1.0 to 3.0, is more preferably 1.2 to 3.0, and is further preferably 1.2 to 2.0. The lower the polydispersity of the resin Y, the more excellent the resin Y in terms of resolution and resist shape.

In the case where the resist composition includes the resin Y, the content of the resin Y is preferably 10.0% to 60.0% by mass and is more preferably 10.0% to 50.0% by mass of the total solid content in the composition.

Only one type of the resin Y may be used alone, or a plural types of the resins Y may be used in combination. In the case where two or more types of the resins Y are used, the total content thereof preferably falls within the suitable content range described above.

### Onium Salt Compound

The resist composition preferably includes an onium salt compound. In particular, the onium salt compound is preferably a compound having an onium salt structure that generates an acid upon being irradiated with an actinic ray or radiation (hereinafter, such a compound is referred to as “photodecomposable onium salt compound”).

In the case where the resist composition includes the photodecomposable onium salt compound, in a portion that has not been exposed to the light, the resins X and Y are likely to aggregate with the photodecomposable onium salt compound with the interactive group that may be included in the resins X and Y being interposed therebetween. On the other hand, upon being exposed to the light, the dissociation of the photodecomposable onium salt compound and the interactive group and the cleavage of the photodecomposable onium salt compound may occur and, consequently, the aggregation structure may become disintegrated. That is, the above-described action may further increase the dissolution contrast between the unexposed and exposed portions of the resist film. This may further enhance the advantageous effects of the present invention.

In the case where the resist composition includes the photodecomposable onium salt compound, the resin X included in the resist composition and the resin Y that may be optionally included in the resist composition preferably have an interactive group. The interactive group is as described above.

In particular, in the case where the resin X is a resin the backbone of which becomes decomposed by the action of an acid (e.g., the resins X-II and X-III), the resist composition preferably includes the photodecomposable onium salt compound.

The photodecomposable onium salt compound is described below.

The photodecomposable onium salt compound is preferably a compound that has at least one salt structural site constituted by anion and cation sections and becomes decomposed to generate an acid (preferably, an organic acid) when exposed to light.

In particular, it is preferable that the salt structural site of the photodecomposable onium salt compound be constituted by an organic cation section and an organic anion section that has significantly poor nucleophilicity in order to further increase the likelihood of the decomposition of the compound exposed to light and the production of the organic acid.

The salt structural site may be either a part or the entirety of the photodecomposable onium salt compound. Note that the case where the salt structural site is a part of the photodecomposable onium salt compound corresponds to, for example, a structure that includes two or more salt structural sites connected to one another, like the photodecomposable onium salt PG2 described below.

The number of the salt structural sites included in the photodecomposable onium salt is preferably, but not limited to, 1 to 10, is more preferably 1 to 6, and is further preferably 1 to 3.

Examples of the organic acid generated from the photodecomposable onium salt compound by the action of exposure include sulfonic acids (e.g., an aliphatic sulfonic acid, an aromatic sulfonic acid, and a camphorsulfonic acid); carboxylic acids (e.g., an aliphatic carboxylic acid, an aromatic carboxylic acid, and an aralkyl carboxylic acid); and carbonyl sulfonylimide acid, bis(alkylsulfonyl)imide acid, and tris(alkylsulfonyl)methide acid.

The acid generated from the photodecomposable onium salt compound by the action of exposure may be an inorganic acid (e.g., a hydroxide ion).

The organic acid generated from the photodecomposable onium salt compound by the action of exposure may be a polyvalent acid having two or more acid groups. For example, in the case where the photodecomposable onium salt compound is the photodecomposable onium salt compound PG2 described below, the organic acid generated from the photodecomposable onium salt compound by the action of exposure is a polyvalent acid having two or more acid groups.

The cation section constituting the salt structural site included in the photodecomposable onium salt compound is preferably an organic cation section and is particularly preferably an organic cation (cation (ZaI) or (ZaII)) represented by Formula (ZaI) or (ZaII), respectively, which is described above.

### Photodecomposable Onium Salt Compound PG1

Preferable examples of the photodecomposable onium salt compound include an onium salt compound represented by “M⁺X⁻” which generates an organic acid when exposed to light (hereinafter, this onium salt compound is referred to also as “photodecomposable onium salt compound PG1”).

In the compound represented by “M⁺X⁻”, M⁺ represents an organic cation, and X⁻ represents an organic anion.

The photodecomposable onium salt compound PG1 is described below.

The organic cation represented by M⁺ in the photodecomposable onium salt compound PG1 is preferably an organic cation (cation (ZaI) or (ZaII)) represented by Formula (ZaI) or (ZaII), respectively, which is described above.

The organic anion represented by X-in the photodecomposable onium salt compound PG1 is preferably a non-nucleophilic anion (i.e., an anion having significantly poor ability to cause a nucleophilic reaction).

Examples of the non-nucleophilic anion include sulfonate anions (e.g., an aliphatic sulfonate anion, an aromatic sulfonate anion, and a camphor sulfonate anion), carboxylate anions (e.g., an aliphatic carboxylate anion, an aromatic carboxylate anion, and an aralkyl carboxylate anion), sulfonylimide anions, bis(alkylsulfonyl)imide anions, and tris (alkylsulfonyl) methide anions.

It is also preferable that the organic anion be, for example, the organic anion represented by X_{B}⁻ in Formula (O2), which is described above.

It is also preferable that the photodecomposable onium salt compound PG1 be, for example, the photoacid generator or the like disclosed in Paragraphs [0135] to [0171] of WO2018/193954A, Paragraphs [0077] to [0116] of WO2020/066824A, or Paragraphs [0018] to [0075] and [0334] and [0335] of WO2017/154345A.

The molecular weight of the photodecomposable onium salt compound PG1 is preferably 3,000 or less, is more preferably 2,000 or less, and is further preferably 1,000 or less. Photodecomposable Onium Salt Compound PG2

Preferable examples of the photodecomposable onium salt compound further include the compounds (I) and (II) below. Hereinafter, the compounds (I) and (II) are referred to also as “photodecomposable onium salt compound PG2”. The photodecomposable onium salt compound PG2 is a compound that has two or more salt structural sites described above and generates a polyvalent organic acid when exposed to light.

The photodecomposable onium salt compound PG2 is described below.

### Compound (I)

The compound (I) is a compound that has one or more structural sections X below and one or more structural sections Y below and generates an acid including first and second acidic sections derived from the structural sections X and Y, which are described below, when irradiated with an actinic ray or radiation.

Structural section X: a structural site that is constituted by an anion site A₁⁻ and a cation site M₁⁺ and that forms the first acidic section represented by HA₁ when irradiated with an actinic ray or radiation

Structural section Y: a structural site that is constituted by an anion site A₂⁻ and a cation site M₂⁺ and that forms the second acidic section represented by HA₂ when irradiated with an actinic ray or radiation

Note that the compound (I) satisfies Condition I below.

Condition I: a compound PI formed as a result of the cation sites M₁⁺ and M₂⁺ included in the structural sections X and Y of the compound (I), respectively, being replaced with H⁺ has an acid dissociation constant a1 derived from the acidic section represented by HA₁, which is formed as a result of the cation site M₁⁺ of the structural section X being replaced with H⁺, and an acid dissociation constant a2 derived from the acidic section represented by HA₂, which is formed as a result of the cation site M₂⁺ of the structural section Y being replaced with H⁺, and the acid dissociation constant a2 is larger than the acid dissociation constant a1.

The compound PI corresponds to the acid generated when the compound (I) is irradiated with an actinic ray or radiation.

In the case where the compound (I) has two or more structural sections X, the structural sections X may be identical to or different from one another. Two or more A₁⁻'s may be identical to or different from one another. Two or more M₁⁺'s may be identical to or different from one another.

In compound (I), A₁⁻ and A₂⁻ may be identical to or different from each other, and M₁⁺ and M₂⁺ may be identical to or different from each other. It is preferable that A₁⁻ and A₂⁻ be different from each other.

The anion sites A₁⁻ and A₂⁻ are structural sites including a negatively charged atom or atomic group, and examples thereof include the structural sites selected from the group consisting of Formulae (AA-1) to (AA-3) and (BB-1) to (BB-6) below. In Formulae (AA-1) to (AA-3) and (BB-1) to (BB-6) below, * represents a bond position, and R^{A} represents a monovalent organic group. Examples of the monovalent organic group represented by R^{A} include a cyano group, a trifluoromethyl group, and a methanesulfonyl group.

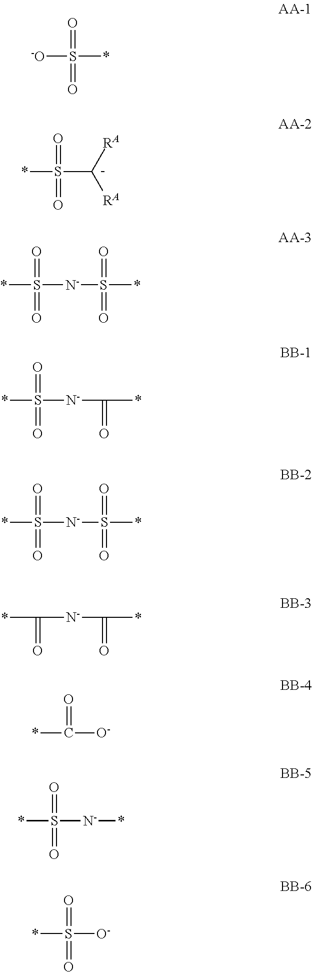

The cation sites M₁⁺ and M₂⁺ are structural sites including a positively charged atom or atomic group, and examples thereof include monovalent organic cations in terms of electric charge. The organic cation is preferably, but not limited to, the organic cation (cation (ZaI) or (ZaII)) represented by Formula (ZaI) or (ZaII), respectively, which is described above.

### Compound (II)

The compound (II) is a compound that has two or more structural sections X described above and one or more structural sections Z below and generates an acid including two or more first acidic sections derived from the structural sections X and the structural section Z when irradiated with an actinic ray or radiation.
Structural section Z: a nonionic section capable of neutralizing an acid

The compound (II) may generate a compound PII (i.e., an acid) having an acidic section represented by HA₁, which is formed as a result of the cation site M₁⁺ of the structural section X being replaced with H⁺, when irradiated with an actinic ray or radiation. That is, the compound PII is a compound having the above acidic section represented by HA₁ and the nonionic structural section Z capable of neutralizing an acid.

Note that the definitions of the structural section X, A₁⁻, and M₁⁺ in the compound (II) are the same as those of the structural section X, A₁⁻, and M₁⁺ in the compound (I) above, and preferable examples thereof are also the same.

Two or more structural sections X above may be identical to or different from one another. Two or more A₁⁻'s may be identical to or different from one another. Two or more M₁⁺'s may be identical to or different from one another.

The nonionic section of the structural section Z which is capable of neutralizing an acid is preferably, but not limited to, for example, a section including a group capable of electrostatically interacting with a proton or a functional group having an electron.

Examples of the group capable of electrostatically interacting with a proton and the functional group having an electron include a functional group having a macrocyclic structure, such as a cyclic polyether, and a functional group having a nitrogen atom with an unshared electron pair that does not contribute to x-conjugation. Examples of the nitrogen atom with an unshared electron pair that does not contribute to x-conjugation include nitrogen atoms having the partial structures illustrated in the formula below.

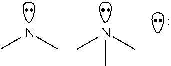

### Unshared Electron Pair

Examples of the partial structures of the group capable of electrostatically interacting with a proton and the functional group having an electron include a crown ether structure, an aza-crown ether structure, primary to tertiary amine structures, a pyridine structure, an imidazole structure, and a pyrazine structure. Among these, primary to tertiary amine structures are preferable.

The molecular weight of the photodecomposable onium salt compound PG2 is preferably 100 to 10,000, is more preferably 100 to 2,500, and is further preferably 100 to 1,500.

As for the photodecomposable onium salt compound PG2, the compound described in Paragraphs [0023] to [0095] of WO2020/158313A may be cited.

Examples of sections that may be included in the photodecomposable onium salt compound PG2 and that are other than cations are illustrated below.

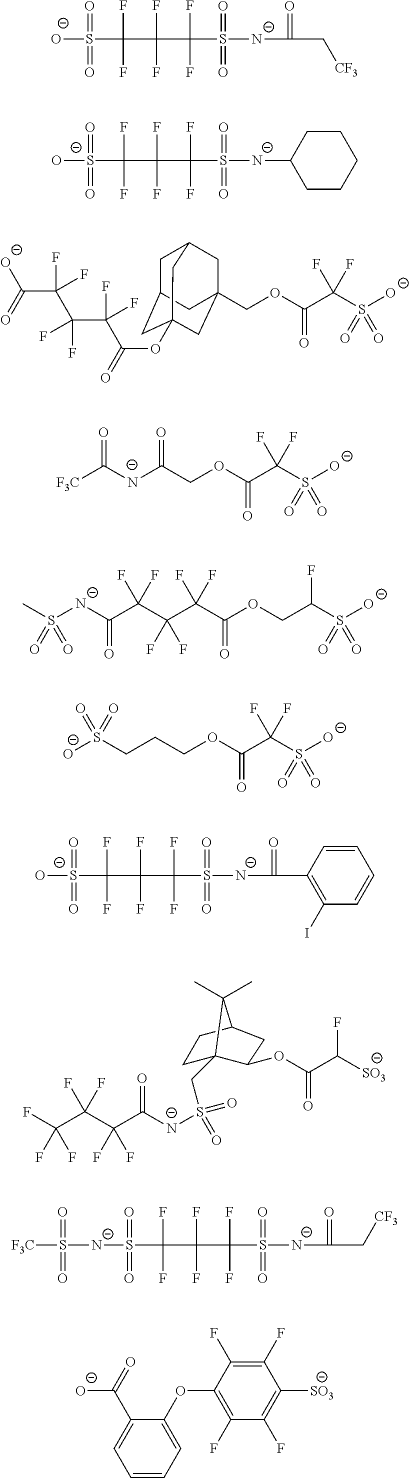

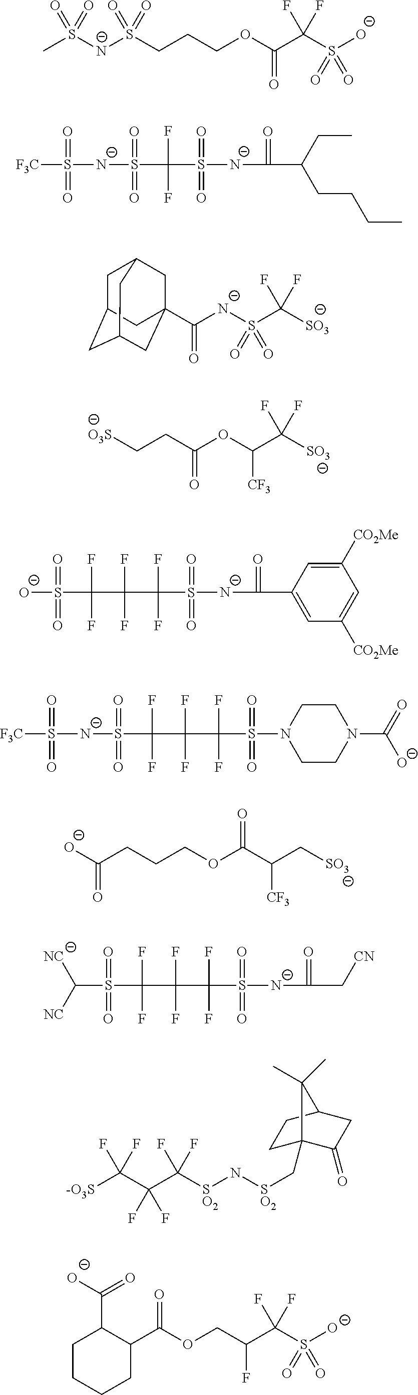

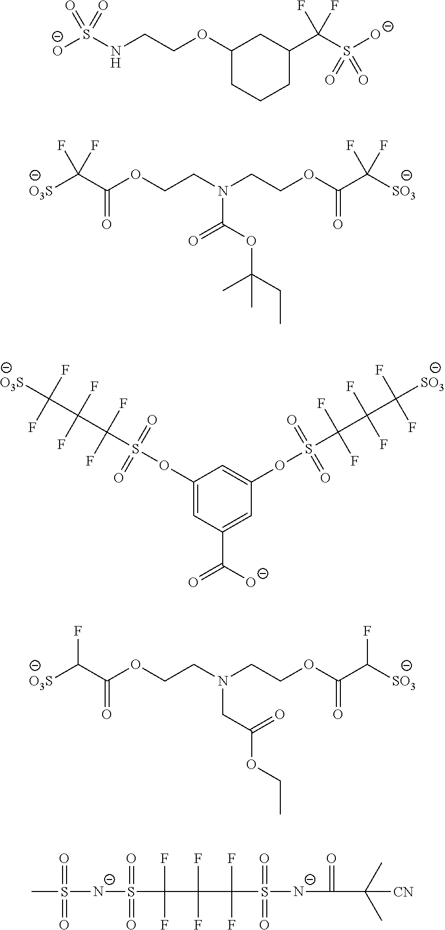

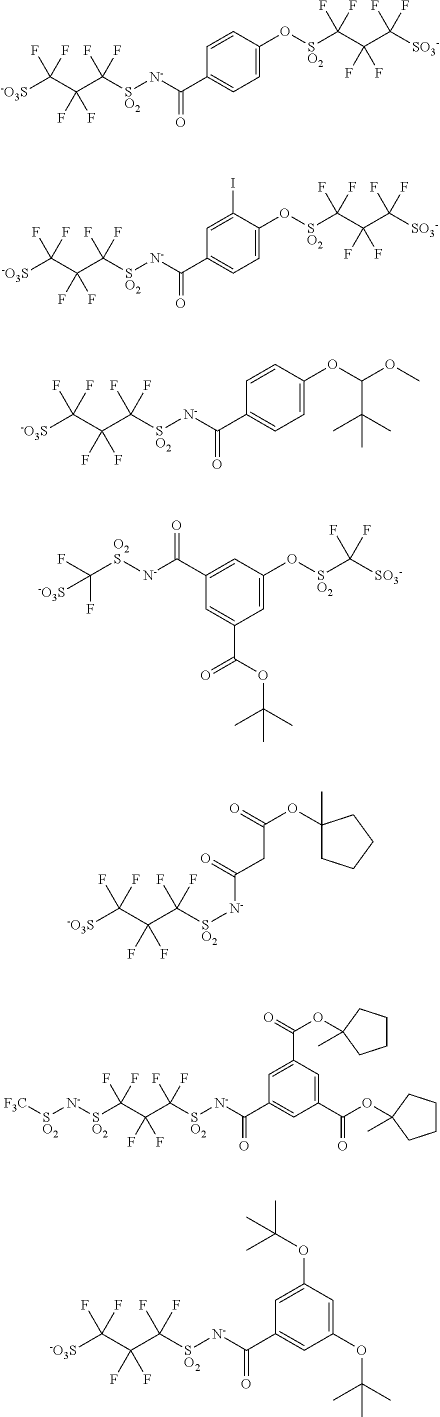

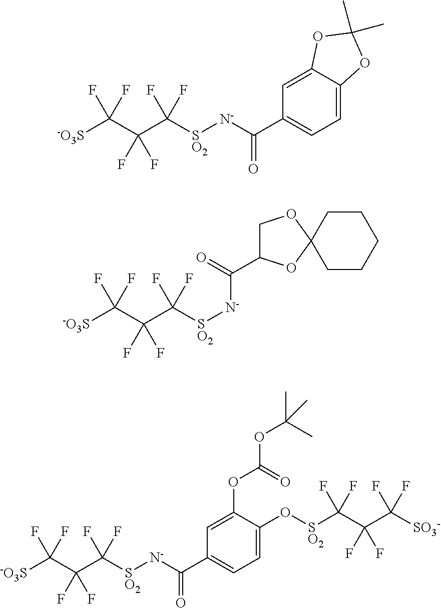

Specific examples of the photodecomposable onium salt compound PG2 are illustrated below. Note that the photodecomposable onium salt compound PG2 is not limited to the following examples.

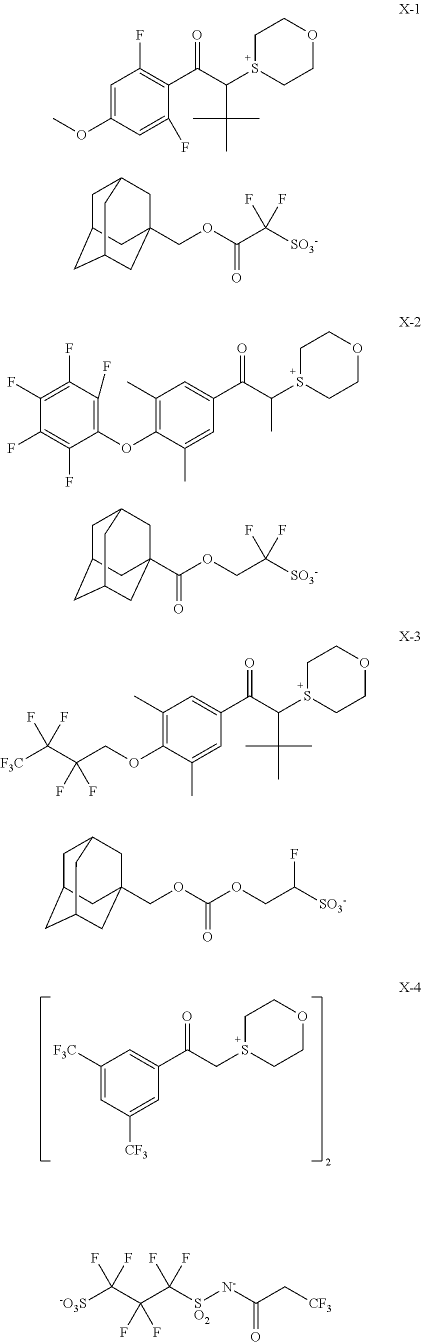

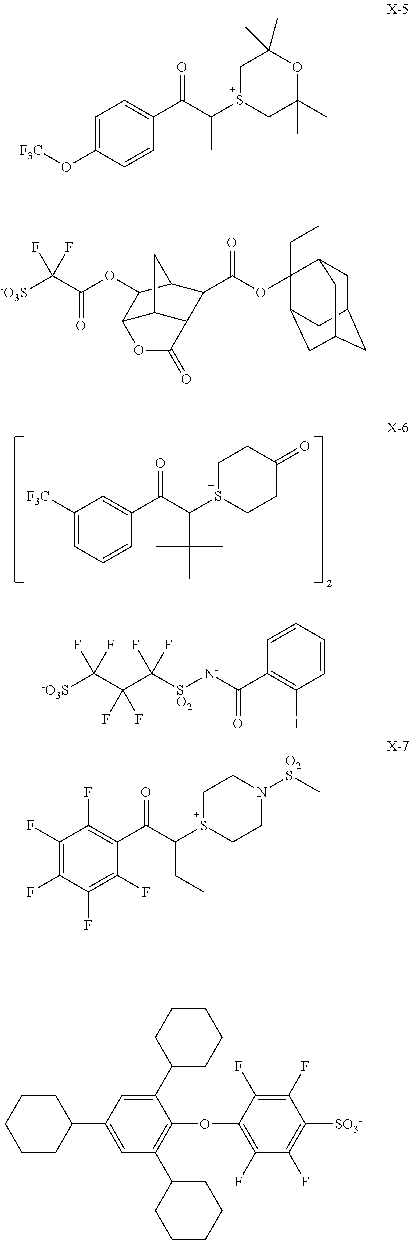

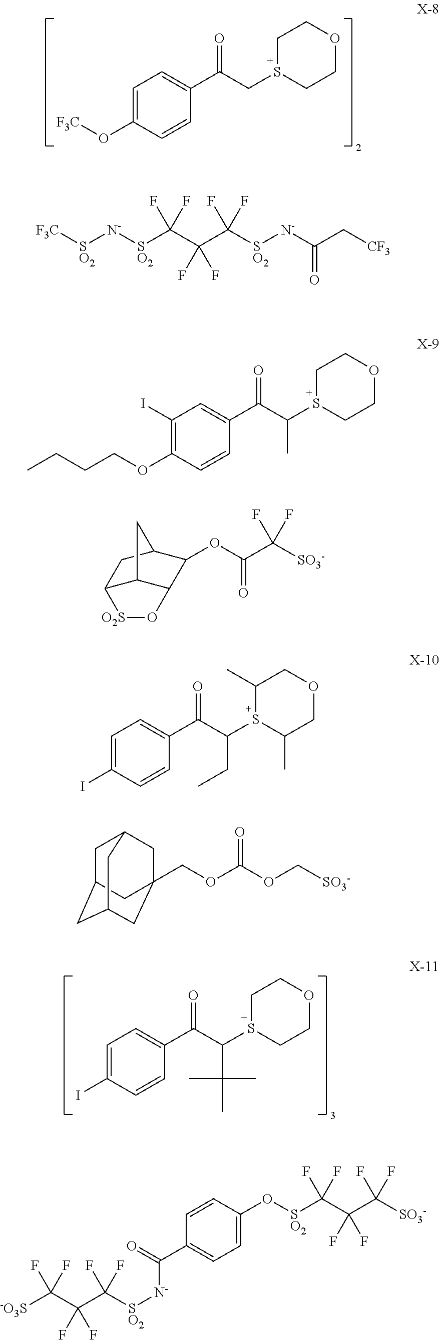

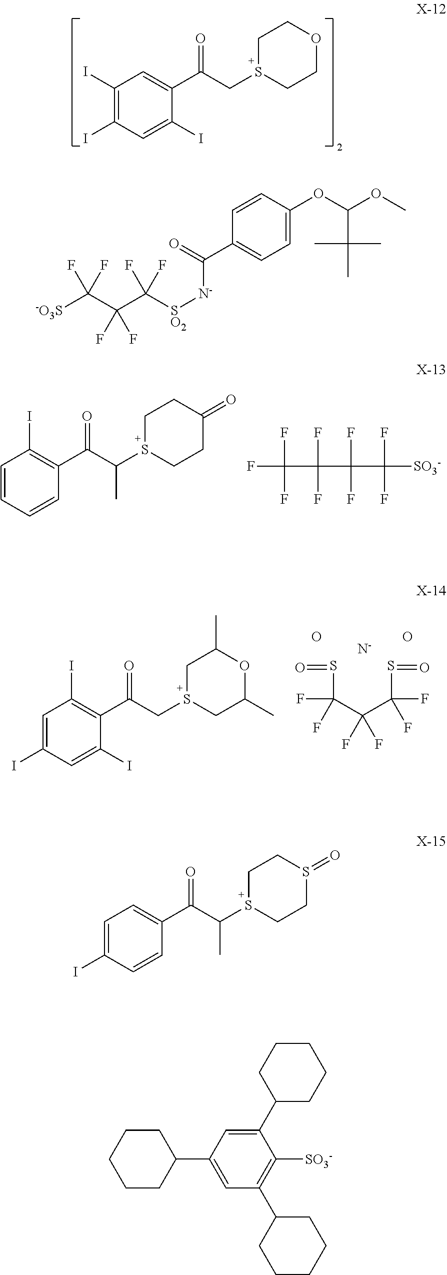

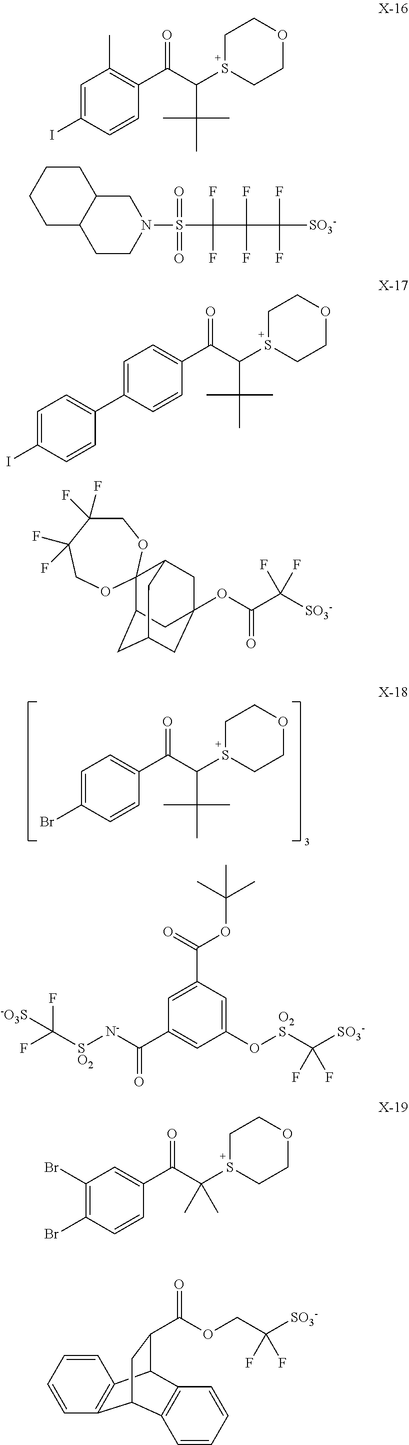

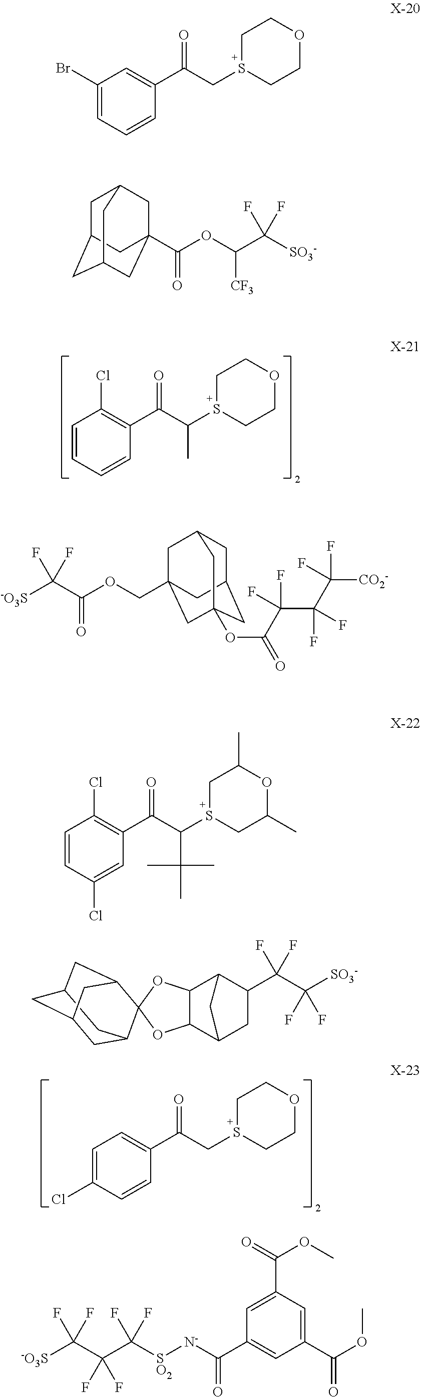

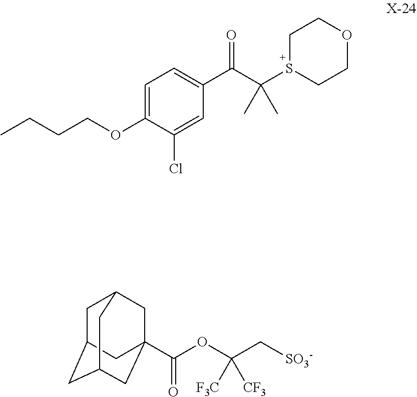

In the case where the resist composition includes the onium salt compound (preferably, the photodecomposable onium salt compound), the content of the onium salt compound is preferably, but not limited to, 0.5% by mass or more, is more preferably 1.0% by mass or more, and is further preferably 5.0% by mass or more of the total solid content in the composition. The above content is preferably 40.0% by mass or less and is more preferably 30.0% by mass or less.

Only one type of the onium salt compound (preferably, the photodecomposable onium salt compound) may be used alone. Alternatively, two or more types of the onium salt compounds may be used. In the case where two or more types of the onium salt compounds are used, the total content thereof preferably falls within the suitable content range above.

### Capping Agent

In the case where the resist composition includes a resin that corresponds to Mode X-3 as a resin X and/or a resin that corresponds to Mode Y-3 as a resin Y, the resist composition preferably includes a compound (i.e., a capping agent) reactive with the polar groups included in the resins X and Y by the action of exposure, an acid, a base, or heat. The reaction of the capping agent with the polar groups included in the resins X and Y reduces the degrees of polarity of the polar groups.

The capping agent may be a compound capable of binding to the polar groups included in the resins X and Y by the action of exposure, an acid, a base, or heat or a compound the structure of which changes by the action of exposure, an acid, a base, or heat and which becomes capable of binding to the polar groups included in the resins X and Y subsequent to the structure change.

The capping agent is preferably a compound having a functional group reactive with the polar groups included in the resins X and Y, such as an alcoholic hydroxyl group, a phenolic hydroxyl group, and a carboxyl group.

The mechanisms by which the capping agent reacts with the polar groups are not limited; the capping agent may react with the polar groups by any mechanisms in which the reaction is caused by the action of exposure, an acid, a base, or heat.

Examples of the compound reactive with the polar groups, such as an alcoholic hydroxyl group, a phenolic hydroxyl group, and a carboxyl group, include a tertiary alcohol, a tertiary ether, an epoxide, a vinyl ether, an olefin, a benzyl ether, a benzyl alcohol, and a carboxylic acid.

As for specific examples of the combination of the polar groups and the capping agent, for example, in the case where the polar group is an alcoholic hydroxyl group or a carboxyl group, an epoxide or the like is preferable. In the case where the polar group is a phenolic hydroxyl group, a tertiary alcohol, a tertiary ether, an epoxide, a vinyl ether, a benzyl ether, and the like are preferable.

The tertiary alcohol is preferably a compound represented by C(R¹)(R²)(R³)OH.
R¹ to R³ each independently represent a monovalent organic group.

The monovalent organic group is preferably, but is not limited to, an alkyl group (linear or branched), a cycloalkyl group (monocyclic or polycyclic), an alkenyl group (linear or branched), or an aryl group (monocyclic or polycyclic) in order to further enhance hydrophobicity subsequent to capping. The above alkyl, cycloalkyl, alkenyl, and aryl groups may further have a substituent. Examples of the substituent include a fluorine atom, an iodine atom, an alkyl group, a cycloalkyl group, an alkenyl group, and an aryl group.

The alkyl group may be either linear or branched. The alkyl group is preferably an alkyl group having 1 to 20 carbon atoms, is more preferably an alkyl group having 1 to 15 carbon atoms, and is further preferably an alkyl group having 1 to 10 carbon atoms.

The alkyl group may have a fluorine atom, an iodine atom, a cycloalkyl group, an alkenyl group, or an aryl group as a substituent. Specific examples of the cycloalkyl, alkenyl, and aryl groups that may be included in the alkyl group include the same things as those of the cycloalkyl, alkenyl, and aryl groups represented by R¹ to R³.

The cycloalkyl group is preferably a cycloalkyl group having 3 to 20 carbon atoms, is more preferably a cycloalkyl group having 3 to 15 carbon atoms, and is further preferably a cycloalkyl group having 3 to 10 carbon atoms.

The cycloalkyl group may have a fluorine atom, an iodine atom, an alkyl group, an alkenyl group, or an aryl group as a substituent. Specific examples of the alkyl, alkenyl, and aryl groups that may be included in the cycloalkyl group include the same things as those of the alkyl, alkenyl, and aryl groups represented by R¹ to R³.

The alkenyl group may be either linear or branched. The alkenyl group is preferably an alkenyl group having 2 to 20 carbon atoms, is more preferably an alkenyl group having 2 to 15 carbon atoms, and is further preferably an alkenyl group having 2 to 10 carbon atoms.

The alkenyl group may have a fluorine atom, an iodine atom, an alkyl group, a cycloalkyl group, or an aryl group as a substituent. Specific examples of the alkyl, cycloalkyl, and aryl groups that may be included in the alkenyl group include the same things as those of the alkyl, cycloalkyl, and aryl groups represented by R¹ to R³.

The aryl group may be either monocyclic or polycyclic. The aryl group is preferably an aryl group having 6 to 20 carbon atoms, is more preferably an aryl group having 6 to 15 carbon atoms, and is further preferably an aryl group having 6 to 10 carbon atoms.

The aryl group may have a fluorine atom, an iodine atom, an alkyl group, a cycloalkyl group, and an alkenyl group as a substituent. Specific examples of the alkyl, cycloalkyl, and alkenyl groups that may be included in the aryl group include the same things as those of the alkyl, cycloalkyl, and alkenyl groups represented by R¹ to R³.

The tertiary ether is preferably a compound represented by C(R⁴)(R⁵)(R⁶)—O—R⁷, where R⁴ to R⁷ each independently represent a monovalent organic group.

Examples of the monovalent organic groups represented by R⁴ to R⁷ include, but are not limited to, the specific examples of R¹ to R³ included in the above-described tertiary alcohol group.

The epoxide is preferably a compound represented by R⁸-X.
R⁸ represents a monovalent organic group.

Examples of the monovalent organic group represented by R⁸ include, but are not limited to, the specific examples of R¹ to R³ included in the above-described tertiary alcohol group.
X represents an oxiranyl group.

The vinyl ether is a compound represented by CH₂CH—O—CHCH₂. The hydrogen atoms included in the vinyl ether may be replaced with a fluorine or iodine atom.

Examples of the olefin include, but are not limited to, unsaturated hydrocarbon compounds having 2 to 10 carbon atoms. Specific examples thereof include ethylene, propylene, butylene, butadiene, and pentene. The hydrogen atoms included in the olefin may have a substituent. Examples of the substituent include a fluorine atom, an iodine atom, an alkyl group, a cycloalkyl group, an alkenyl group, and an aryl group. Specific examples of the alkyl, cycloalkyl, alkenyl, and aryl groups that may be included in the olefin as a substituent include those of the alkyl, cycloalkyl, alkenyl, and aryl groups represented by R¹ to R³.

The benzyl ether is preferably a compound represented by R⁸—O—CH₂-ph, where ph represents a phenyl group that may have a substituent (e.g., an alkyl group having 1 to 4 carbon atoms, a hydroxyl group, or an alkoxy group having 1 to 4 carbon atoms).
R⁸ represents a monovalent organic group.

Examples of the monovalent organic group represented by R⁸ include, but are not limited to, the specific examples of R¹ to R³ included in the above-described tertiary alcohol group.

According to another embodiment, the benzyl ether may be a compound having a benzyl ether group as a substituent.

The benzyl ether group is preferably a group formed as a result of one hydrogen atom being removed from the ring-member atoms of ph included in the compound represented by R⁸—O—CH₂-ph.

Examples of the compound having a benzyl ether group as a substituent include a compound having a polycyclic aromatic ring (e.g., 9H-fluorene ring) substituted with a benzyl ether group.

The benzyl alcohol is represented by ph-CH₂—OH, where ph represents a phenyl group.

The carboxylic acid is preferably a compound represented by R⁹—COOH.
R⁹ represents a monovalent organic group.

Examples of the monovalent organic group represented by R⁹ include, but are not limited to, the specific examples of R¹ to R³ included in the above-described tertiary alcohol group.

Whether the degrees of polarity of the resins X and Y are reduced after capping has done with the capping agent may be determined by calculating log P values (octanol/water partition coefficients) on the basis of the chemical structures of the polar group that has been and has not been subjected to the action of exposure, an acid, a base, or heat and determining whether the log P is increased subsequent to the reaction with the capping agent.

In the case where the resist composition includes the capping agent, the content of the capping agent (when a plural types of capping agents are present, the total content thereof) is preferably 5% by mass or more and is more preferably 10% by mass or more of the total solid content in the composition. The upper limit for the above content is preferably, but not limited to, 40% by mass or less, is more preferably 30% by mass or less, and is further preferably 20% by mass or less.

The resist composition may include only one type of the capping agent alone or two or more types of the capping agents in combination. In the case where two or more types of the capping agents are used, the total content thereof preferably falls within the suitable content range above.

### Surfactant

The resist composition may include a surfactant. When the resist composition includes a surfactant, it becomes possible to form a pattern having further high adhesiveness in which the amount of develop defects is reduced.

The surfactant is preferably a fluorine- and/or silicone-containing surfactant.

Examples of the fluorine- and/or silicone-containing surfactant include the surfactant disclosed in Paragraphs and of WO2018/193954A.

The above surfactants may be used alone or in combination of two or more.

In the case where the resist composition includes the surfactant, the content of the surfactant is preferably 0.0001% to 2% by mass and is more preferably 0.0005% to 1% by mass of the total solid content in the composition.

### Solvent

The resist composition may include a solvent.

The solvent preferably includes at least one of the components (M1) and (M2) below.
Component (M1): propylene glycol monoalkyl ether carboxylate
Component (M2): at least one selected from the group consisting of propylene glycol monoalkyl ether, a lactic acid ester, an acetic acid ester, an alkoxypropionic acid ester, a chain ketone, a cyclic ketone, a lactone, and an alkylene carbonate.

The above solvent may further include a component other than any of the components (M1) or (M2).

Using the solvent in combination with the above-described resins increases ease of application of the composition and makes it easy to form a pattern in which the number of development defects is small. Since the above solvent is suitable in terms of the balance between the solubility of the above-described resins, boiling point, and viscosity, the solvent may reduce the unevenness in the thickness of a film formed of the composition, the formation of precipitates during spin coating, and the like. This may make it possible to form a pattern in which the number of development defects is small.

Details of the components (M1) and (M2) are described in Paragraphs to of WO2020/004306A.

In the case where the solvent includes a component other than any of the components (M1) or (M2), the content of the other component is preferably 5% to 30% by mass of the total amount of the solvent.

The content of the solvent in the resist composition is preferably set such that the solid component concentration is 0.5% to 30% by mass and is more preferably set such that the solid component concentration is 1% to 20% by mass. This may further increase ease of application of the resist composition.

### Other Additives

The resist composition may further include a dissolution inhibiting compound, a dye, a plasticizer, a photosensitizer, a light absorbent, and/or a compound that enhances solubility in developer (e.g., a phenol compound having a molecular weight of 1,000 or less or an alicyclic or aliphatic compound including a carboxyl group).

The resist composition may further include a dissolution inhibiting compound. Note that the term “dissolution inhibiting compound” used herein refers to a compound having a molecular weight of 3,000 or less which becomes decomposed by the action of an acid to reduce the degree of solubility in an organic-based developer.

The resist composition may be suitably used as a photosensitive composition for EUV or electron beams.

Since EUV has a wavelength of 13.5 nm, which is shorter than the wavelength of ArF (wavelength: 193 nm) light or the like, the number of photons incident is small when exposure is done at the same sensitivity. Therefore, the effects of stochastic fluctuations in the number of photons, that is, “photon shot noise”, are large. This results in degradation of LER and occurrence of bridge defects. Although the photon shot noise can be reduced by increasing the amount of exposure to increase the number of photons incident, this contradicts with the demands for increases in sensitivity.

Although exposure to EUV is described above as an example case, the same issues as described above commonly occur even in the case where exposure to an electron beam is performed.

In the case where the A-value calculated using Formula (1) below is large, the efficiencies at which a resist film formed using the resist composition absorbs EUV and an electron beam are high and the photon shot noise may be reduced with effect. The A-value indicates the efficiencies at which the resist film absorbs EUV and an electron beam in terms of mass ratio.

$$A = ( [ H ] \times 0.04 + [ C ] \times 1. + [ N ] \times 2.1 + [ O ] \times 3.6 + [ F ] \times 5.6 + [ S ] \times 1.5 + [ \text{} I ] \times 39.5 ) / ( [ H ] \times 1 + [ C ] \times 12 + [ N ] \times 14 + [ O ] \times 16 + [ F ] \times 19 + [ S ] \times 32 + [ I ] \times 127 ) \text{} \qquad ( 1 )$$

The A-value is preferably 0.120 or more. The upper limit for the A-value is not set. If the A-value is excessively large, the transmittance of EUV and electron beam through the resist film is reduced, the optical image profile of the resist film becomes degraded, and, consequently, it becomes difficult to form a suitable pattern shape. Therefore, the A-value is preferably 0.240 or less and is more preferably 0.220 or less.

In Formula (1), [H] represents the molar ratio of hydrogen atoms derived from the total solid component to all the atoms included in the total solid component of the actinic ray- or radiation-sensitive resin composition, [C] represents the molar ratio of carbon atoms derived from the total solid component to all the atoms included in the total solid component of the actinic ray- or radiation-sensitive resin composition, [N] represents the molar ratio of nitrogen atoms derived from the total solid component to all the atoms included in the total solid component of the actinic ray- or radiation-sensitive resin composition, [O] represents the molar ratio of oxygen atoms derived from the total solid component to all the atoms included in the total solid component of the actinic ray- or radiation-sensitive resin composition, [F] represents the molar ratio of fluorine atoms derived from the total solid component to all the atoms included in the total solid component of the actinic ray- or radiation-sensitive resin composition, [S] represents the molar ratio of sulfur atoms derived from the total solid component to all the atoms included in the total solid component of the actinic ray- or radiation-sensitive resin composition, and [I] represents the molar ratio of iodine atoms derived from the total solid component to all the atoms included in the total solid component of the actinic ray- or radiation-sensitive resin composition.

For example, when the resist composition includes a resin X, a photodecomposable onium salt compound, and a solvent, the resin X and the photodecomposable onium salt compound correspond to the solid component. In this case, “all the atoms included in the total solid component” corresponds to the total of all the atoms derived from the resin X and the all the atoms derived from the photodecomposable onium salt compound. For example, [H] represents the molar ratio of the hydrogen atoms derived from the total solid component to all the atoms included in the total solid component. In accordance with the above-described example, [H] represents the total molar ratio of the hydrogen atoms derived from the resin X and the hydrogen atoms derived from the photodecomposable onium salt compound to the total of all the atoms derived from the resin X and all the atoms derived from the photodecomposable onium salt compound.

In the case where the structures and contents of all the solid components of the resist composition are known, the A-value can be determined by calculating the atomic ratios of the components. Even in the case where the components are unknown, the atomic ratios of the components can be determined by analyzing a resist film formed by evaporating the solvent component of the resist composition using an analytical method, such as element analysis.

### Method for Producing Electronic Device

The present invention also relates to a method for producing an electronic device in which the above-described pattern forming method is used.

The above electronic device may be suitably used in electrical and electronic equipment (e.g., household electrical appliances, office automation (OA), media-related equipment, optical equipment, and communication equipment).

### EXAMPLES

Further details of the present invention are described below with reference to Examples. The materials, the amounts of the materials used, the proportions of the materials, the treatments, the order in which the treatments were performed, and the like which are described in Examples below can be changed appropriately without departing from the gist of the present invention. Thus, Examples below should not be interpreted as restrictive of the scope of the present invention.

### Components of Actinic Ray- or Radiation-Sensitive Resin Compositions

The components used for preparing an actinic ray- or radiation-sensitive resin compositions and the materials used for evaluations are described below.

### Resins

The structures of the repeating units derived from the monomers used in the synthesis of the resins P-1 to P-16 listed in Table 3 are illustrated below.

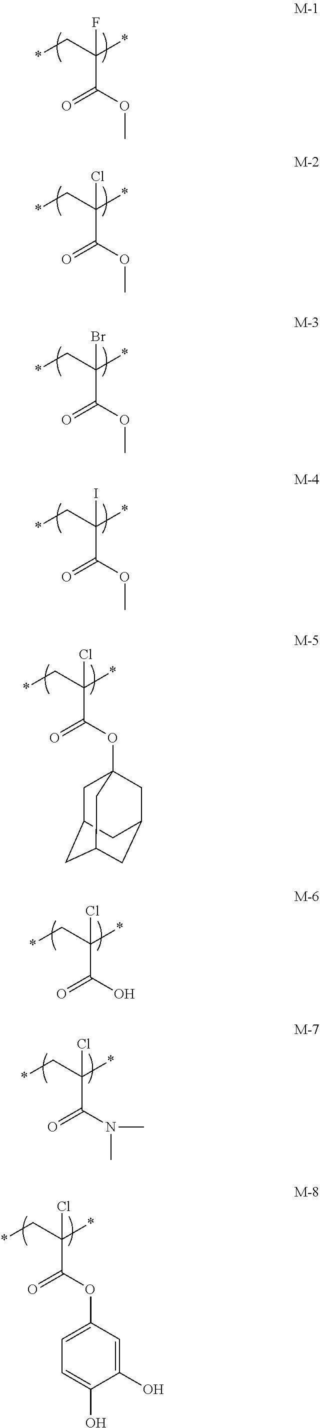

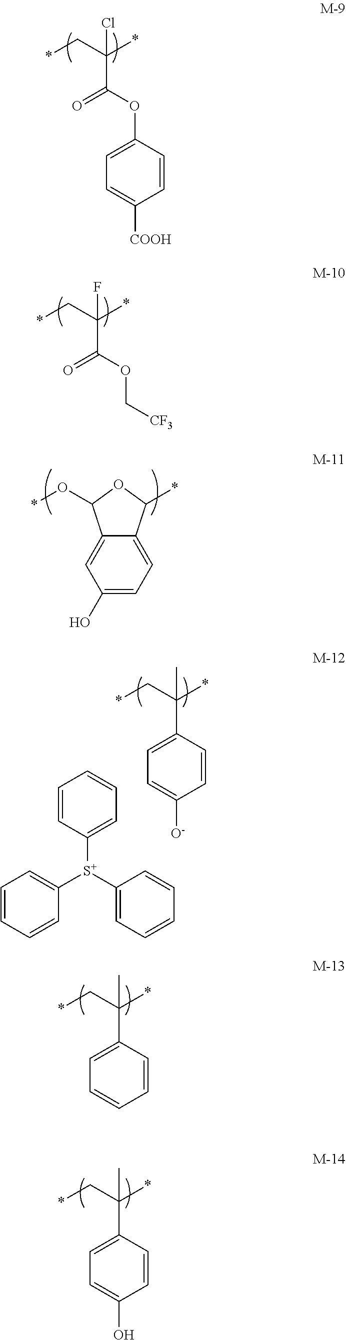

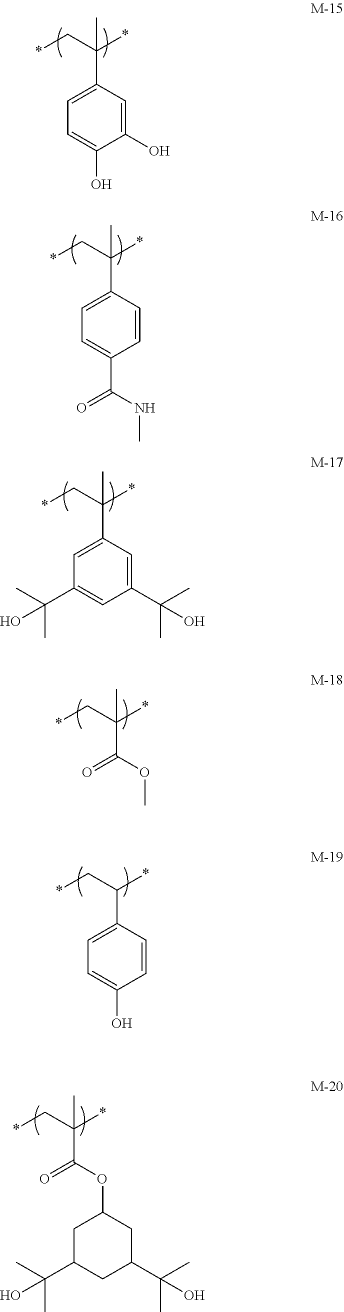

The resins P-2 to P-16 were synthesized in accordance with the method for synthesizing the resin P-1, which is described below (Synthesis Example 1) or a method known in the related art. Table 1 lists the compositional proportions of the repeating units included in each of the resins and the weight-average molecular weight (Mw), number-average molecular weight (Mn), and polydispersity (Mw/Mn (PDI)) of the resin.

Note that the weight-average molecular weight (Mw), number-average molecular weight (Mn), and polydispersity (PDI) of each of the resins P-1 to P-16 were determined by gel permeation chromatography (GPC) using a GPC apparatus “HLC-8120GPC” produced by Tosoh Corporation (solvent: tetrahydrofuran, flow rate (sample injection volume): 10 μL, column: “TSK gel Multipore HXL-M” produced by Tosoh Corporation, column temperature: 40° C., flow rate: 1.0 mL/min, detector: refractive index detector) in terms of polystyrene equivalent weight. The compositional ratios (mol % ratio) of the resins P-1 to P-16 were determined by ¹³C-nuclear magnetic resonance (NMR).

TABLE 1

| Resin | Type and content [mol %] of repeating unit | | | | Mw | Mn | PDI(Mw/Mn) |
|---|---|---|---|---|---|---|---|
| P-1 | M-2 | M-13 | M-15 | — | 40,000 | 25,000 | 1.6 |
| | 50 | 10 | 40 | — | | | |
| P-2 | M-1 | M-6 | M-13 | — | 40,000 | 25,000 | 1.6 |
| | 30 | 30 | 40 | — | | | |
| P-3 | M-3 | M-5 | M-12 | M-14 | 40,000 | 25,000 | 1.6 |
| | 25 | 25 | 10 | 40 | | | |
| P-4 | M-4 | M-7 | M-8 | M-16 | 40,000 | 25,000 | 1.6 |
| | 10 | 10 | 40 | 40 | | | |
| P-5 | M-7 | M-10 | M-15 | M-16 | 40,000 | 25,000 | 1.6 |
| | 20 | 20 | 50 | 10 | | | |
| P-6 | M-2 | M-9 | M-13 | M-14 | 40,000 | 25,000 | 1.6 |
| | 20 | 30 | 30 | 20 | | | |
| P-7 | M-11 | — | — | — | 40,000 | 25,000 | 1.6 |
| | 100 | — | — | — | | | |
| P-8 | M-2 | M-13 | M-15 | — | 40,000 | 19,000 | 2.1 |
| | 50 | 10 | 40 | — | | | |
| P-9 | M-2 | M-13 | M-15 | — | 40,000 | 22,200 | 1.8 |
| | 50 | 10 | 40 | — | | | |
| P-10 | M-2 | M-13 | M-15 | — | 25,000 | 15,600 | 1.6 |
| | 50 | 10 | 40 | — | | | |
| P-11 | M-2 | M-13 | M-15 | — | 35,000 | 21,900 | 1.6 |
| | 50 | 10 | 40 | — | | | |
| P-12 | M-2 | M-13 | — | — | 40,000 | 25,000 | 1.6 |
| | 50 | 50 | — | — | | | |
| P-13 | M-5 | M-13 | M-17 | — | 40,000 | 25,000 | 1.6 |
| | 45 | 25 | 30 | — | | | |
| P-14 | M-18 | M-20 | — | — | 10,000 | 6,200 | 1.6 |
| | 30 | 70 | — | — | | | |
| P-15 | M-18 | M-19 | — | — | 10,000 | 6,200 | 1.6 |
| | 50 | 50 | — | — | | | |
| P-16 | M-2 | M-13 | — | — | 25,000 | 12,000 | 2.1 |
| | 50 | 50 | — | — | | | |

### Synthesis Example 1: Synthesis of Resin P-1

Under a nitrogen gas stream. 70.0 g of cyclohexanone was charged into a three-necked flask, which was heated to 85° C. A solution prepared by dissolving the monomers corresponding to the respective repeating units of the resin P-1 described above (45.0 g. 10.0 g. and 45.0 g, in order from left in Table 1) and a polymerization initiator “V-601” produced by FUJIFILM Wako Pure Chemical Corporation (0.57 g) in 70.0 g of cyclohexanone was added dropwise to the flask over 6 hours. After the addition of the solution had been finished, the reaction was further conducted at 85° C. for 2 hours. After the reaction liquid had been left to cool, it was added dropwise to a liquid mixture of methanol and water over 20 minutes. Powder particles precipitated as a result of the addition of the reaction liquid was collected by filtration and dried. Hereby, a resin P-1 (73.6 g) was prepared. The compositional ratio (i.e., molar ratio) of the repeating units determined by nuclei magnetic resonance (NMR) was 50/10/40. The weight-average molecular weight of the resin P-1 determined in terms of standard polystyrene equivalent weight was 40,000. The polydispersity (PDI) of the resin P-1 was 1.6.

### Photodecomposable Onium Salts

The structures of the photodecomposable onium salts (C-1 to C-9) described in Table 3 are illustrated below.

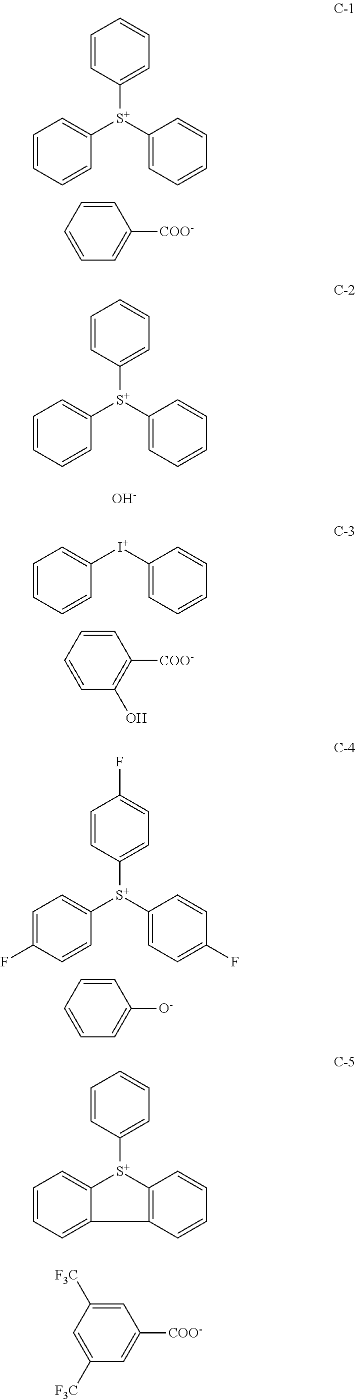

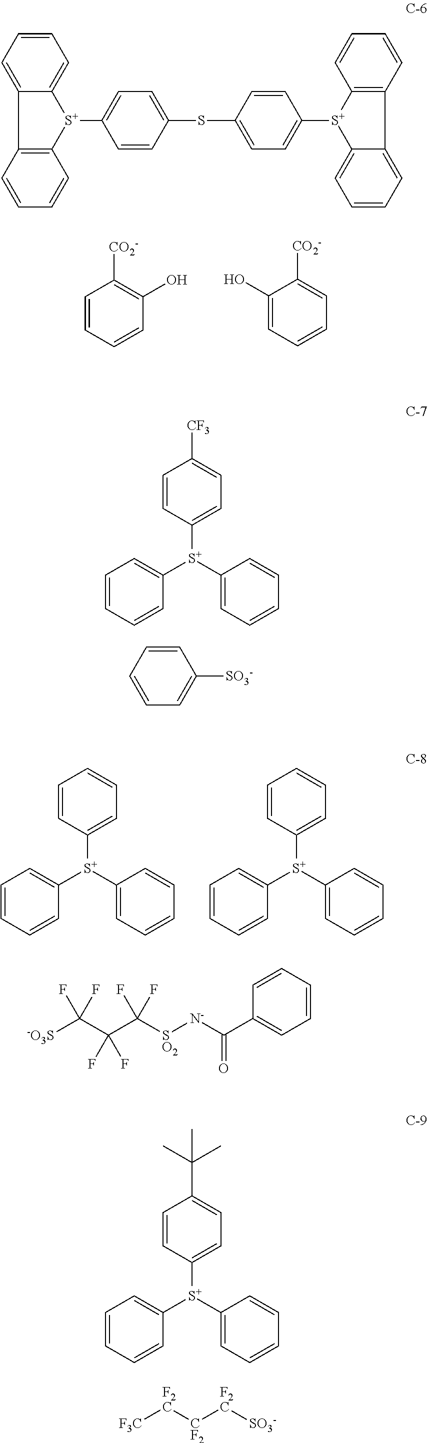

### Hydrophobization Additives (Capping Agents)

The structures of the hydrophobization additives (D-1 and D-2) described in Table 3 are illustrated below.

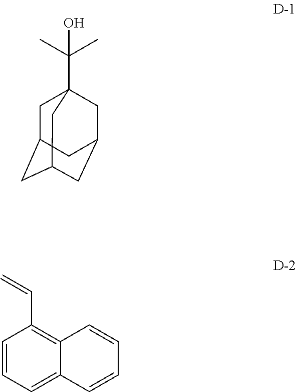

### Solvents

The solvents described in Table 3 are listed below.
SL-1: Propylene glycol monomethyl ether acetate (PGMEA)
SL-2: Propylene glycol monomethyl ether (PGME)
SL-3: Cyclohexanone
SL-4: y-Butyrolactone
SL-5: Ethyl lactate
SL-6: Diacetone alcohol

### Solvents Included in Developers and Rinse Liquids

The solvents included in the developers and rinse liquids described in Table 4 are listed below.
D-1: Ethyl propionate
D-2: Propyl acetate
D-3: Butyl acetate
D-4: Propyl propionate
D-5: Hexyl acetate
D-6: Isoamyl butyrate
D-7: n-Octane
D-8: n-Undecane
D-9: Isopropyl alcohol
D-10: n-Butanol
D-11: 4-Methyl-2-pentanol
D-12: Diisobutyl ether
D-13: Cyclohexanone
D-14: 2-Heptanone
D-15: Diisobutyl ketone
D-16: Propylene glycol monomethyl ether acetate (PGMEA)
D-17: Propylene glycol monomethyl ether (PGME)
D-18: Ethyl lactate
D-19: Vertrel™ XF (CF₃CFHCFHCF₂CF₃)
D-20: Novec™ 7300 (C₂F₅CF(OCH₃)C₃F₇)

Table 2 lists the physical properties of the organic solvents used as developers and rinse liquids. Note that the term “Boiling point” used in Table 2 refers to a boiling point under 1 atmospheric pressure (760 mmHg).

TABLE 2

| No. | Solvent name | Boiling point | | ClogP |
|---|---|---|---|---|
| D-1 | Ethyl propionate | 99° | C. | 1.24 |
| D-2 | Propyl acetate | 102° | C. | 1.24 |
| D-3 | Butyl acetate | 126° | C. | 1.77 |
| D-4 | Propyl propionate | 122° | C. | 1.77 |
| D-5 | Hexyl acetate | 172° | C. | 2.83 |
| D-6 | Isoamyl butyrate | 178° | C. | 3.23 |
| D-7 | n-Octane | 125° | C. | 4.93 |
| D-8 | n-Undecane | 196° | C. | 6.51 |
| D-9 | Isopropyl alcohol | 83° | C. | 0.07 |
| D-10 | n-Butanol | 117° | C. | 0.82 |
| D-11 | 4-Methyl-2-pentanol | 132° | C. | 1.53 |
| D-12 | Diisobutyl ether | 122° | C. | 2.73 |
| D-13 | Cyclohexanone | 156° | C. | 0.87 |
| D-14 | 2-Heptanone | 151° | C. | 1.91 |
| D-15 | Diisobutyl ketone | 168° | C. | 2.71 |
| D-16 | PGMEA | 146° | C. | 0.60 |
| D-17 | PGME | 120° | C. | −0.30 |
| D-18 | Ethyl lactate | 154° | C. | 0.33 |
| D-19 | CF₃CFHCFHCF₂CF₃ | 55° | C. | 2.75 |
| D-20 | C₂F₅CF(OCH₃)C₃F₇ | 98° | C. | 5.09 |

The components described in Table 3 below were mixed with one another. The resulting liquid mixture was filtered through a polyethylene filter having a pore size of 0.03 μm. Hereby, a resist composition (i.e., a resin composition) was prepared. In Table 3, “Resin (X)” refers to a resin the molecular weight of which reduces as a result of the backbone of the resin being broken by the action of exposure, an acid, or a base; “Resin (Y)” refers to a resin other than the resin (X); “PAG (C)” refers to the photodecomposable onium salt compound, and “Hydrophobization additive” refers to the hydrophobization additive (i.e., the capping agent).

The solid component concentration in each of the resist composition had been adjusted appropriately such that the resist composition could be formed into a coating film having the thickness described in Table 4 below. Note that the term “solid component” used herein refers to all the components other than a solvent. The resist compositions prepared were used in Examples and Comparative Examples.

In Table 3, “Content [mass %]” refers to the content [mass %] of each component relative to the total solid content in the resist composition.

TABLE 3

| | | | | | | | Hydrophobization | | |
|---|---|---|---|---|---|---|---|---|---|
| | Resin (X) | | Resin (Y) | | PAG(C) | | additive | | |
| Resist | | Content | | Content | | Content | | Content | Solvent |
| composition | Type | [mass %] | Type | [mass %] | Type | [mass %] | Type | [mass %] | [mass ratio] |
| R-1 | P-1 | 85% | — | — | C-1 | 15% | — | — | SL-1/SL-2 = 80/20 |
| R-2 | P-2 | 81% | — | — | C-2 | 19% | — | — | SL-1/SL-2/SL-3 = |
| | | | | | | | | | 60/20/20 |
| R-3 | P-3 | 80% | — | — | C-3 | 20% | — | — | SL-1/SL-2/SL-5 = |
| | | | | | | | | | 30/20/50 |
| R-4 | P-4 | 88% | — | — | C-4 | 12% | — | — | SL-3 = 100 |
| R-5 | P-5 | 85% | — | — | C-5 | 15% | — | — | SL-1 = 100 |
| R-6 | P-6 | 77% | — | — | C-6 | 23% | — | — | SL-1/SL-6 = 20/80 |
| R-7 | P-7 | 85% | — | — | C-7 | 15% | — | — | SL-1/SL-2/SL-4 = |
| | | | | | | | | | 80/15/5 |
| R-8 | P-8 | 88% | — | — | C-1 | 12% | — | — | SL-1/SL-2 = 60/40 |
| R-9 | P-9 | 92% | — | — | C-3 | 8% | — | — | SL-1/SL-2 = 80/20 |
| R-10 | P-10 | 85% | — | — | C-6 | 15% | — | — | SL-1/SL-2/SL-4 = |
| | | | | | | | | | 80/15/5 |
| R-11 | P-11 | 84% | — | — | C-8 | 16% | — | — | SL-1/SL-2/SL-4 = |
| | | | | | | | | | 80/15/5 |
| R-12 | P-12 | 100% | — | — | — | — | — | — | SL-1/SL-2/SL-4 = |
| | | | | | | | | | 80/15/5 |
| R-13 | P-13 | 85% | — | — | C-3/C-9 | 5%/10% | — | — | SL-1/SL-2/SL-4 = |
| | | | | | | | | | 80/15/5 |
| R-14 | P-12 | 38% | P-14 | 50% | C-8 | 12% | — | — | SL-1/SL-2/SL-4 = |
| | | | | | | | | | 80/15/5 |
| R-15 | P-12 | 47% | P-15 | 40% | C-5 | 13% | — | — | SL-1/SL-2/SL-4 = |
| | | | | | | | | | 80/15/5 |
| R-16 | P-6 | 74% | — | — | C-7 | 11% | D-1 | 15% | SL-1/SL-2/SL-4 = |
| | | | | | | | | | 80/15/5 |
| R-17 | P-12 | 35% | P-15 | 35% | C-9 | 15% | D-2 | 15% | SL-1/SL-2/SL-4 = |
| | | | | | | | | | 80/15/5 |
| R-18 | P-16 | 100% | — | — | — | — | — | — | SL-1/SL-2/SL-4 = |
| | | | | | | | | | 80/15/5 |
| R-19 | — | — | P-15 | 85% | C-1 | 15% | — | — | SL-1/SL-2/SL-4 = |
| | | | | | | | | | 80/15/5 |

### Pattern Formation and Evaluations

### Formation of Pattern by EUV Exposure

An underlayer film-forming composition “SHB-A940” produced by Shin-Etsu Chemical Co., Ltd. was applied onto a silicon wafer having a diameter of 300 mm, and the resulting coating film was baked at 205° C. for 60 seconds to form an underlayer film having a thickness of 20 nm. The resist composition described in Table 3 was applied onto the underlayer film to form a resist film under the conditions (“Thickness” and “PreBake”) described in Table 4. Hereby, a silicon wafer including a resist film disposed thereon was formed.

The silicon wafer including a resist film disposed thereon, which was prepared in the above-described manner, was subjected to pattern irradiation using an EUV scanner “NXE3400” (NA: 0.33) produced by ASML while the amount of exposure light was changed. The reticle used was a mask having a hexagonal contact hole array with a pitch of 36 nm and an opening size of 21 nm. Subsequently, only in the case where a mention is made to baking, baking (post exposure baking, PEB) was performed under the conditions described in Table 4. Subsequently, puddling was performed for 30 seconds with the developer described in Table 4. Then, only in the case where a mention is made to rinsing in Table 4, while the wafer was rotated at a rotational speed of 1,000 rpm, the rinse liquid described in Table 4 was poured over the wafer for 10 seconds in order to perform rinsing. Subsequently, the wafer was rotated at a rotational speed of 4,000 rpm for 30 seconds. Hereby, a contact hole pattern having a pitch of 36 nm was formed.

### Evaluation of Critical Resolution

With a critical dimension-scanning electron microscope (SEM) “CG6300” produced by Hitachi High-Tech Corporation, 2,000 holes formed at various amounts of exposure light were inspected for the average hole diameter and the pattern quality. The average diameter of holes formed at the minimum amount of exposure light with which any of the 2,000 holes inspected was not opened was defined as “critical resolution”. The smaller the value, the higher the resolving power and the performance.

The above critical resolution is preferably 17.5 nm or less, is more preferably 17.0 nm or less, is further preferably 16.0 nm or less, and is particularly preferably 15.0 nm or less.

### Evaluation of In-Plane Evenness of Resolution

The wafer was treated in the same manner as in the above pattern forming method, except that the entire surface of the wafer was exposed to light at the exposure amount with which the critical resolution determined above was observed. Hereby, a wafer including a hole pattern formed on the entire surface of the wafer, the hole pattern having a critical resolution size, was prepared. With a critical dimension-scanning electron microscope “CG6300” produced by Hitachi High-Tech Corporation, 10,000 holes were randomly inspected at each of the positions 30, 60, 90, and 120 mm away from the center of the wafer outward in order to count the number of the non-opening holes. The smaller the number of the non-opening holes observed at each position, the higher the likelihood of homogeneous resolution being desirably achieved over the surface of the wafer.

As for the in-plane evenness of resolution, the maximum number of non-opening holes observed at each of the positions 30, 60, 90, and 120 mm away from the center of the wafer outward is preferably 9 or less, is more preferably 5 or less, is further preferably 3 or less, and is particularly preferably 1.

### Results

Table 4 lists the evaluation results above.

Note that the compositional ratios between the solvents include in each of the developers and rinse liquids are on a mass basis.

TABLE 4

| | | | | | | | Properties of developer and rinse liquid | | |
|---|---|---|---|---|---|---|---|---|---|
| | | | | | | | including two or more organic solvents | | |
| | | | | | | | | One of the | Presence |
| | | | | | | | | developers | of solvent |
| | | | | | | | | has higher | including |
| | Resist application conditions | | | PEB and developing conditions | | | Maximum | boiling | 50 mass % or |
| Table 4 | | Thickness | | | | Rinse | boiling | point and | more fluorine |
| (Part-1) | Resist | [mm] | PreBake | PEB | Developer | liquid | point | larger ClogP | atoms |
| Example | R-1 | 40 | 100° C./60 s | 120° C./60 s | D-3 = 100 | D-3:D-8 = | 196° C. | Yes | No |
| 1 | | | | | | 90:10 | | | |
| Example | R-1 | 40 | 120° C./60 s | 120° C./60 s | D-3:D-8 = | D-5 = 100 | 196° C. | Yes | No |
| 2 | | | | | 90:10 | | | | |
| Example | R-1 | 40 | 120° C./60 s | 100° C./60 s | D-3:D-8 = | D-6:D-8 = | 196° C. | Yes | No |
| 3 | | | | | 90:10 | 90:10 | | | |
| Example | R-2 | 45 | 120° C./60 s | — | D-3 = 100 | D-2:D-12 = | 122° C. | Yes | No |
| 4 | | | | | | 40:60 | | | |
| Example | R-3 | 35 | 100° C./60 s | 120° C./60 s | D-5 = 100 | D-3:D-6 = | 178° C. | Yes | No |
| 5 | | | | | | 70:30 | | | |
| Example | R-4 | 40 | 130° C./60 s | 100° C./60 s | D-11 = 100 | D-3:D-8 = | 196° C. | Yes | No |
| 6 | | | | | | 90:10 | | | |
| Example | R-5 | 40 | 80° C./60 s | 130° C./60 s | D-14 = 100 | D-3:D-15 = | 168° C. | Yes | No |
| 7 | | | | | | 80:20 | | | |
| Example | R-6 | 40 | 120° C./60 s | 120° C./60 s | D-3 = 100 | D-4:D-8 = | 196° C. | Yes | No |
| 8 | | | | | | 85:15 | | | |
| Example | R-7 | 40 | 120° C./60 s | 120° C./60 s | D-3 = 100 | D-5:D-8 = | 196° C. | Yes | No |
| 9 | | | | | | 90:10 | | | |
| Example | R-1 | 40 | 120° C./60 s | 120° C./60 s | D-3 = 100 | D-6:D-8 = | 196° C. | Yes | No |
| 10 | | | | | | 90:10 | | | |
| Example | R-1 | 40 | 120° C./60 s | 120° C./60 s | D-3 = 100 | D-11:D-15 = | 168° C. | Yes | No |
| 11 | | | | | | 50:50 | | | |
| Example | R-1 | 40 | 120° C./60 s | 120° C./60 s | D-3 = 100 | D-7:D-12 = | 125° C. | Yes | No |
| 12 | | | | | | 20:80 | | | |

| | Results of performance evaluation | | | | |
|---|---|---|---|---|---|
| | | Number of non-opening holes (out of 10,000) | | | |
| | Critical | Position | Position | Position | Position |
| Table 4 | resolution | 30 nm | 60 nm | 90 nm | 120 nm |
| (Part-1) | [nm] | from center | from center | from center | from center |
| Example | 14.3 | 1 | 1 | 0 | 0 |
| 1 | | | | | |
| Example | 14.2 | 1 | 0 | 1 | 1 |
| 2 | | | | | |
| Example | 14.8 | 1 | 0 | 0 | 1 |
| 3 | | | | | |
| Example | 14.7 | 0 | 1 | 0 | 0 |
| 4 | | | | | |
| Example | 14.1 | 1 | 1 | 0 | 1 |
| 5 | | | | | |
| Example | 14.8 | 0 | 1 | 1 | 0 |
| 6 | | | | | |
| Example | 14.7 | 0 | 0 | 1 | 0 |
| 7 | | | | | |
| Example | 14.0 | 0 | 1 | 1 | 1 |
| 8 | | | | | |
| Example | 14.7 | 0 | 0 | 1 | 0 |
| 9 | | | | | |
| Example | 14.3 | 0 | 1 | 0 | 1 |
| 10 | | | | | |
| Example | 14.1 | 1 | 0 | 0 | 1 |
| 11 | | | | | |
| Example | 14.8 | 0 | 1 | 0 | 0 |
| 12 | | | | | |

TABLE 5

| | | | | | | | Properties of developer and rinse liquid | | |
|---|---|---|---|---|---|---|---|---|---|
| | | | | | | | including two or more organic solvents | | |
| | | | | | | | | One of the | Presence |
| | | | | | | | | developers | of solvent |
| | | | | | | | | has higher | including |
| | Resist application conditions | | | PEB and developing conditions | | | Maximum | boiling | 50 mass % or |
| Table 4 | | Thickness | | | | Rinse | boiling | point and | more fluorine |
| (Part-2) | Resist | [mm] | PreBake | PEB | Developer | liquid | point | larger ClogP | atoms |
| Example | R-1 | 40 | 120° C./60 s | 120° C./60 s | D-3 = 100 | D-5:D-13 = | 172° C. | Yes | No |
| 13 | | | | | | 70:30 | | | |
| Example | R-1 | 40 | 120° C./60 s | 120° C./60 s | D-3 = 100 | D-8:D-14 = | 196° C. | Yes | No |
| 14 | | | | | | 20:80 | | | |
| Example | R-1 | 40 | 120° C./60 s | 120° C./60 s | D-3 = 100 | D-5:D-14 = | 172° C. | Yes | No |
| 15 | | | | | | 50:50 | | | |
| Example | R-1 | 40 | 120° C./60 s | 120° C./60 s | D-3 = 100 | D-14:D-15 = | 168° C. | Yes | No |
| 16 | | | | | | 50:50 | | | |
| Example | R-1 | 40 | 120° C./60 s | 120° C./60 s | D-3 = 100 | D-8:D-16 = | 196° C. | Yes | No |
| 17 | | | | | | 30:70 | | | |
| Example | R-1 | 40 | 120° C./60 s | 120° C./60 s | D-3 = 100 | D-8:D-17 = | 196° C. | Yes | No |
| 18 | | | | | | 30:70 | | | |
| Example | R-1 | 40 | 120° C./60 s | 120° C./60 s | D-3 = 100 | D-8:D-18 = | 196° C. | Yes | No |
| 19 | | | | | | 30:70 | | | |
| Example | R-1 | 40 | 120° C./60 s | 120° C./60 s | D-8:D-16 = | D-5 = 100 | 196° C. | Yes | No |
| 20 | | | | | 30:70 | | | | |
| Example | R-1 | 40 | 120° C./60 s | 120° C./60 s | D-3:D-8 = | — | 196° C. | Yes | No |
| 21 | | | | | 90:10 | | | | |
| Example | R-1 | 40 | 120° C./60 s | 120° C./60 s | D-8:D-17 = | — | 196° C. | Yes | No |
| 22 | | | | | 30:70 | | | | |
| Example | R-1 | 40 | 120° C./60 s | 120° C./60 s | D-8:D-18 = | D-5 = 100 | 196° C. | Yes | No |
| 23 | | | | | 30:70 | | | | |
| Example | R-1 | 40 | 120° C./60 s | 120° C./60 s | D-3 = 100 | D-7:D-14 = | 151° C. | No | No |
| 24 | | | | | | 20:80 | | | |

| | Results of performance evaluation | | | | |
|---|---|---|---|---|---|
| | | Number of non-opening holes (out of 10,000) | | | |
| | Critical | Position | Position | Position | Position |
| Table 4 | resolution | 30 nm | 60 nm | 90 nm | 120 nm |
| (Part-2) | [nm] | from center | from center | from center | from center |
| Example | 14.1 | 1 | 1 | 0 | 0 |
| 13 | | | | | |
| Example | 14.1 | 0 | 1 | 0 | 0 |
| 14 | | | | | |
| Example | 14.8 | 0 | 0 | 1 | 0 |
| 15 | | | | | |
| Example | 14.0 | 0 | 1 | 1 | 0 |
| 16 | | | | | |
| Example | 14.1 | 1 | 1 | 1 | 1 |
| 17 | | | | | |
| Example | 14.6 | 1 | 0 | 1 | 0 |
| 18 | | | | | |
| Example | 14.6 | 0 | 1 | 1 | 0 |
| 19 | | | | | |
| Example | 14.8 | 0 | 0 | 1 | 1 |
| 20 | | | | | |
| Example | 14.0 | 0 | 1 | 0 | 0 |
| 21 | | | | | |
| Example | 14.8 | 0 | 1 | 0 | 0 |
| 22 | | | | | |
| Example | 14.8 | 0 | 1 | 0 | 0 |
| 23 | | | | | |
| Example | 15.5 | 3 | 1 | 2 | 1 |
| 24 | | | | | |

TABLE 6

| | | | | | | | Properties of developer and rinse liquid | | |
|---|---|---|---|---|---|---|---|---|---|
| | | | | | | | including two or more organic solvents | | |
| | | | | | | | | One of the | Presence |
| | | | | | | | | developers | of solvent |
| | | | | | | | | has higher | including |
| | Resist application conditions | | | PEB and developing conditions | | | Maximum | boiling | 50 mass % or |
| Table 4 | | Thickness | | | | Rinse | boiling | point and | more fluorine |
| (Part-3) | Resist | [mm] | PreBake | PEB | Developer | liquid | point | larger ClogP | atoms |
| Example | R-1 | 40 | 120° C./60 s | 120° C./60 s | D-3 = 100 | D-2:D-10 = | 117° C. | No | No |
| 25 | | | | | | 70:30 | | | |
| Example | R-1 | 40 | 120° C./60 s | 120° C./60 s | D-3 = 100 | D-2:D-19 = | 102° C. | No | Yes |
| 26 | | | | | | 50:50 | | | |
| Example | R-8 | 40 | 120° C./60 s | 120° C./60 s | D-3 = 100 | D-3:D-8 = | 196° C. | Yes | No |
| 27 | | | | | | 90:10 | | | |
| Example | R-9 | 40 | 120° C./60 s | 120° C./60 s | D-3 = 100 | D-3:D-8 = | 196° C. | Yes | No |
| 28 | | | | | | 90:10 | | | |
| Example | R-10 | 40 | 120° C./60 s | 120° C./60 s | D-3 = 100 | D-3:D-8 = | 196° C. | Yes | No |
| 29 | | | | | | 90:10 | | | |
| Example | R-11 | 40 | 120° C./60 s | 120° C./60 s | D-3 = 100 | D-3:D-8 = | 196° C. | Yes | No |
| 30 | | | | | | 90:10 | | | |
| Example | R-12 | 40 | 120° C./60 s | 120° C./60 s | D-3 = 100 | D-3:D-8 = | 196° C. | Yes | No |
| 31 | | | | | | 90:10 | | | |
| Example | R-13 | 40 | 120° C./60 s | 120° C./60 s | D-3 = 100 | D-3:D-8 = | 196° C. | Yes | No |
| 32 | | | | | | 90:10 | | | |
| Example | R-14 | 40 | 120° C./60 s | 120° C./60 s | D-3 = 100 | D-3:D-8 = | 196° C. | Yes | No |
| 33 | | | | | | 90:10 | | | |
| Example | R-15 | 40 | 120° C./60 s | 120° C./60 s | D-3 = 100 | D-3:D-8 = | 196° C. | Yes | No |
| 34 | | | | | | 90:10 | | | |
| Example | R-16 | 40 | 120° C./60 s | 120° C./60 s | D-3 = 100 | D-3:D-8 = | 196° C. | Yes | No |
| 35 | | | | | | 90:10 | | | |
| Example | R-17 | 40 | 120° C./60 s | 120° C./60 s | D-3 = 100 | D-3:D-8 = | 196° C. | Yes | No |
| 36 | | | | | | 90:10 | | | |

| | Results of performance evaluation | | | | |
|---|---|---|---|---|---|
| | | Number of non-opening holes (out of 10,000) | | | |
| | Critical | Position | Position | Position | Position |
| Table 4 | resolution | 30 nm | 60 nm | 90 nm | 120 nm |
| (Part-3) | [nm] | from center | from center | from center | from center |
| Example | 16.6 | 3 | 4 | 3 | 4 |
| 25 | | | | | |
| Example | 17.4 | 7 | 9 | 7 | 6 |
| 26 | | | | | |
| Example | 16.3 | 3 | 5 | 5 | 4 |
| 27 | | | | | |
| Example | 15.2 | 2 | 3 | 3 | 3 |
| 28 | | | | | |
| Example | 16.6 | 3 | 4 | 4 | 4 |
| 29 | | | | | |
| Example | 15.4 | 1 | 3 | 1 | 2 |
| 30 | | | | | |
| Example | 17.1 | 5 | 7 | 8 | 8 |
| 31 | | | | | |
| Example | 15.5 | 1 | 3 | 2 | 2 |
| 32 | | | | | |
| Example | 16.4 | 3 | 3 | 5 | 4 |
| 33 | | | | | |
| Example | 15.5 | 3 | 1 | 2 | 1 |
| 34 | | | | | |
| Example | 14.3 | 1 | 0 | 1 | 0 |
| 35 | | | | | |
| Example | 15.2 | 1 | 3 | 1 | 3 |
| 36 | | | | | |

TABLE 7

| | | | | | | | Properties of developer and rinse liquid | | |
|---|---|---|---|---|---|---|---|---|---|
| | | | | | | | including two or more organic solvents | | |
| | | | | | | | | One of the | Presence |
| | | | | | | | | developers | of solvent |
| | | | | | | | | has higher | including |
| | Resist application conditions | | | PEB and developing conditions | | | Maximum | boiling | 50 mass % or |
| Table 4 | | Thickness | | | | Rinse | boiling | point and | more fluorine |
| (Part-4) | Resist | [mm] | PreBake | PEB | Developer | liquid | point | larger ClogP | atoms |
| Comparative | R-18 | 40 | 120° C./60 s | 120° C./60 s | D-1:D-20 = | D-5 = 100 | 99° C. | No | Yes |
| example 1 | | | | | 50:50 | | | | |
| Comparative | R-18 | 40 | 120° C./60 s | 120° C./60 s | D-9:D-19 = | — | 83° C. | No | Yes |
| example 2 | | | | | 50:50 | | | | |
| Comparative | R-18 | 40 | 120° C./60 s | 120° C./60 s | D-5 = 100 | — | — | — | — |
| example 3 | | | | | | | | | |
| Comparative | R-19 | 40 | 120° C./60 s | 120° C./60 s | D-2:D-19 = | D-5 = 100 | 102° C. | No | Yes |
| example 4 | | | | | 50:50 | | | | |

| | Results of performance evaluation | | | | |
|---|---|---|---|---|---|
| | | Number of non-opening holes (out of 10,000) | | | |
| | Critical | Position | Position | Position | Position |
| Table 4 | resolution | 30 nm | 60 nm | 90 nm | 120 nm |
| (Part-4) | [nm] | from center | from center | from center | from center |
| Comparative | 18.2 | 201 | 203 | 245 | 137 |
| example 1 | | | | | |
| Comparative | 18.8 | 125 | 179 | 147 | 144 |
| example 2 | | | | | |
| Comparative | 22.5 | 39 | 12 | 23 | 19 |
| example 3 | | | | | |
| Comparative | 23.1 | 39 | 19 | 32 | 14 |
| example 4 | | | | | |

The results described in Table 4 confirm that the resist composition according to the present invention may produce the intended advantageous effects.

A comparison between Examples 1 and 24 confirms that, in the case where the boiling points and C log P values of two of the organic solvents included in the specific chemical solution used as a developer and/or a rinse liquid satisfy the relationship that one of the two organic solvents has a higher boiling point and a larger C log P than the other, critical resolution and the in-plane evenness of resolution may be further enhanced.

A comparison between Examples 24 and 25 confirms that, in the case where the specific chemical solution used as a developer and/or a rinse liquid includes an organic solvent having a boiling point 120° C. or more, critical resolution and the in-plane evenness of resolution may be further enhanced.

A comparison between Examples 25 and 26 confirms that, in the case where the specific chemical solution used as a developer and/or a rinse liquid does not include an organic solvent including 50% by mass or more fluorine atoms, critical resolution and the in-plane evenness of resolution may be further enhanced.

A comparison between Examples 1, 27, and 28 confirms that, in the case where the polydispersity (PDI) of the resin X is 2.0 or less (more preferably, 1.7 or less), critical resolution and the in-plane evenness of resolution may be further enhanced.

A comparison between Examples 1, 29, and 30 confirms that, in the case where the weight-average molecular weight Mw of the resin X is 30,000 or more (more preferably, 40,000 or more), critical resolution and the in-plane evenness of resolution may be further enhanced.

A comparison between Examples 1 and 31 confirms that, in the case where the resin X includes an interactive group that interacts with an onium salt compound, the interaction being canceled by the action of exposure, an acid, or a base, and the resist composition further includes an onium salt compound, critical resolution and the in-plane evenness of resolution may be further enhanced.

A comparison between Examples 31 and 32 confirms that, in the case where the resin X includes a group the polarity of which being reduced by the action of exposure, an acid, or a base, critical resolution and the in-plane evenness of resolution may be further enhanced.

A comparison between Examples 31 and 33 confirms that, in the case where the resist composition further includes a resin Y other than the resin X, and the resin Y includes a group the polarity of which being reduced by the action of exposure, an acid, or a base, critical resolution and the in-plane evenness of resolution may be further enhanced.

A comparison between Examples 31 and 34 confirms that, in the case where the resist composition further includes a resin Y other than the resin X, and the resin Y includes an interactive group that interacts with an onium salt compound, the interaction being canceled by the action of exposure, an acid, or a base, and the resist composition further includes an onium salt compound, critical resolution and the in-plane evenness of resolution may be further enhanced.

A comparison between Examples 31 and 36 confirms that, in the case where the resist composition further includes a resin Y other than the resin X, the resin Y has a polar group, and the resist composition further includes a compound that reacts with the polar group by the action of exposure, an acid, or a base, critical resolution and the in-plane evenness of resolution may be further enhanced.

What is claimed is:

1. A pattern forming method comprising:
a step 1 of forming a resist film on a substrate with an actinic ray- or radiation-sensitive resin composition including a resin X, a molecular weight of the resin X reducing as a result of a backbone of the resin X being broken by an action of exposure, an acid, or a base;
a step 2 of exposing the resist film to light; and
a step 3 of developing the resist film with a developer including an organic solvent to remove an exposed portion to form a pattern,
wherein the pattern forming method may further comprise a step 4 of cleaning the pattern using a rinse liquid including an organic solvent subsequent to the step 3,
in the case where the pattern forming method does not comprise the step 4 subsequent to the step 3, the developer is a chemical solution including two or more types of organic solvents,
in the case where the pattern forming method comprises the step 4 subsequent to the step 3, at least one of the developer or the rinse liquid is a chemical solution including two or more types of organic solvents, and
the chemical solution including two or more types of organic solvents includes at least an organic solvent having a boiling point of 100° C. or more.

2. The pattern forming method according to claim 1,
wherein the resin X has a group, a polarity of the group being reduced by an action of exposure, an acid, or a base.

3. The pattern forming method according to claim 1,
wherein the composition further includes a resin Y other than the resin X, and
the resin Y has a group, a polarity of the group being reduced by an action of exposure, an acid, or a base.

4. The pattern forming method according to claim 1,
wherein the resin X has an interactive group that interacts with an onium salt compound, an interaction between the interactive group and the onium salt compound being canceled by an action of exposure, an acid, or a base, and
the composition further includes an onium salt compound.

5. The pattern forming method according to claim 1,
wherein the composition further includes a resin Y other than the resin X,
the resin Y has an interactive group that interacts with an onium salt compound, an interaction between the interactive group and the onium salt compound being canceled by an action of exposure, an acid, or a base, and
the composition further includes an onium salt compound.

6. The pattern forming method according to claim 1,
wherein the resin X has a polar group, and
the composition further includes a compound capable of reacting with the polar group by an action of exposure, an acid, or a base.

7. The pattern forming method according to claim 1,
wherein the composition further includes a resin Y other than the resin X,
the resin Y has a polar group, and
the composition further includes a compound capable of reacting with the polar group by an action of exposure, an acid, or a base.

8. The pattern forming method according to claim 1,
wherein the resin X has a weight-average molecular weight of 40,000 or more.

9. The pattern forming method according to claim 1,
wherein the resin X has a polydispersity of 1.7 or less.

10. The pattern forming method according to claim 1,
wherein the chemical solution including two or more types of organic solvents substantially does not include an organic solvent containing 50% by mass or more fluorine atoms.

11. The pattern forming method according to claim 1,
wherein the chemical solution including two or more types of organic solvents includes an organic solvent having a boiling point of 120° C. or more.

12. The pattern forming method according to claim 1,
wherein the chemical solution including two or more types of organic solvents includes organic solvents A and B,
the organic solvent A has a higher boiling point than the organic solvent B, and
the organic solvent A has a larger C log P than the organic solvent B.

13. A method for producing an electronic device,
the method comprising the pattern forming method according to claim 1.

14. The pattern forming method according to claim 2,
wherein the resin X has a weight-average molecular weight of 40,000 or more.

15. The pattern forming method according to claim 2,
wherein the resin X has a polydispersity of 1.7 or less.

16. The pattern forming method according to claim 2,
wherein the chemical solution including two or more types of organic solvents substantially does not include an organic solvent containing 50% by mass or more fluorine atoms.

17. The pattern forming method according to claim 2,
wherein the chemical solution including two or more types of organic solvents includes an organic solvent having a boiling point of 120° C. or more.

18. The pattern forming method according to claim 2,
wherein the chemical solution including two or more types of organic solvents includes organic solvents A and B,
the organic solvent A has a higher boiling point than the organic solvent B, and
the organic solvent A has a larger C log P than the organic solvent B.

19. A method for producing an electronic device,
the method comprising the pattern forming method according to claim 2.

20. The pattern forming method according to claim 3,
wherein the resin X has a weight-average molecular weight of 40,000 or more.
